(19) United States
(12) Patent Application Publication
(10) Pub. No.: US 2022/0019441 A1
(43) Pub. Date: Jan. 20, 2022

(54) CIRCUITS, METHODS, AND ARTICLES OF MANUFACTURE FOR HYPER-DIMENSIONAL COMPUTING SYSTEMS AND RELATED APPLICATIONS

(71) Applicant: The Regents of the University of California, Oakland, CA (US)

(72) Inventors: Tajana Simunic Rosing, San Diego, CA (US); Justin Morris, San Diego, NC (US); Mohsen Imani, San Diego, CA (US); Yeseong Kim, La Jolla, CA (US); John Messerly, Danville, CA (US); Yunhui Guo, San Diego, CA (US); Behnam Khaleghi, La Jolla, CA (US); Saransh Gupta, La Jolla, CA (US); Sahand Salamat, San Diego, CA (US); Joonseop Sim, San Diego, CA (US)

(21) Appl. No.: 17/376,105

(22) Filed: Jul. 14, 2021

Related U.S. Application Data
(60) Provisional application No. 63/051,698, filed on Jul. 14, 2020.

(51) Int. Cl. G06F 9/38; G06N 3/063; G06F 9/30; G11C 13/00

(52) U.S. Cl. CPC G06F 9/3836; G11C 13/0026; G06F 9/30036; G06N 3/063

(57) ABSTRACT

A hyperdimensional processing system can be configured to process hyperdimensional (HD) data, where the system can include a CPU configured to receive compiled binary executable data including CPU native instructions and hyperdimensional processing unit (HPU) native instructions, wherein the CPU is configured to store the CPU native instructions in a main memory coupled to the CPU for retrieval and execution by the CPU, the CPU further configured to forward the HPU native instructions to a HPU. The HPU can be configured to receive HPU native instructions native instructions and to store the HPU native instructions in a hyperdimensional memory coupled to the HPU for retrieval and execution by the CPU. Other aspects and embodiments according to the present invention are also disclosed herein.

### CLAIM FOR PRIORITY

This application claims priority to Provisional Application Ser. No. 63/051,698 entitled Combined Hyper-Computing Systems and Applications filed in the U.S. Patent and Trademark Office on Jul. 14, 2020, the entire disclosure of which is hereby incorporated herein by reference.

### STATEMENT OF GOVERNMENT SUPPORT

This invention was made with government support under Grant Nos. 1527034, 1730158, 1826967, 1911095, 1527034 and 1730158 awarded by the National Science Foundation (NSF). The government has certain rights in the invention.

### FIELD

The present invention relates to the field of information processing in general, and more particularly, to hyper-dimensional computing systems.

### BACKGROUND

In conjunction with computer engineering and architecture, Hyperdimensional Computing (HDC) may be an attractive solution for efficient online learning. For example, it is known that HDC can be a lightweight alternative to deep learning for classification problems, e.g., voice recognition and activity recognition, as the HDC-based learning may significantly reduce the number of training epochs required to solve problems in these related areas. Further, HDC operations may be parallelizable and offer protection from noise in hyper-vector components, providing the opportunity to drastically accelerate operations on parallel computing platforms. Studies show HDC's potential for application to a diverse range of applications, such as language recognition, multimodal sensor fusion, and robotics.

### SUMMARY

Embodiments according to the present invention can provide systems, circuits, and articles of manufacture for hyper-dimensional computing systems architecture and related applications. Pursuant to these embodiments, a hyperdimensional processing system can be configured to process hyperdimensional (HD) data, where the system can include a CPU configured to receive compiled binary executable data including CPU native instructions and hyperdimensional processing unit (HPU) native instructions, wherein the CPU is configured to store the CPU native instructions in a main memory coupled to the CPU for retrieval and execution by the CPU, the CPU further configured to forward the HPU native instructions to a HPU. The HPU can be configured to receive HPU native instructions native instructions and to store the HPU native instructions in a hyperdimensional memory coupled to the HPU for retrieval and execution by the CPU. Other aspects and embodiments according to the present invention are also disclosed herein.

### BRIEF DESCRIPTION OF THE DRAWINGS

FIG. 1 illustrates the encoding presented in Equation 1-2a.

FIG. 2 illustrates original and retrieved handwritten digits.

FIGS. 3a-b illustrate Impact of increasing (left) and reducing (right) more effectual dimensions.

FIG. 4 illustrates retraining to recover accuracy loss.

FIGS. 5a-b illustrate Accuracy-sensitivity trade-off of encoding quantization.

FIG. 6 illustrates impact of inference quantization and dimension masking on PSNR and accuracy.

FIGS. 7a-b illustrate Principal blocks of FPGA implementation.

FIGS. 8a-d illustrate Investigating the optimal a, dimensions and impact of data size in the benchmark models.

FIGS. 9a-b: illustrate Impact of inference quantization (left) and dimension masking on accuracy and MSE.

FIG. 10: illustrates an overview of the framework wherein user, item and rating are encoded using hyperdimensional vectors and similar users and similar items are identified based on their characterization vectors.

FIGS. 11a-b: illustrate (a) the process of the hypervectors generation, and (b) the HyperRec encoding module.

FIG. 12: illustrates the impact of dimensionality on accuracy and prediction time.

FIG. 13: illustrates the process of the hypervectors generation.

FIG. 14: illustrates Overview of high-dimensional processing systems.

FIGS. 15a-b: illustrate HDC encoding for ML to encode a feature vector (el, . . . , en) to a feature hypervector (HV).

FIGS. 16a-j: illustrate HDC regression examples. (a-c) show how the retraining and boosting improve prediction quality including (d-j) that show various prediction results with confidence levels and (g) that shows the HDC can solve a multivariate regression.

FIG. 17: illustrates the HPU architecture.

FIGS. 18a-b: illustrate accuracy changed with DBlink.

FIGS. 19a-c: illustrate three Pipeline optimization techniques.

FIG. 20: illustrates a program example.

FIGS. 21a-b: illustrates software support for the HPU.

FIGS. 22a-c: illustrate quality comparison for various learning tasks.

FIGS. 23a-b: illustrate detailed quality evaluation.

FIGS. 24a-c: illustrate Summary of efficiency comparison.

FIG. 25: illustrates Impacts of DBlink on Energy Efficiency.

FIG. 26: illustrates Impacts of DBlink on the HDC Model.

FIG. 27: illustrates Impacts of pipeline optimization.

FIG. 28a-b: illustrate Accuracy loss due to memory endurance.

FIG. 29: illustrates an Overview of HD computing in performing the classification task.

FIGS. 30a-b: illustrate an overview of SearcHD encoding and stochastic training

FIGS. 31a-c: illustrate (a) In-memory implementation of SearcHD encoding module; (b) The sense amplifier supporting bitwise XOR operation and; (c) The sense amplifier supporting majority functionality on the XOR results.

FIGS. 32a-d: illustrate (a) CAM-based associative memory; (b) The structure of the CAM sense amplifier; (c) The ganged circuit and; (d) The distance detector circuit.

FIGS. 33a-d: illustrate classification accuracy of SearcHD, kNN, and the baseline HD algorithms.

FIGS. 34a-d: illustrate training execution time and energy consumption of the baseline HD computing and SearcHD with different configurations including (a) ISOLET, (b) FACE, (c) UCIHAR, and (d) IOT.

FIGS. 35a-d: illustrate inference execution time and energy consumption of the baseline HD algorithm and SearcHD with different configurations including (a) ISOLET, (b) FACE, (c) UCIHAR, and (d) IOT.

FIG. 36: illustrates SearcHD classification accuracy and normalized EDP improvement when the associative memory works in different minimum detectable distances.

FIGS. 37a-d: (a) illustrates impact of dimensionality on SearcHD accuracy and efficiency, (b) occupied area by the encoding and associative search modules in digital design and analog SearcHD; (c) illustrates area and energy breakdown of the encoding module; (d) area and energy breakdown of the associative search module, respectively.

FIG. 38: illustrates an overview of HD computing performing classification task.

FIGS. 39a-e: illustrate an overview of proposed optimization approaches to improve the efficiency of associative search.

FIG. 40: illustrates energy consumption and execution time of HD using proposed optimization approaches.

FIG. 41: illustrates an overview of GenieHD.

FIGS. 42a-d: illustrate Encoding where in (a), (b), and (c), the window size is 6, and wherein (d) the reference encoding steps described in Method 1.

FIGS. 43a-d: illustrate similarity Computation in Pattern Matching. (a) and (b) are computed using Equation 6-2. The histograms shown in (c) and (d) are obtained by testing 1,000 patterns for each of the existing and non-existing cases when R is encoded for a random DNA sequence using D=100,000 and P=5,000.

FIGS. 44a-c: illustrate hardware Acceleration Design wherein the dotted boxes in (a) show the hypervector components required for the computation in the first stage of the reference encoding.

FIG. 45: illustrates performance and Energy Comparison of GenieHD for State-of-the-art Methods.

FIGS. 46a-d: illustrate scalability of GenieHD wherein (a) shows the execution time breakdown to process the single query and reference, (b)-(d) shows how the speedup changes as increasing the number of queries for a reference.

FIG. 47: illustrates accuracy Loss over Dimension Size.

FIGS. 48a-b: illustrate (a) Alignment graph of the sequences ATGTTATA and ATCGTCC; (b) Solution using dynamic programming.

FIG. 49: illustrates Implementing operations using digital processing in memory.

FIGS. 50a-e: illustrate RAPID architecture. (a) Memory organization in RAPID with multiple units connected in H-tree fashion. Same colored arrows represent parallel transfers. Each node in the architecture has a 32-bit comparator, represented by yellow circles, (b) A RAPID unit consisting of three memory blocks, C-M, Bh and By, (c) A C-M block is a single memory block, physically partitioned into two parts by switches including three regions, gray for storing the database or reference genome, green to perform query reference matching and build matrix C, and blue to perform the steps of computation 1, (d) The sense amplifiers of C-M block and the leading ‘1’ detector used for executing minimum, (e) Bh and By blocks which store traceback directions and the resultant alignment.

FIGS. 51a-c: illustrate (a) Storage scheme in RAPID for reference sequence; (b) propagation of input query sequence through multiple units, and (c) evaluation of sub matrices when the units are limited.

FIGS. 52a-b: illustrate Routine comparison across platform.

FIG. 53: illustrates Comparison of execution of different chromosome test pairs. RAPID-1 is a RAPID chip of size 660 mm2 while RAPID-2 has an area of 1300 mm2.

FIGS. 54a-c: illustrate Delay and power of FPGA resources w.r.t. voltage.

FIGS. 55a-c: illustrate Comparison of voltage scaling techniques under varying workloads, critical paths, and applications power behavior.

FIG. 56: illustrates an Overview of an FPGA-based datacenter platform.

FIG. 57: illustrates an Example of Markov chain for workload prediction.

FIGS. 58a-c: illustrate (a) the architecture of the proposed energy-efficient multi-FPGA platform. The details of the (b) central controller, and (c) the FPGA instances.

FIG. 59: illustrates Comparing the efficiency of different voltage scaling techniques under a varying workload for Tabla framework.

FIG. 60: illustrates Voltage adjustment in different voltage scaling techniques under the varying workload for Tabla framework.

FIG. 61: illustrates Power efficiency of the proposed technique in different acceleration frameworks.

FIG. 62: illustrates Implementing operations using digital PIM.

FIGS. 63a-b: (a) illustrate Change in latency for binary multiplication with the size of inputs in state-of-the-art PIM techniques; (b) The increasing block size requirement in binary multiplication.

FIGS. 64a-c: illustrates a SCRIMP overview.

FIGS. 65a-b: illustrate Generation of stochastic numbers using (a) group write, (b) SCRIMP row-parallel generation.

FIGS. 66a-b: illustrate (a) Implication in a column/row, (b) XNOR in a column.

FIGS. 67a-d: illustrate Buried switch technique for array segmenting.

FIGS. 68a-b: illustrate (a) Area overhead and (b) leakage current comparison of proposed segmenting switch to the conventional design.

FIGS. 69a-c: illustrate SCRIMP addition and accumulation in parallel across bit-stream. (a) Discharging of bitlines through multiple rows (rows 1, 3, . . . , x here), (b) linear SCRIMP addition with counter value to output relation, and (c) non-linear SCRIMP addition centered around 0.5.

FIG. 70: illustrates A SCRIMP block.

FIG. 71: illustrates an Implementation of fully connected layer, convolution layer, and hyperdimensional computing on SCRIMP.

FIG. 72: illustrates an Effect of bit-stream length on the accuracy and energy consumption for different applications.

FIG. 73: illustrates Visualization of quality of computation in Sobel application, using different bit-stream lengths.

FIGS. 74a-b: illustrate Speedup and energy efficiency improvement of SCRIMP running (a) DNNs, (b) HD computing.

FIGS. 75a-b: illustrate (a) Relative performance per area of SCRIMP as compared to different SC accelerators with and without SCRIMP addition and (b) comparison of computational and power efficiency of running DNNs on SCRIMP and previously proposed DNN accelerators.

FIGS. 76a-b: illustrates SCRIMP's resilience to (a) memory bit-flips and (b) endurance.

FIG. 77: illustrate an Area Breakdown.

### DETAILED DESCRIPTION OF EMBODIMENTS ACCORDING TO THE INVENTION

Exemplary embodiments of the present disclosure are described in detail with reference to the accompanying drawings. The disclosure may, however, be exemplified in many different forms and should not be construed as being limited to the specific exemplary embodiments set forth herein. Rather, these exemplary embodiments are provided so that this disclosure will be thorough and complete, and will fully convey the scope of the disclosure to those skilled in the art.

The present inventors have disclosed herein methods of applying Hyperdimensional Computing systems and applications of those systems to those applications. The contents are organized into several numbered part listed below. It will be understood that although the material herein is listed as being included in a particular part, one of ordinary skill in the art (given the benefit of the present disclosure) will understand that the material in any of the parts may be combined with one another. Therefore, embodiments according to the present invention can include aspects from a combination of the material in the parts described herein. The parts herein include:

PART 1: PriveHD: Privacy Preservation in Hyperdimensional computing

PART 2: HyperRec: Recommendation system Using Hyperdimensional computing

PART 3: Hyperdimensional Computer System Architecture and exemplary Applications

PART 4: SearchHD: Searching Using Hyperdimensional computing

PART 5: Associative Search Using Hyperdimensional computing

PART 6: GenieHD: DNA Pattern Matching Using Hyperdimensional computing

PART 7: RAPID: DNA Sequence Alignment Using ReRAM Based in-Memory Processing

PART 8: Workload-Aware Processing in Mult-FPGA Platforms

PART 9: SCRIMP: Stochastic Computing Architecture Using ReRAM Based in-Memory Processing

### Part 1: PriveHD: Privacy Preservation in Hyperdimensional Computing

As appreciated by the present inventors, privacy of data is a major challenge in machine learning as a trained model may expose sensitive information of the enclosed dataset. In addition, the limited computation capability and capacity of edge devices have made cloud-hosted inference inevitable. Sending private information to remote servers makes the privacy of inference also vulnerable because of susceptible communication channels or even untrustworthy hosts. Accordingly, privacy-preserving training and inference of brain-inspired Hyperdimensional (HD) computing, a new learning technique that is gaining traction due to its light-weight computation and robustness particularly appealing for edge devices with tight constraints can be utilized. Indeed, despite its promising attributes, HD computing has virtually no privacy due to its reversible computation. An accuracy-privacy trade-off method can be provided through meticulous quantization and pruning of hypervectors to realize a differentially private model as well as to obfuscate the information sent for cloud-hosted inference when leveraged for efficient hardware implementation.

### 1-I. Introduction

The efficacy of machine learning solutions in performing various tasks have made them ubiquitous in different application domains. The performance of these models is proportional to the size of the training dataset. Thus, machine learning models utilize copious proprietary and/or crowdsourced data, e.g., medical images. In this sense, different privacy concerns arise. The first issue is with model exposure. Obscurity is not considered a guaranteed approach for privacy, especially parameters of a model (e.g., weights in the context of neural networks) that might be leaked through inspection. Therefore, in the presence of an adversary with full knowledge of the trained model parameters, the model should not reveal the information of constituting records.

Second, the increasing complexity of machine learning models, on the one hand, and the limited computation and capacity of edge devices, especially in the IoT domain with extreme constraints, on the other hand, have made offloading computation to the cloud indispensable. An immediate drawback of cloud-based inference is compromising client data privacy. The communication channel is not only susceptible to attacks, but an untrusted cloud itself may also expose the data to third-party agencies or exploit it for its own benefits. Therefore, transferring the least amount of information while achieving maximal accuracy is of utmost importance. A traditional approach to deal with such privacy concerns is employing secure multi-party computation that leverages homomorphic encryption whereby the device encrypts the data, and the host performs computation on the ciphertext. These techniques, however, impose a prohibitive computation cost on edge devices.

Previous work on machine learning, particularly deep neural networks, have come up with generally two approaches to preserve the privacy of training (model) or inference. For privacy-preserving training, the well-known concept of differential privacy is incorporated in the training. Differential privacy, often known as the standard notation of guaranteed privacy, aims to apply a carefully chosen noise distribution in order to make the response of a query (here, the model being trained on a dataset) over a database randomized enough so the singular records remain indistinguishable whilst the query result is fairly accurate. Perturbation of partially processed information, e.g., the output of the convolution layer in neural networks, before offloading to a remote server is another trend of privacy-preserving studies that target the inference privacy. Essentially, it degrades the mutual information of the conveyed data. This approach degrades the prediction accuracy and requires (re)-training the neural network to compensate the injected noise or analogously learning the parameters of a noise that can be tolerated by the network, which are not always feasible, e.g., when the model is inaccessible.

HD is a novel efficient learning paradigm that imitates the brain functionality in cognitive tasks, in the sense that the human brain computes with patterns of neural activity rather than scalar values. These patterns and underlying computations can be realized by points and light-weight operations in a hyperdimensional space, i.e., by hypervectors of ˜10,000 dimensions. Similar to other statistical mechanisms, the privacy of HD might be preserved by noise injection, where formally the granted privacy budget is directly proportional to the amount of the introduced noise and indirectly to the sensitivity of mechanism. Nonetheless, as a query hypervector (HD's raw output) has thousands of w-bits dimensions, the sensitivity of the HD model can be extremely large, which requires a tremendous amount of noise to guarantee differential privacy, which significantly reduces accuracy. Similarly, the magnitude of each output dimension is large (each up to 2^{w}), so is the intensity of the required noise to disguise the transferring information for inference.

As appreciated by the present inventors, different techniques including well-devised hypervector (query and/or class) quantization and dimension pruning can be used to reduce the sensitivity, and consequently, the required noise to achieve a differentially private HD model. We also target inference privacy by showing how quantizing the query hypervector, during inference, can achieve good prediction accuracy as well as multifaceted power efficiency while significantly degrading the Peak Signal-to-Noise Ratio (PSNR) of reconstructed inputs (i.e., diminishing useful transferred information). Furthermore, an approximate hardware implementation that benefits from the aforementioned innovations, can also be possible for further performance and power efficiency.

### 1-II. Preliminary

### 1-II.1. Hyperdimensional Computing

Encoding is the first and major operation involved in both training and inference of HD. Assume that an input vector (an image, voice, etc.) comprises [symbol] dimensions (elements or features). Thus, each input [symbol] can be represented as (1). ‘vᵢ’s are elements of the input, where each feature vᵢ takes value among ƒ₀ to ƒₗ_{ᵢᵥ}₋₁. In a black and white image, there are only two feature levels (lᵢᵥ=2), and ƒ₀=0 and ƒ₁=1.

$$\begin{matrix}{\vec{𝒱}}_{iv} = 〈 {v}_{0} , {v}_{1} , … , {v}_{{𝒟}_{iv} - 1} 〉 & ( 1 \text{-} 1 ) \\ \vert {v}_{i} \vert ∈ ℱ = \{ {f}_{0} , {f}_{1} , … {f}_{{ℓ}_{iv} - 1} \} & \end{matrix}$$

Varied HD encoding techniques with different accuracy-performance trade-off have been proposed. Equation (1-2) shows analogous encodings that yield accuracies similar to or better than the state of the art.

$$\begin{matrix}\vec{ℋ} = {\sum }_{k = 0}^{{𝒟}_{iv} - 1} {\vert {v}_{k} \vert}_{∈ ℱ} \cdot {\vec{ℬ}}_{k} & ( 1 \text{-} 2 a ) \\ \vec{ℋ} = {\sum }_{k = 0}^{{𝒟}_{iv} - 1} {\vec{ℒ}}_{{v}_{k}} \cdot {\vec{ℬ}}_{k} & ( 1 \text{-} 2 b )\end{matrix}$$

[symbol] ₖ's are randomly chosen hence orthogonal bipolar base hypervectors of dimension Dₕᵥ δ10⁴ to retain the spatial or temporal location of features in an input. That is, [symbol] ₖ∈{−1, +1 [symbol] and δ( [symbol] ₖ_{₁}, [symbol] ₖ_{₂})≃0, where δ denotes the cosine similarity:

$$δ ( {\vec{ℬ}}_{{k}_{1}} , {\vec{ℬ}}_{{k}_{2}} ) = \frac{{\vec{ℬ}}_{{k}_{1}} \cdot {\vec{ℬ}}_{{k}_{2}}}{‖ {\vec{ℬ}}_{{k}_{1}} ‖ \cdot ‖ {\vec{ℬ}}_{{k}_{2}} ‖}$$

Evidently, there are [symbol] ᵢᵥ fixed based/location hypervectors for an input (one per feature). The only difference of the encodings in (1-2a) and (1-2b) is that in (1-2a) the scalar value of each input feature vₖ (mapped/quantized to nearest ƒ in [symbol] ) is directly multiplied in the corresponding base hypervector [symbol] ₖ. However, in (1-2b), there is a level hypervector of the same length ( [symbol] ₕᵥ) associated with different feature values. Thus, for k^{th} feature of the input, instead of multiplying ƒ_{|vk|}≃|vₖ| by location vector [symbol] ₖ, the associated hypervector [symbol] ᵥ_{ₖ} performs a dot-product with [symbol] ₖ. As both vectors are binary, the dot-product reduces to dimension-wise XNOR operations. To maintain the closeness in features (to demonstrate closeness in original feature values), and [symbol] ₀ and [symbol] are entirely orthogonal, and each [symbol] ₖ₊₁ is obtained by flipping randomly chosen

$$\frac{( {D}_{h ν} )}{2 \cdot {ℓ}_{i v}}$$

bits of [symbol] ₖ.

Training of HD is simple. After generating each encoding hyper-vector [symbol] of inputs belonging to class/label 1, the class hypervector \vec{C}^{l} can be obtained by bundling (adding) all [symbol] s. Assuming there are [symbol] inputs having label l:

$${\vec{C}}^{l} = {\sum }_{j}^{𝒥} {\vec{ℋ}}_{j}^{l} \qquad ( 1 \text{-} 3 )$$

Inference of HD has a two-step procedure. The first step encodes the input (similar to encoding during training) to produce a query hyper-vector [symbol] . Thereafter, the similarity (δ) of [symbol] and all class hypervectors are obtained to find out the class with highest similarity:

$$δ ( \vec{ℋ} , {\vec{C}}^{l} ) = \frac{\vec{ℋ} \cdot {\vec{C}}^{l}}{‖ \vec{ℋ} ‖ \cdot ‖ {\vec{C}}^{l} ‖} = \frac{{\sum }_{k = 0}^{{𝒟}_{hv} - 1} {h}_{k} \cdot {c}_{k}^{l}}{\sqrt{{\sum }_{k = 0}^{{𝒟}_{hv} - 1} {h}_{k}^{2}} \cdot \sqrt{{\sum }_{k = 0}^{{𝒟}_{hv} - 1} {c}_{k}^{{l}^{2}}}} \qquad ( 1 \text{-} 4 )$$

Note that

$$\sqrt{{\sum }_{k = 0}^{{𝒟}_{hv} - 1} {h}_{k}^{2}}$$

is a repeating factor when comparing with all classes, so can be discarded. The

$$\sqrt{{\sum }_{k = 0}^{{𝒟}_{hv} - 1} {c}_{k}^{{l}^{2}}}$$

factor is also constant for a classes, so only needs to be calculated once.

Retraining can boost the accuracy of the HD model by discarding the mispredicted queries from corresponding mispredicted classes and adding them to the right class. Retraining examines if the model correctly returns the label I for an encoded query [symbol] . If the model mispredicts it as label l^{¢}, the model updates as follows.

$${\vec{C}}^{l} = {\vec{C}}^{l} + \vec{ℋ} \begin{matrix} \\ \end{matrix} \\ {\vec{C}}^{{l}^{′}} = {\vec{C}}^{{l}^{′}} - \vec{ℋ} \qquad ( 1 \text{-} 5 )$$

### 2-II.2. Differential Privacy

Differential privacy targets the indistinguishability of a mechanism (or algorithm), meaning whether observing the output of an algorithm, i.e., computations' result, may disclose the computed data. Consider the classical example of a sum query ƒ(n)=Σ₁ⁿg(xᵢ) over a database with xᵢs being the first to n^{th} rows, and g(xi)∈{0, 1}, i.e., the value of each record is either 0 or 1. Although the function ƒ does not reveal the value of an arbitrary record m, it can be readily obtained by two requests as ƒ(m)−ƒ(m−1). Speaking formally, a randomized algorithm [symbol] is ε-indistinguishable or ε-differentially private if for any inputs [symbol] ₁ and [symbol] ₂ that differ in one entry (a.k.a adjacent inputs) and any output S of [symbol] , the following holds:

$$Pr [ ℳ ( {𝒟}_{1} ) ∈ 𝒮 ] \leq {e}^{ɛ} \cdot Pr [ ℳ ( {𝒟}_{2} ) ∈ 𝒮 ] \qquad 1 \text{-} 6$$

This definition guarantees that observing [symbol] ₁ instead of [symbol] ₂ scales up the probability of any event by no more than e^{ε}. Evidently, smaller values of non-negative e provide stronger guaranteed privacy. Dwork et al. have shown that e-differential privacy can be ensured by adding a Laplace noise of scale

$$Lap ( \frac{Δ f}{ɛ} )$$

to the output of algorithm. Δƒ, defined as l₁ norm in Equation (1-7), denotes the sensitivity of the algorithm which represents the amount of change in a mechanism's output by changing one of its arguments, e.g., inclusion/exclusion of an input in training.

$$\begin{matrix}Δ f = {‖ f ( {𝒟}_{1} ) - f ( {𝒟}_{2} ) ‖}_{1} & 1 \text{-} 7 \\ ℳ ( 𝒟 ) = f ( 𝒟 ) + 𝒢 ( 0 , Δ {f}^{2} {σ}^{2} ) & 1 \text{-} 8\end{matrix}$$

[symbol]

(0, Δƒ²σ²) is Gaussian noise with mean zero and standard deviation of Δƒ·σ. Both ƒ and [symbol] are [symbol] ₕᵥ|C| dimensions, i.e., |C| output class hypervectors of [symbol] ₕᵥ dimensions. Here, Δƒ=∥ƒ( [symbol] ₁)−ƒ( [symbol] ₂)∥₂ is [symbol] norm, which relaxes the amount of additive noise. ƒ meets (ε, δ)—privacy if

$$δ \geq \frac{4}{5} {e}^{- \frac{{( σ ɛ )}^{2}}{2}} .$$

Achieving small ε for a given δ needs larger σ, which by (1-8) translates to larger noise.

### 1-III. PRIVEHD

### 1-III.1. Privacy Breach of HD

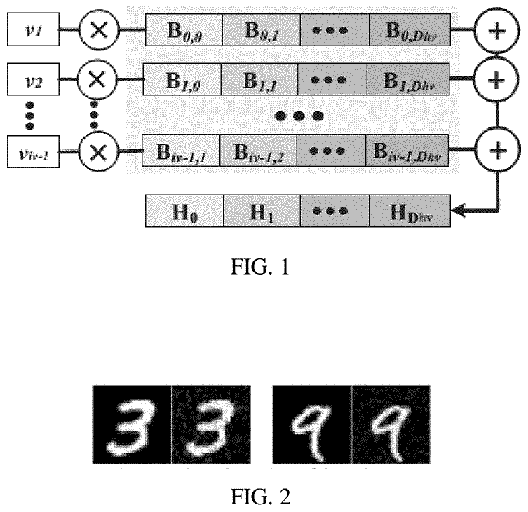

In contrast to the deep neural networks that comprise non-linear operations that somewhat cover up the details of raw input, HD operations are fairly reversible, leaving it zero privacy. That is, the input can be reconstructed from the encoded hypervector. Consider the encoding of Equation (1-2a), which is also illustrated by FIG. 1. Multiplying each side of the equation to hypevector, for each dimension gives:

$$\begin{matrix}{\vec{ℋ}}_{j} \cdot {ℬ}_{0 , j} = {\sum }_{k = 0}^{{𝒟}_{iv} - 1} ( \vert {v}_{k} \vert \cdot {ℬ}_{k , j} ) \cdot {ℬ}_{0 , j} = \vert {v}_{0} \vert \cdot {ℬ}_{0 , j}^{2} + {\sum }_{k = 1}^{{𝒟}_{iv} - 1} \vert {v}_{k} \vert {ℬ}_{k , j} {ℬ}_{0 , j} = \vert {v}_{0} \vert + {\sum }_{k = 1}^{{𝒟}_{iv} - 1} \vert {v}_{k} \vert {ℬ}_{k , j} {ℬ}_{0 , j} & ( 1 \text{-} 9 ) \\ {ℬ}_{0 , j} ∈ \{ - 1 , + 1 \} , so {ℬ}_{0 , j}^{2} = 1. & \\ Summing all dimensions together yields & \\ {\sum }_{j = 0}^{{𝒟}_{hv} - 1} {\vec{ℋ}}_{j} \cdot {ℬ}_{0 , j} = {𝒟}_{hv} \cdot \vert {v}_{0} \vert + {\sum }_{k = 1}^{{𝒟}_{iv} - 1} ( \vert {v}_{k} \vert {\sum }_{j = 0}^{{𝒟}_{hv} - 1} {ℬ}_{k , j} \cdot {ℬ}_{0 , j} ) & ( 1 \text{-} 10 )\end{matrix}$$

As the base hypervectors are orthogonal and especially [symbol] ₕᵥ is large, [symbol] ≃0 in the right side of Equation (1-10). It means that every feature |vₘ| can be retrieved back by

$$\vert {v}_{m} \vert = \frac{\vec{ℋ} \cdot {\vec{ℬ}}_{m}}{{𝒟}_{hv}} .$$

Note that without lack of generality we assumed |vₘ|=ƒᵥ_{ₘ}, i.e., features are not normalized or quantized. Indeed, we are retrieving the features (‘ƒᵢ’s), that might or might not be the exact raw elements. Also, although we showed the reversibility of the encoding in (1-2a), it can easily be adjusted to the other HD encodings. FIG. 2 shows the reconstructed inputs of MNIST samples by using Equation (1-10) to achieve each of 28×28 pixels, one by one.

That being said, the encoded hypervector [symbol] sent for cloud-hosted inference can be inspected to reconstruct the original input. This reversibility also breaches the privacy of the HD model. Consider that, according to the definition of differential privacy, two datasets [symbol] ₁ and [symbol] ₂ differ by one input. If we subtract all class hypervectors of the models trained over [symbol] ₁ and [symbol] ₂, the result (difference) will exactly be the encoded vector of the missing input (remember from Equation (1-3) that class hypervectors are simply created by adding encoded hypervectors of associated inputs). The encoded hypervector hence, can be decoded back to obtain the missing input.

### 1-III.2. Differentially Private HD Training

Let ƒ [symbol] ₁ and ƒ [symbol] ₂ be models trained with encoding of Equation (1-2a) over datasets that differ in a single datum (input) present in [symbol] ₂ but not in [symbol] ₁. The outputs (i.e., class hypervectors) of ƒ( [symbol] ₁) and ƒ( [symbol] ₂) thus differ in inclusion of a single [symbol] ₕᵥ—dimension encoded vector that misses from a particular class of ƒ( [symbol] ₁). The other class hypervectors will be the same. Each bipolar hypervector [symbol] · [symbol] (see Equation (1-2) or FIG. 1) constituting the encoding [symbol] is random and identically distributed, hence according to the central limit theorem [symbol] is approximately [symbol] normally distributed with μ=0 and σ²=Dᵢᵥ, i.e., the number of vectors building [symbol] . In [symbol] norm, however, the absolute value of the encoded [symbol] matters. Since [symbol] has normal distribution, mean of the corresponding folded (absolute) distribution is:

$${μ}_{\vert \vec{ℋ} \vert} = σ \sqrt{\frac{2}{π}} {e}^{- \frac{{μ}^{2}}{2 {σ}^{2}}} + μ ( 1 - Φ ( - \frac{μ}{σ} ) ) = \sqrt{\frac{2 {𝒟}_{iv}}{π}} \qquad ( 1 \text{-} 11 )$$

The [symbol] sensitivity will therefore be

$$Δ f = {‖ \vec{ℋ} ‖}_{1} = √ \frac{2 {𝒟}_{iv}}{π} \cdot {𝒟}_{hv} .$$

For the [symbol] sensitivity we indeed deal with a squared Gaussian (chi-squared) distribution with freedom degree of one, thus:

$$Δ f = {‖ \vec{ℋ} ‖}_{2} = \sqrt{{𝒟}_{hv} \cdot {μ}^{′}} = \sqrt{{𝒟}_{hv} \cdot {σ}^{2}} = \sqrt{{𝒟}_{hv} \cdot {𝒟}_{iv}} \qquad ( 1 \text{-} 12 )$$

Note that the mean of the chi-squared distribution (μ′) is equal to the variance (σ²) of the original distribution of [symbol] . Both Equation (1-11) and (1-12) imply a large noise to guarantee privacy. For instance, for a modest 200-features input (Dᵢᵥ=200) the [symbol] sensitivity is 10³\sqrt{2} while a proportional noise will annihilate the model accuracy. In the following, we describe techniques to shrink the variance of the required noise.

### 1-III.2.1 Model Pruning.

An immediate observation from Equation (1-12) is to reduce the number of hypervectors dimension, Dₕᵥ to mollify the sensitivity, hence, the required noise. Not all the dimensions of a class hypervector have the same impact on prediction. Remember, from Equation (1-4), that prediction is realized by a normalized dot-product between the encoded query and class hypervectors. Intuitively, we may prune out the close-to-zero class elements as their element-wise multiplication with query elements leads to less-effectual results. Notice that this concept (i.e., discarding a major portion of the weights without significant accuracy loss) does not readily hold for deep neural networks as the impact of those small weights might be amplified by large activations of previous layers. In HD, however, information is uniformly distributed over the dimensions of the query hypervector, so overlooking some of the query's information (the dimensions corresponding to discarded less-effectual dimensions of class hypervectors) should not cause unbearable accuracy loss.

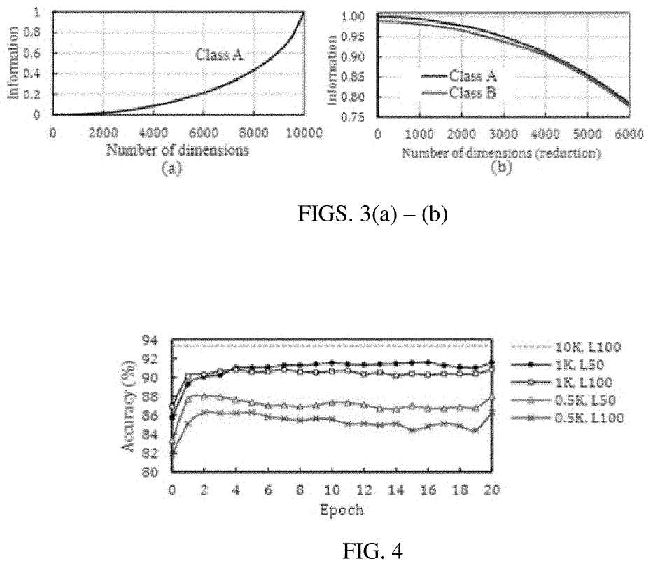

We demonstrate the model pruning as an example in FIG. 3 (that belongs to a speech recognition dataset). In FIG. 3a, after training the model, we remove all dimensions of a certain class hypervector. Then we increasingly add (return) its dimensions starting from the less-effectual dimensions. That is, we first restore the dimensions with (absolute) values close to zero. Then we perform a similarity check (i.e., prediction of a certain query hypervector via normalized dot-product) to figure out what portion of the original dot-product value is retrieved. As it can be seen in the same figure, the first 6,000 close-to-zero dimensions only retrieve 20% of the information required fora fully confident prediction. This is because of the uniform distribution of information in the encoded query hypervector: the pruned dimensions do not correspond to vital information of queries. FIG. 3b further clarifies our observation. Pruning the less-effectual dimensions slightly reduces the prediction information of both class A (correct class, with an initial total of 1.0) and class B (incorrect class). As more effectual dimensions of the classes are pruned, the slope of information loss plunges. It is worthy of note that in this example the ranks of classes A and B have been retained.

We augment the model pruning by retraining explained in Equation (1-5) to partially recover the information of the pruned dimensions in the remaining ones. For this, we first nullify s % of the close-to-zero dimensions of the trained model, which perpetually remain zero. Therefore, during the encoding of query hypervectors, we do not anymore need to obtain the corresponding indexes of queries (note that operations are dimension-wise), which translates to reduced sensitivity. Thereafter, we repeatedly iterate over the training dataset and apply Equation (1-5) to update the classes involved in mispredictions. FIG. 4 shows that 1-3 iteration(s) is sufficient to achieve the maximum accuracy (the last iteration in the figure shows the maximum of all the previous epochs). In lower dimension, decreasing the number of levels ( [symbol] in Equation (1-1), denoted by L in the legend), achieves slightly higher accuracy as hypervectors lose the capacity to embrace fine-grained details.

1-III.2.2 Encoding Quantization. Previous work on HD computing have introduced the concept of model quantization for compression and energy efficiency, where both encoding and class hypervectors are quantized at the cost of significant accuracy loss. We, however, target quantizing the encoding hypervectors since the sensitivity is merely determined by the [symbol] norm of encoding. Equation (1-13) shows the 1-bit quantization of encoding in (1-2a). The original scalar-vector product, as well as the accumulation, is performed in full-precision, and only the final hypervector is quantized. The resultant class hypervectors will also be non-binary (albeit with reduced dimension values).

$${\vec{ℋ}}_{q 1} = sign ( {\sum }_{k = 0}^{{𝒟}_{iv} - 1} {\vert {v}_{k} \vert}_{∈ ℱ} \cdot {\vec{ℬ}}_{k} ) \qquad ( 1 \text{-} 13 )$$

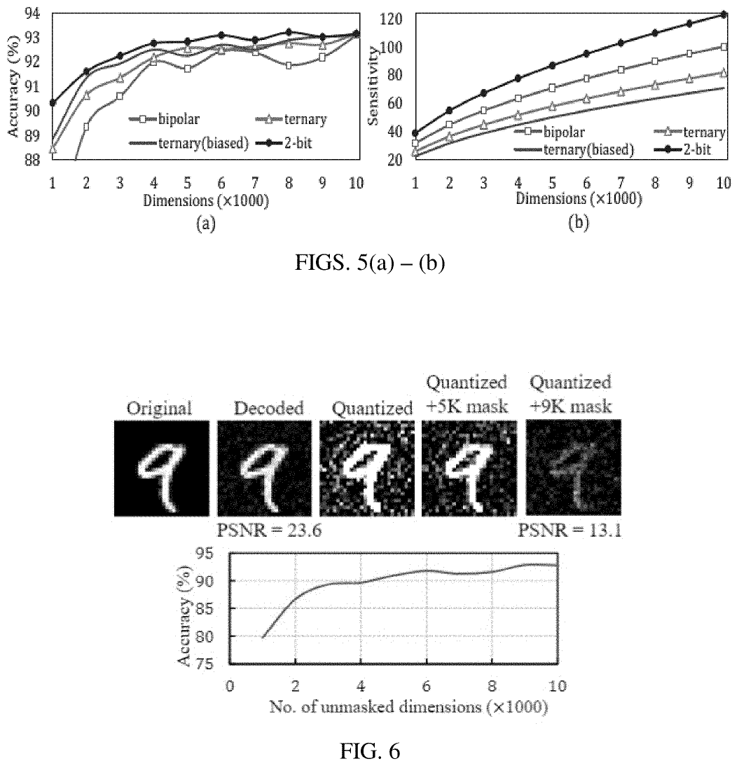

FIG. 5 shows the impact of quantizing the encoded hypervectors on the accuracy and the sensitivity of the same speech recognition dataset trained with such encoding. In 10,000 dimensions, the bipolar (i.e., ± or sign) quantization achieves 93.1% accuracy while it is 88.1% in previous work. This improvement comes from the fact that we do not quantize the class hypervectors. We then leveraged the afore-mentioned pruning approach to simultaneously employ quantization and pruning, as demonstrated in FIG. 5a. In Dₕᵥ=1000, the 2-bit quantization ({−2, ±1, 0}) achieves 90.3% accuracy, which is only 3% below the full-precision full-dimension baseline. It should note be noted that the small oscillations in specific dimensions, e.g., lower accuracy in 5,000 dimensions compared to 4,000 dimensions in bipolar quantization, are due to randomness of the initial hypervectors and non-orthogonality that show up in smaller space.

FIG. 5(b) shows the sensitivities of the corresponding models. After quantizing, the number of features, Dᵢᵥ (see Equation (1-12)), does not matter anymore. The sensitivity of a quantized model can be formulated as follows.

$$Δ f = {‖ \vec{ℋ} ‖}_{2} = {( {\sum }_{k ∈ \vert q \vert} {p}_{k} \cdot {𝒟}_{hv} \cdot {k}^{2} )}^{1 / 2} \qquad ( 1 \text{-} 14 )$$

Pk shows the k (e.g., ±1) in the quantized encoded hypervector, so Pₖ· [symbol] ₕᵥ is the total occurrence of k quantized encoded hypervector. The rest is simply the definition of [symbol] norm. As hypervectors are randomly generated and i.i.d, the distribution of kϵ|q| is uniform. That is, in the bipolar quantization, roughly Dₕᵥ/² of encoded dimensions are 1 (or −1). We therefore also exploited a biased quantization to give more weight for p₀ in the ternary quantization, dubbed as ‘ternary (biased)’ in FIG. 5b. Essentially the biased quantization assigns a quantization threshold to conform to p−1=p₁=¼, while p₀=½. This reduces the sensitivity by a factor of

$$\frac{\sqrt{\frac{{𝒟}_{hv}}{4} + \frac{{𝒟}_{hv}}{4}}}{\sqrt{\frac{{𝒟}_{hv}}{3} + \frac{{𝒟}_{hv}}{3}}} = 0.87 \times .$$

Combining quantization and pruning, we could shrink the [symbol] sensitivity to Δƒ=22.3, which originally was \sqrt{10⁴·617}=2484 for the speech recognition with 617-features inputs.

### 1-III.3. Inference Privacy

Thanks to the multi-layer structure of ML, IoT devices mostly rely on performing primary (e.g., feature extraction) computations on the edge (or edge server) and offload the decision-making final layers to the cloud. To tackle the privacy challenges of offloaded inference, previous work on DNN-based inference generally inject noise on the offloaded computation. This necessitates either to retrain the model to tolerate the injected noise (of a particular distribution), or analogously, learn the parameters of a noise that maximally perturbs the information with preferably small impact on the accuracy.

We described how the original feature vector can be reconstructed from the encoding hypervectors. Inspired by the encoding quantization technique explained in the previous section, we introduce a turnkey technique to obfuscate the conveyed information without manipulating or even accessing the model. Indeed, we observed that quantizing down to 1-bit (bipolar) even in the presence of model pruning could yield acceptable accuracy. As shown in FIG. 5a, 1-bit quantization only incurred 0.25% accuracy loss. Those models, however, were trained by accumulating quantized encoding hypervectors. Intuitively, we expect that performing inference with quantized query hypervectors on full-precision classes (class hyper-vectors generated by non-quantized encoding hypervectors) should give the same or better accuracy as quantizing is nothing but degrading the information. In other words, in the previous case, we deal with checking the similarity of a degraded query with classes built up also from degraded information, but now we check the similarity of a degraded query with information-rich classes.

Therefore, instead of sending the raw data, we propose to perform the light-weight encoding part on the edge and quantize the encoded vector before offloading to the remote host. We call it inference quantization to distinguish between encoding quantization, as inference quantization targets a full-precision model. In addition, we also nullify a specific portion of encoded dimensions, i.e., mask out them to zero, to further obfuscate the information. Remember that our technique does not need to modify or access to the trained model.

FIG. 6 shows the impact of inference 1-bit quantization on the speech recognition model. When only the offloaded information (i.e., query hypervector with 10,000 dimensions) is quantized, the prediction accuracy is 92.8%, which is merely 0.5% lower than the full-precision baseline. By masking out 5,000 dimensions, the accuracy is still above 91%, while the reconstructed image becomes blurry. While the recon-structed image (from a typical encoded hypervector) has a PSNR of 23.6 dB, in our technique, it shrinks to 13.1.

### 1-III.4 Hardware Optimization

The bit-level operations involved in the disclosed techniques and dimension-wise parallelism of the computation makes FPGA a promising platform to accelerate privacy-aware HD computing. We derived efficient implementations to further improve the performance and power. We adopted the encoding of Equation 1-2b as it provides better optimization opportunity.

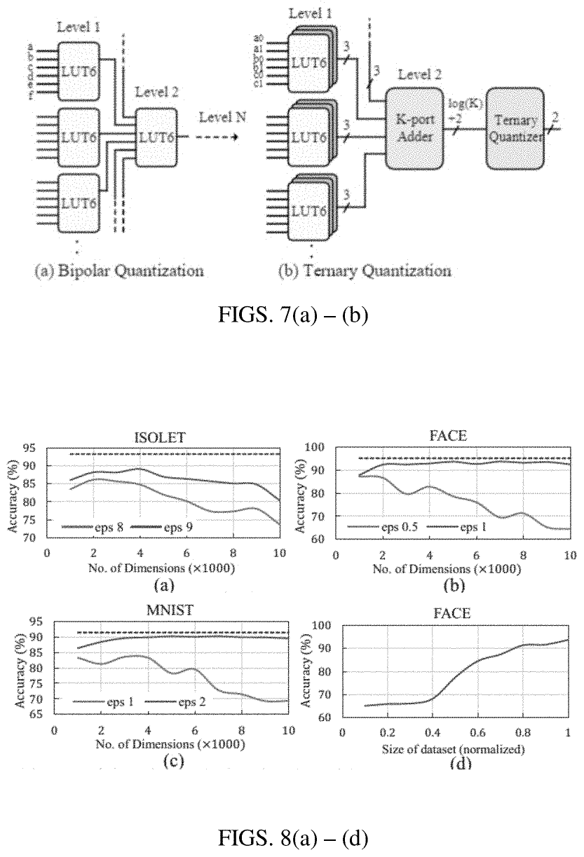

For the 1-bit bipolar quantization, a basic approach is adding up all bits of the same dimension, followed by a final sign/threshold operation. This is equivalent to a majority operation between ‘−1’s and ‘+1’s. Note that we can represent −1 by 0, and +1 by 1 in hardware, as it does not change the logic. We shrink this majority by approximating it as partial majorities. As shown by FIG. 7a, we use 6-input look-up tables (LUT-6) to obtain the majority of every six bits (out of _{div} bits), which are binary elements making a certain dimension. In the case an LUT has equal number of 0 and 1 inputs, it breaks the tie randomly (predetermined). We can repeat this until log _{div} stages but that would degrade accuracy. Thus, we use majority LUTs in the first stage, so the next stages are typical adder-tree. This approach is not exact, however, in practice it imposes <1% accuracy loss due to inherent error tolerance of HD, especially we use majority LUTs only in the first stage, so the next stages are typical adder-tree. Total number of LUT-6s will be:

$${n}_{LUT 6} = \frac{{d}_{iv}}{6} + \frac{1}{6} ( {\sum }_{i = 1}^{log {d}_{iv}} \frac{{d}_{iv}}{3} \times \frac{i}{{2}^{i - 1}} ) ≃ \frac{7}{18} {d}_{iv}$$

which is 70.8% less than 4/3 dᵢᵥ required in the exact adder-tree implementation.

For the ternary quantization, we first note that each dimension can be {0, ±1}, so requires two bits. The minimum (maximum) of adding three dimensions is therefore −3 (+3), which requires three bits, while typical addition of three 2-bit values requires four bits. Thus, as shown in FIG. 7b, we can pass numbers (dimensions) a̅₁̅a̅₀̅, b̅₁̅b̅₀̅ and c̅₁̅c̅₀̅ to three LUT-6 to produce the 3-bit output. Instead of using an exact adder-tree to sum up the resultant dᵢᵥ/3 three-bits, we use saturated adder-tree where the intermediate adders maintain a bit-width of three through truncating the least-significant bit of output. In a similar fashion to Equation (15), we can show that this technique uses about 2 div LUT-6, saving 33.3% compared to about 3 div in the case of using exact adder-tree to sum up _{div} ternary values.

### 1-IV. Results

### 1-IV.1. Differentially Private Training

We evaluated the privacy metrics of the disclosed techniques by training three models on different categories: a speech recognition dataset (ISOLET), the MNIST handwritten digits dataset, and Caltech web faces dataset (FACE). The goal of training evaluation is to find out the minimum ε with affordable impact on accuracy. We set the δ parameter of the privacy to 10⁻⁵ (which is reasonable especially the size of our datasets are smaller than 10⁵). Accordingly, for a particular ε, we can obtain the σ factor of the required Gaussian noise (see Equation (1-8)) from

$$δ \geq \frac{4}{5} {e}^{- \frac{{( σ ɛ )}^{2}}{2}} .$$

We iterate over different values of a to find the minimum while the prediction accuracy remains acceptable.

FIGS. 8a-c) shows the obtained e for each training model and corresponding accuracy. For instance, for the FACE model (FIG. 8b), ε=1 (labeled by eps1) gives an accuracy within 1.4% of the non-private full-precision model. Shown by the same figure, slightly reducing ε to 0.5 causes significant accuracy loss. This figure also reveals where the minimum ε is obtained. For each ε, using the disclosed pruning and ternary quantization, we reduce the dimension to decrease the sensitivity. At each dimension, we inject a Gaussian noise with standard deviation of Δƒ·σ with σ obtainable from

$$δ = {10}^{- 5} = \frac{4}{5} {e}^{- \frac{{( σ ɛ )}^{2}}{2}} ,$$

which is ˜4.75 for a demanded ε=1. Δƒ of different quantization schemes and dimensions is already discussed and shown by FIG. 5. When the model has large number of dimensions, its primary accuracy is better, but on the other hand has higher sensitivity (∝ [symbol] ). Thus, there is a trade-off between dimension reduction to decrease sensitivity (hence, noise) and inherent accuracy degradation associated with dimension reduction itself. For FACE model, we see that optimal number of dimensions to yield the minimum ε is 7,000. It should be noted that although there is no prior work on HD privacy (and few works on DNN training privacy) for a head-to-head comparison, we could obtain a single digit ε=2 for the MNIST dataset with ˜1% accuracy loss (with 5,000 ternary dimensions), which is comparable to the differentially private DNN training over the MNIST in that achieved the same ε with ˜4% accuracy loss. In addition, differentially private DNN training requires very large number of training epochs where the per-epoch training time also increases (e.g., by 4.5×) while we readily apply the noise after building up all class hypervectors. We also do not retrain the noisy model as it violates the concept of differential privacy.

FIG. 8d shows the impact of training data size on the accuracy of the FACE differentially private model. Obviously, increasing the number of training inputs enhances the model accuracy. This due to the fact that, because of quantization of encoded hypervectors, the class vectors made by their bundling have smaller values. Thus, the magnitude of induced noise becomes comparable to the class values. As more data is trained, the variance of class dimensions also increases, which can better bury the same amount of noise. This can be considered a vital insight in privacy-preserved HD training.

### 1-IV.2. Privacy-Aware Inference

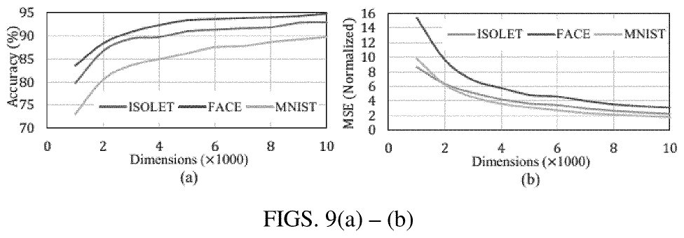

FIG. 9a shows the impact of bipolar quantization of encoding hypervectors on the prediction accuracy. As discussed, here we quantize the encoded hypervectors (to be offloaded to cloud for inference) while the class hypervectors remain intact. Without pruning the dimensions, the accuracy of ISOLET, FACE, and MNIST degrades by 0.85% on average, while the mean squared error of the reconstructed input increases by 2.36×, compared to the data reconstructed (decoded) from conventional encoding. Since the dataset of ISOLET and FACE are extracted features (rather than raw data), we cannot visualize them, but from FIG. 9b we can observe that ISOLET gives a similar MSE error to MNIST (for which the visualized data can be seen in FIG. 6) while the FACE dataset leads to even higher errors.

TABLE 1-I
Efficiency of the baseline and PriveHD on FPGA

| | Raspberry Pi | | GPU | | Prive-HD (FPGA) | |
|---|---|---|---|---|---|---|
| | Throughput | Energy | Throughput | Energy | Throughput | Energy |
| ISOLET | 19.8 | 0.155 | 135,300 | 8.9 × 10⁻¹ | 2,500,000 | 2.7 × 10⁻⁶ |
| FACE | 11.9 | 0.266 | 104,079 | 1.2 × 10⁻³ | 694,444 | 4.7 × 10⁻⁶ |
| MNIST | 23.9 | 0.129 | 140,550 | 8.5 × 10⁻⁴ | 3,125,000 | 3.0 × 10⁻⁶ |

In conjunction with quantizing the offloaded inference, as discussed before, we can also prune some of the encoded dimensions to further obfuscate the information. We can see that in the ISOLET and FACE models, discarding up to 6,000 dimensions leads to a minor accuracy degradation while the increase of their information loss (i.e., increased MSE) is considerable. In the case of MNIST, however, accuracy loss is abrupt and does not allow for large pruning. However, even pruning 1,000 of its dimensions (together with quantization) reduces the PSNR to ˜15, meaning that reconstruction of our encoding is highly lossy.

### 1-IV.3. FPGA Implementation

We implemented the HD inference using the proposed encoding with the optimization detailed in Section 1-III-D. We implemented a pipelined architecture with building blocks shown in FIG. 7a as in the inference we only used binary (bipolar) quantization. We used a hand-crafted design in Verilog HDL with Xilinx primitives to enable efficient implementation of the cascaded LUT chains. Table 1-I compares the results of Prive-HD on Xilinx Kintex-7 FPGA KC705 Evaluation Kit, versus software implementation on Raspberry Pi 3 embedded processor and NVIDIA GeForce GTX 1080 Ti GPU. Throughout denotes number of inputs processed per second, and energy indicates energy (in Joule) of processing a single input. All benchmarks have the same number of dimensions in different platforms. For FPGA, we assumed that all data resides in the off-chip DRAM, otherwise the latency will be affected but throughout remains intact as off-chip latency is eliminated in the computation pipeline. Thanks to the massive bit-level parallelism of FPGA with relatively low power consumption (˜7 W obtained via Xilinx Power Estimator, compared to 3 W of Raspberry Pi obtained by Hioki 3334 power meter, and 120 W of GPU obtained through NVIDIA system management interface), the average inference throughput of Prive-HD is 105,067× and 15.8× of Raspberry Pi and GPU, respectively. Prive-HD improves the energy by 52,896× and 288× compared to Raspberry Pi and GPU, respectively.

As described above, a privacy-preserving training scheme can be provided by quantizing the encoded hypervectors involved in training, as well as reducing their dimensionality, which together enable employing differential privacy by relieving the required amount of noise. We also showed that we can leverage the same quantization approach in conjunction with nullifying particular elements of encoded hyper-vectors to obfuscate the information transferred for untrust worthy cloud (or link) inference. We also disclosed hardware optimization for efficient implementation of the quantization schemes by essentially using approximate cascaded majority operations. Our training technique could address the discussed challenges of HD privacy and achieved single-digit privacy metric. Our disclosed inference, which can be readily employed in a trained HD model, could reduce the PSNR of an image dataset to below 15 dB with affordable impact on accuracy. Finally, we implemented the disclosed encoding on an FPGA platform which achieved 4.1×energy efficiency compared to existing binary techniques.

### Part 2: HvperRec: Recommendation System Using Hyperdimensional Computing

As further appreciated by the present inventors, recommender systems are ubiquitous. Online shopping websites use recommender systems to give users a list of products based on the users' preferences. News media use recommender systems to provide the readers with the news that they may be interested in. There are several issues that make the recommendation task very challenging. The first is that the large volume of data available about users and items calls for a good representation to dig out the underlying relations. A good representation should achieve a reasonable level of abstraction while providing minimum resource consumption. The second issue is that the dynamic of the online markets calls for fast processing of the data.

Accordingly, in some embodiments, a new recommendation technique can be based on hyperdimensional computing, which is referred to herein as HyperRec. In HyperRec, users and items are modeled with hyperdimensional binary vectors. With such representation, the reasoning process of the disclosed technique is based on Boolean operations which is very efficient. In some embodiments, methods may decrease the mean squared error by as much as 31.84% while reducing the memory consumption by about 87%.

### 2-I. Introduction

Online shopping websites adopt recommender systems to present products that users will potentially purchase. Due to the large volume of products, it is a difficult task to predict which product to recommend. A fundamental challenge for online shopping companies is to develop accurate and fast recommendation algorithms. This is vital for user experience as well as website revenues. Another fundamental fact about online shopping websites is that they are highly dynamic composites. New products are imported every day. People consume products in a very irregular manner. This results in continuing changes of the relations between users and items.

Traditional recommendation algorithms can be roughly categorized into two threads. One is the neighbor-based method that tries to find the similarity between users and between items based on the ratings. The other is latent-factor based methods. These methods try to represent users and items as low-dimensional vectors and translate the recommendation problem into a matrix completion problem. The training procedures require careful tuning to escape local minima and need much space to store the intermediate results. Both of the methods are not optimized for hardware acceleration.

In some embodiments, users, items and ratings can be encoded using hyperdimensional binary vectors. In some embodiments, reasoning process of HyperRec can use only Boolean operations, the similarities are computed based on the Hamming distance. In some embodiments, HyperRec may provide the following (among other) advantages:

HyperRec is based on hyperdimensional computing. User and item information can be preserved nearly loseless for identifying similarity. It is a binary encoding method and only relies on Boolean operations. The experiments on several large datasets such as Amazon datasets demonstrate that the disclosed method is able to decrease the mean squared error by as much as 31.84% while reducing the memory consumption by about 87%.

Hardware friendly: Since the basic operations of hyperdimensional vectors are component-wise operations and associative search, this design can be accelerated in hardware.

Ease of interpretation: Due to the fact that the encodings and computations of the disclosed method are based on geometric intuition, the prediction process of the technique has a clear physical meaning to diagnose the model.

### 2-II. Landscape of HyperRec

Recommender systems: The emergence of the e-commerce promotes the development of recommendation algorithms. Various approaches have been proposed to provide better product recommendations. Among them, collaborative filtering is a leading technique which tries to recommend the user with products by analyzing similar users' records. We can roughly classify the collaborative filtering algorithms into two categories: neighbor-based methods and latent-factor methods. Neighbor-based methods try to identify similar users and items for recommendation. Latent-factor models use vector representation to encode users and items, and approximate the rating that a user will give to an item by the inner product of the latent vectors. To give the latent vectors probabilistic interpretations, Gaussian matrix factorization models were proposed to handle extremely large datasets and to deal with cold-start users and items. Given the massive amount of data, developing hardware friendly recommender systems becomes critical.

Hyperdimensional computing: Hyperdimensional computing is a brain-inspired computing model in which entities are represented as hyperdimensional binary vectors. Hyperdimensional computing has been used in analogy-based reasoning, latent semantic analysis, language recognition, prediction from multimodal sensor fusion, hand gesture recognition and brain-computer interfaces.

The human brain is more capable of recognizing patterns than calculating with numbers. This fact motivates us to simulate the process of brain's computing with points in high-dimensional space. These points can effectively model the neural activity patterns of the brain's circuits. This capability makes hyperdimensional vectors very helpful in many real-world tasks. The information that contained in hyperdimensional vectors is spread uniformly among all its components in a holistic manner so that no component is more responsible to store any piece of information than another. This unique feature makes a hypervector robust against noises in its components. Hyperdimensional vectors are holographic, (pseudo)random with i.i.d. components.

A new hypervector can be based on vector or Boolean operations, such as binding that forms a new hypervector which associates two base hypervectors, and bundling that combines several hypervectors into a single composite hypervector. Several arithmetic operations that are designed for hypervectors include the following.

Component-wise XOR: We can bind two hypervectors A and B by component-wise XOR and denote the operation as A⊗B. The result of this operation is a new hypervector that is dissimilar to its constituents (i.e., d(A⊗B;A)≈D/2), where d( ) is the Hamming distance; hence XOR can be used to associate two hypervectors.

Component-wise majority: bundling operation is done via the component-wise majority function and is denoted as [A+B+C]. The majority function is augmented with a method for breaking ties if the number of component hypervectors is even. The result of the majority function is similar to its constituents, i.e., d([A+B+C];A)<D/2. This property makes the majority function well suited for representing sets.

Permutation: The third operation is the permutation operation that rotates the hypervector coordinates and is denoted as r(A). This can be implemented as a cyclic right-shift by one position in practice. The permutation operation generates a new hypervector which is unrelated to the base hypervector, i.e., d(r(A);A)>D/2. This operation is usually used for storing a sequence of items in a single hypervector. Geometrically, the permutation operation rotates the hypervector in the space. The reasoning of hypervectors is based on similarity. We can use cosine similarity, Hamming distance or some other distance metrics to identify the similarity between hypervectors. The learned hypervectors are stored in the associative memory. During the testing phase, the target hypervector is referred as the query hypervector and is sent to the associative memory module to identify its closeness to other stored hypervectors.

Traditional recommender systems usually encode users and items as low-dimensional full-precision vectors. There are two main drawbacks of this approach. The first is that the user and item profiles cannot be fully exploited due to the low dimensionality of the encoding vectors and it is unclear how to choose a suitable dimensionality. The second is that the traditional approach consumes much more memory by representing user and item vectors as full-precision numbers, and this representation is not suitable for hardware acceleration.

In some embodiments, users and items are stored as binary numbers which can save the memory by orders of magnitude and enable fast hardware implementations.

TABLE 2-I
Notations used in this Part:

| Notations | Description |
|---|---|
| U | number of users |
| V | number of items |
| R | the maximum rating value |
| u | individual user |
| v | individual item |
| r | individual rating |
| D | number of dimensions of hypervectors |
| rᵤᵥ | rating given by user u for item v |
| \hat{r}ᵤᵥ | predicted rating of user u for item v |
| Hᵤ | D-dimensional hypervector of user u |
| Hᵥ | D-dimensional hypervector of item v |
| Hᵣ | D-dimensional hypervector of rating r |
| Bᵤ | the set of items bought by user u |
| Bᵥ | the set of users who bought the item v |
| N^{k}(v) | the k-nearest items of item v |
| N^{k}(u, v) | the k-nearest users of user u in the set Bᵥ |
| μᵤ | bias parameter of user μ |
| μᵥ | bias parameter of item v |

### 2-III. HyperRec

### 2.III.1. Overview

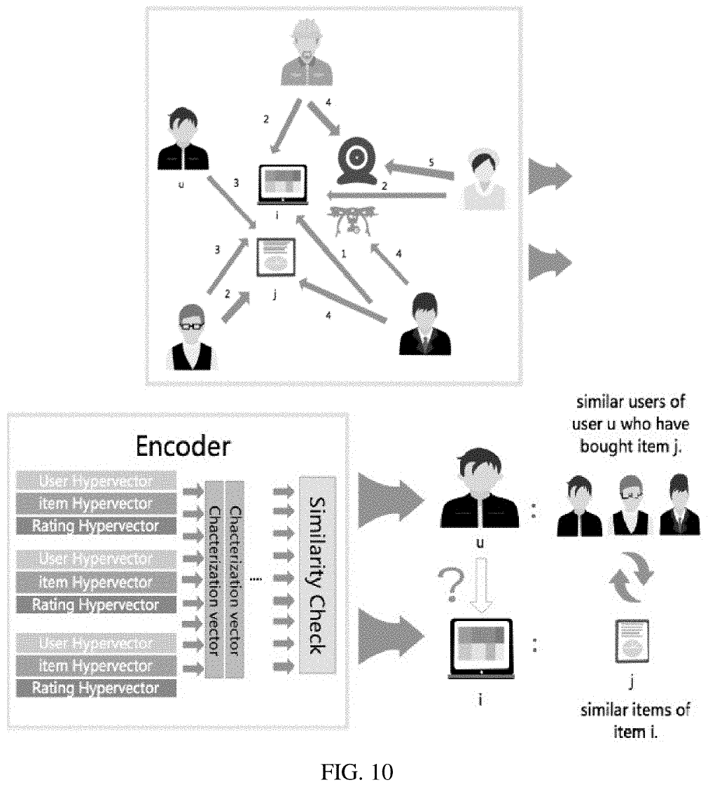

In some embodiments, HyperRec provides a three-stage pipeline: encoding, similarity check and recommendation. In HyperRec, users, items and ratings are included with hyperdimensional binary vectors. This is very different from the traditional approaches that try to represent users and items with low-dimensional full-precision vectors. In this manner users' and items' characteristics are captured and enable fast hardware processing. Next, the characterization vectors for each user and item are constructed, then the similarities between users and items are computed. Finally, recommendations are made based on the similarities obtained in the second stage. The overview of the framework is shown in FIG. 10. The notations used herein are listed in Table 2-I.

### 2-III.2. HD Encoding

All users, items and ratings are included using hyperdimensional vectors. Our goal is to discover and preserve users' and items' information based on their historical interactions. For each user u and item v, we randomly generate a hyperdimensional binary vector, Hᵤ=random_binary(D) Hᵥ=random_binary(D)

Where random_binary( ) is a (pseudo)random binary sequence generator which can be easily implemented by hardware. However, if we just randomly generate a hypervector for each rating, we lose the information that consecutive ratings should be similar. Instead, we first generate a hypervector filled with ones for rating 1. Having R as the maximum rating, to generate the hypervector for rating r, we flip the bits between

$$( r - 2 ) \frac{D}{R} and ( r - 1 ) \frac{D}{R}$$

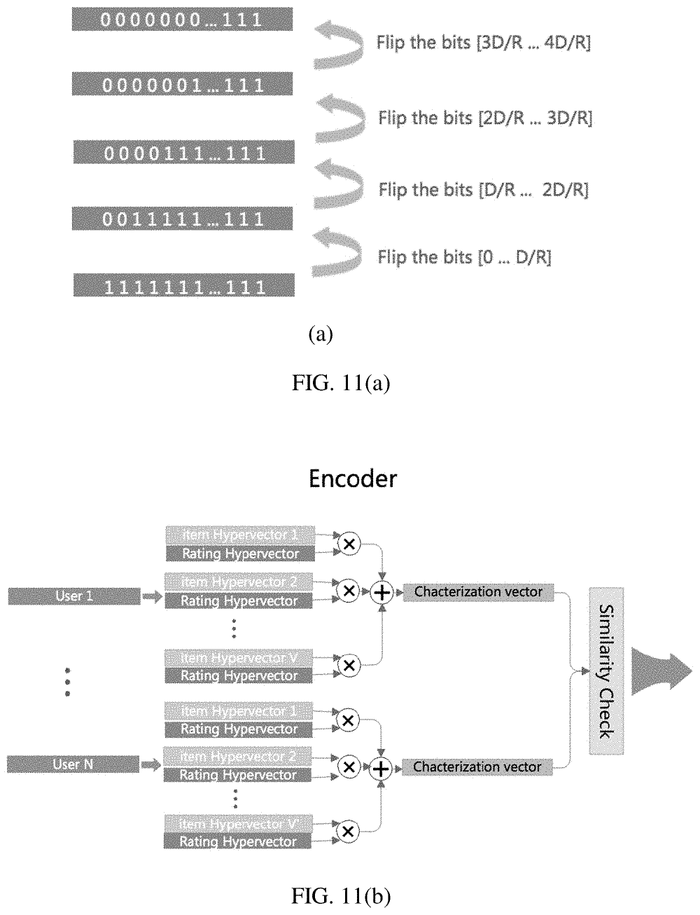

of the hypervector of rating r−1 and assign the resulting vector to rating r. The generating process of rating hypervectors is shown in FIG. 11a. By this means, consecutive ratings are close in terms of Hamming distance. If two ratings are numerically different from each other by a large margin, the Hamming distance between their hypervectors is large. We compute the characterization hypervector of each user and each item as follows:

$${C}_{u} = {[ {H}_{{r}_{{uv}_{1}}} ⊗ {H}_{{v}_{1}} + … + {H}_{{r}_{{uv}_{n}}} ⊗ {H}_{{v}_{n}} ]}_{\{ {v}_{1} , … , {v}_{n} ∈ {B}_{u} \}}$$

$${C}_{v} = {[ {H}_{{r}_{{u}_{1} v}} ⊗ {H}_{{u}_{1}} + … + {H}_{{r}_{{u}_{n} v}} ⊗ {H}_{{u}_{n}} ]}_{\{ {u}_{1} , … , {u}_{n} ∈ {B}_{v} \}}$$

Where ⊗ is the XOR operator and [A+ . . . +B] is the component-wise majority function. The process is shown in FIG. 11b. By this approach, we can capture the difference between users' consuming behaviors and their rating patterns. For instance, if two users u and u′ bought the same item and rated it similarly, the Hamming distance between their characterization hypervectors will be small. We keep the last D/R bits of all rating hypervectors the same, so if two users rated the same item very differently, the Hamming distance between their characterization vectors will still be closer than the users who have no relation. This encoding has a number of advantages. Due to the high dimensionality of hypervectors we can preserve the information about users and items as much as possible in the characterization hypervectors. The representation is robust against noises which is important for identifying similar users. Meanwhile, this encoding approach enables fast hardware implementation because it only relies on Boolean operations.

### 2-III.3. Recommending Products

After we obtain the characterization hypervectors of users and items, we use Hamming distance to identify similarity. In order to compute the rating that user u will give to item v, we first identify the k-nearest items of item v based the ratings they received and denote this set as N^{k}(v). For each of the k-nearest item v′∈N^{k}(v), we also identify k′-nearest users of user u in the set B_{v′}, based on the ratings they give, and denote this as N^{k′}(u, v′). Then we compute the predicted rating of user u for item v′ as follows:

$${\hat{r}}_{{uv}^{′}} = {μ}_{u} + \frac{{\sum }_{{u}^{′} ∈ {N}^{{k}^{′}} ( u , {v}^{′} )} ( 1 - dist ( u , {u}^{′} ) ) ( {r}_{{u}^{′} {v}^{′}} - {μ}_{{u}^{′}} )}{C} \qquad ( 2 \text{-} 1 )$$

Where ⊗ is the normalization factor which is Σ_{u′∈N}_{^{k′}}_{(u,v′)}(1−dist(u,u′)) And dist(u,u′) is the normalized Hamming distance between the characterization vectors of users u and u′. Then, we compute the predicted rating of user u for item v as;

$${\hat{r}}_{uv} = {μ}_{v} + {\sum }_{{v}^{′} ∈ {N}^{k} ( v )} ( 1 - dist ( v , {v}^{′} ) ) ( {\hat{r}}_{{uv}^{′}} - {μ}_{{v}^{′}} ) \qquad ( 2 - 2 )$$

Similarly, dist (v, v′) is the normalized Hamming distance between the characterization vector of item v and item v′. After we obtain the predicted ratings of user u for all the items he/she did not buy before, we can recommend the user u with the items with highest predicted ratings. HyperRec has the simplicity of neighbor-based methods and meanwhile utilizes the effectiveness of latent-factor based methods. It is fast since there is no training phase and the computation consists of only Boolean operations. Moreover, it is easily extendable and can be one of the building blocks of more complex techniques.

### 2-III.4. Empirical Studies

Experiments were performed using several real-world large datasets. The results show that the disclosed technique decreases the mean squared error by as much as 31.84% on the Amazon datasets and it only consumes approximately 13% of the memory compared with the state-of-the-art methods.

### 2-III.5. Datasets and Evaluation Protocol

We used datasets from Movielens, Amazon, FilmTrust and Yelp. The Movielens datasets contain thousands of ratings that users given to movies over various periods of time. For the movilens-10M, we randomly sample 10000 users and for each user we sample 5 items. Amazon datasets contain a variety of categories ranging from Arts to Sports. The FilmTrust dataset was crawled from the FilmTrust website in June, 2011 and is a relatively small dataset. Yelp dataset contains over 700000 ratings that users given to food and restaurants. The detailed statistics of the datasets are listed in Table 2-II.

### 2-III.6. Baselines

We compared our technique with several other prediction methods.

KNNBasic: A basic neighbor-based algorithm.

KNNWithMeans: A variation of KNNbasic algorithm which takes into account the mean ratings of each user.

SVD: This algorithm factorizes the user-item rating matrix, the predicted rating of user u for item v is,

$${\overline{r}}_{uv} = μ + {b}_{u} + {b}_{v} + {q}_{u}^{T} {p}_{v} \qquad ( 2 \text{-} 3. )$$

Where μ is the global bias, bᵤ is the user bias and bᵥ is the item bias. qᵤ and pᵥ is the latent user vector representation and latent item vector representation.

SVD++: SVD++ is an extension of SVD which also considers implicit ratings.

PMF: This is a matrix factorization algorithm for recommender systems.

NMF: This algorithm is similar to PMF except that it constraints the factors of user and items to be nonnegative.

SlopeOne: This is a simple item-based collaborative filtering algorithm. The predicted rating of user u for item i is

$${\overline{r}}_{ui} = {μ}_{u} + \frac{1}{card ( {R}_{i} )} {\sum }_{j ∈ {R}_{i}} dev ( i , j ) \qquad ( 2 \text{-} 4 )$$

Where Rᵢ is the set of relevant items of item i, i.e. the set of items j rated by u that also have at least one common user with i. And dev(i,j) is defined as the average difference between the ratings received by item i and the ratings received by item j.

Co-clustering. This algorithm clusters users and items based on their average ratings. The rating the user u give to item v can be computed as:

$${\overline{r}}_{uv} = {\overline{A}}_{uv} + ( {μ}_{u} - {\overline{A}}_{u} ) + ( {μ}_{v} - {\overline{A}}_{v} ) \qquad ( 2 \text{-} 5 )$$

Where Āᵤᵥ is the average rating of the co-cluster Aᵤᵥ, Āᵤ is the average rating of the cluster u, and Aᵥ is the average rating of the cluster v.

TABLE 2-II
Statistics of the datasets:

| | movielens-100K | movielens-1M | movielens-10M | FilmTrust | Yelp | Amazon |
|---|---|---|---|---|---|---|
| Users | 943 | 6,040 | 10,000 | 1,508 | 25,677 | 33,642 |
| Items | 1,682 | 3,706 | 4,424 | 2,071 | 25,815 | 19,605 |
| Observations | 100,000 | 1,000,209 | 349,390 | 35,497 | 731,671 | 112,053 |
| Average Rating | 3.53 | 3.58 | 3.55 | 2.80 | 3.75 | 4.18 |
| Sparseness | 6.30% | 4.47% | 0.79% | 1.64% | 0.11% | 0.02% |

TABLE 2-III
The mean squared error of all the algorithms on Movielens, Yelp and Filmtrust.

| | KNNBasic | KNNWithMeans | SVD | SVD++ | PMF | NMF | SlopeOne | Co Clustering | HyperRec |
|---|---|---|---|---|---|---|---|---|---|
| movielens-100K | 0.9811 | 0.9507 | 0.9357 | 0.9215 | 0.9502 | 0.9632 | 0.9442 | 0.9646 | 0.9649 |
| movielens-1M | 0.9335 | 0.9414 | 0.8920 | 0.8797 | 0.8734 | 0.9190 | 0.9045 | 0.9148 | 0.9195 |
| movielens-10M | 1.1597 | 1.1469 | 1.0088 | 1.0043 | 1.0966 | 1.1254 | 1.2100 | 1.1170 | 1.1030 |
| Yelp | 1.1065 | 1.0832 | 1.0703 | 1.0709 | 1.1550 | 1.1190 | 1.1048 | 1.0822 | 1.0604 |
| Filmtrust | 0.9232 | 0.9203 | 0.8996 | 0.8821 | 1.1562 | 0.9231 | 0.9378 | 0.9416 | 0.8806 |

TABLE 2-IV
The mean squared error of all the algorithms on Amazon.

| | KNNBasic | KNNWithMeans | SVD | SVD++ | PMF | NMF | SlopeOne | Co Clustering | HyperRec |
|---|---|---|---|---|---|---|---|---|---|
| Arts | 1.0380 | 0.9837 | 1.0467 | 1.0109 | 0.9445 | 1.1065 | 0.9897 | 1.0672 | 0.9320 |
| Tools | 1.1370 | 1.1233 | 1.0583 | 1.0437 | 1.1272 | 1.2208 | 1.1457 | 1.1265 | 1.1506 |
| Sports | 0.9874 | 0.9227 | 0.9681 | 0.9423 | 1.0917 | 1.0535 | 0.9311 | 0.9926 | 0.9108 |
| Musical | 1.0784 | 1.1568 | 1.0636 | 1.0593 | 1.0551 | 1.2772 | 1.1628 | 1.1903 | 1.2965 |
| Clothing | 0.7117 | 0.4768 | 0.7439 | 0.6849 | 0.7262 | 0.5961 | 0.4824 | 0.6362 | 0.3250 |
| Patio | 1.2455 | 1.2536 | 1.2178 | 1.2062 | 1.1965 | 1.3284 | 1.2716 | 1.2690 | 1.2805 |
| Office | 1.2241 | 1.1885 | 1.1788 | 1.1658 | 1.2815 | 1.2587 | 1.2026 | 1.2820 | 1.2527 |

### 2-III.7. Parameter Setting and Evaluations

We randomly selected 70% of ratings in each dataset as training dataset and 20% of ratings in each dataset as testing dataset. The rest 10% of ratings in each dataset are used to tune free parameters. For KNNBasic and KNNWithMeans, the number of neighbors is 40. For SVD, SVD++ and PMF, the dimension of the latent factors is 100. For NMF, the dimension of the latent factor is 20. The learning rate of SVD and PMF is 0.005. The learning rate of SVD++ is 0.007. For all the latent-factor based methods, the regularization parameters is 0.02 and the training epoch is 50. For the co-clustering algorithm, we choose the size of the cluster to be 3. For HyperRec, the dimension of the hypervectors is set to be 1000. The number of neighboring items is set to be 5 and the number o neighboring users is set to be 30. In the experiments, we used mean squared error (MS) to evaluate the performance of the algorithms.

TABLE 2-V
Memory and Time Complexity Analysis
of SVD++ and HyperRec.

| | Metrics | SVD++ | | Hyper Rec | |
|---|---|---|---|---|---|
| m1-100K | Time | 186.08 | s | 25.88 | s |
| | Memory | 27.56M | | 2.625M | |
| Arts | Time | 3.10 | s | 1.10 | s |
| | Memory | 23.24M | | 2.619M | |
| Clothing | Time | 43.50 | s | 40.99 | s |
| | Memory | 102.74M | | 13.03M | |
| Office | Time | 412.2 | s | 9.43 | s |

| | | |
|---|---|---|
| Memory | 73.32M | 7.66M |

### 2-III.8. Results Analysis

We list the experimental results of all the algorithms in Table 2-III, and Table 2-IV. The best result on each dataset is shown in bold. As we can see, HyperRec achieves the best results on about half of the datasets. This is surprising due to its simplicity compared with other methods. Compared with neighbor-based methods, our method can capture richer information about users and items, which can help us identify similar users and items easily. Compared with latent-factor based methods, HyperRec needs much less memory and is easily scalable. HyperRec stores users and items as binary vectors rather than full-precision numbers and only relies on Boolean operations. These unique properties make it very hardware-friendly so it can be easily accelerated.

### 2-III.9. Memory and Time Complexity Analysis

In this section, we compare the memory consumption and time complexity of HyperRec with SVD++. In SVD++, users and items are usually represented by one hundred dimension full-precision vectors. For each user, we need at least 3200 bits to store his/her latent features and 3200 bits to store the gradients that are used for optimization. In HyperRec, we need only 1000 bits to represent each user, which amounts to a factor of six of memory saving. More importantly, binary representations enable fast hardware acceleration. We compare the memory consumption and time complexity of HyperRec with SVD++ in Table 2-V on the four datasets of different sizes: m1-100k, Arts, Clothing and Office. All the experiments are run on a laptop with Intel Core i5 2.9 GHz, 8G RAM. As we can see, HyperRec consumes much less memory compared with SVD++, which is very important for devices that do not have enough memory. And on average, HyperRec is about 13.75 times faster than SVD++ on these four datasets, this fact is crucial for real-time applications.

### 2-III.10. High Dimensionality Helpful Affects

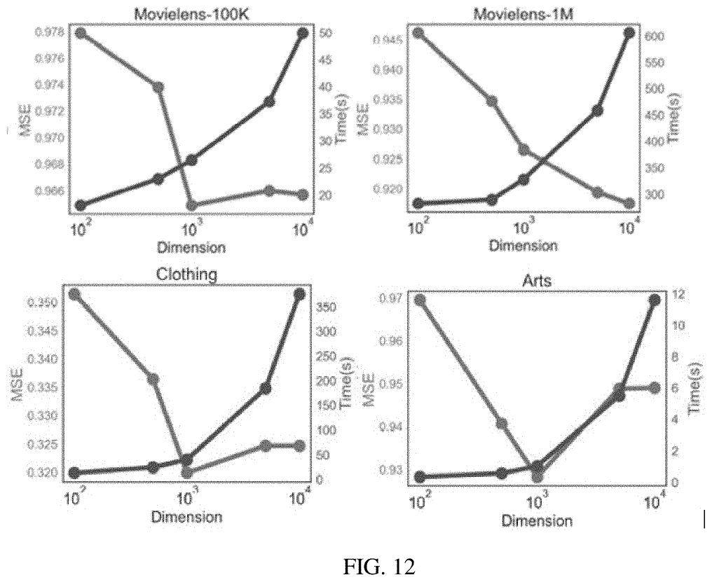

The dimensionality of the hypervectors has a notable impact on the performance of the technique. To examine how the size of dimensionality affects performance, we vary the dimensionality and examine the results of our model on three datasets: m1-100k, ml-1m and Clothing. As we can see from the FIG. 12. If we increase the dimensionality of the hypervectors from one hundred to one thousand, we can achieve a huge improvement in accuracy. The reason is that in high-dimensional space the vectors can store more information and they are more robust against errors. However, if we continue to enlarge the dimensionality to tens of thousands, accuracy tends to remain stable. One possible reason for this phenomenon is that for sparse datasets, a dimension as large as one thousand is enough to encode the necessary information. For denser datasets, we can enlarge the dimensionality accordingly to ensure the performance of the disclosed method.

### 2-III.11. Hardware Acceleration

Here we use a standard digital ASIC flow to design dedicated hardware for HyperRec. We describe the disclosed designs, in a fully parameterized manner, using RTL System-Verilog. For the synthesis, we use Synopsys Design Compiler with the FreePDK 45 nm technology library. We extract its switching activity during post-synthesis simulations in ModelSim by applying the test sentences. Finally, we measure their power consumption using Synopsys PrimeTime.

In digital, HyperRec encoding can be simply designed using three memory blocks. The first memory stores the item hyper-vectors, the second memory stores user hypervectors and the third memory is keeping rating hypervectors. For each user, our design reads the item hypervector and then accordingly fetches a rating hypervector. These hypervectors bind together element-wise using an XOR array. Then, these hypervectors add together over all dimensions using D adder block and generate a characterization vector for each user. In order to binarize the data point, each element in hypervector is compared to half of the hypervectors (say n). If the value in each coordinate overpasses n it sets the value of that dimension to 1, otherwise the value of that dimension stays ‘0’. Similarly, our method generates a characterization vector for each item. Note that encoding happens only once over data points, thus HyperRec does not need to pay the cost of encoding at runtime. Similarly, the search can perform using another XOR array followed by adder to count the number of mismatches and a tree-based comparator to find a vector with minimum mismatch. The multiplication between the bipolar hypervectors can be modeled in binary using XOR operation. Using this hardware, all item and rating hypervectors can bind in parallel for all users. After binding the item and rating hypervectors our design binarizes the vectors using comparator block.

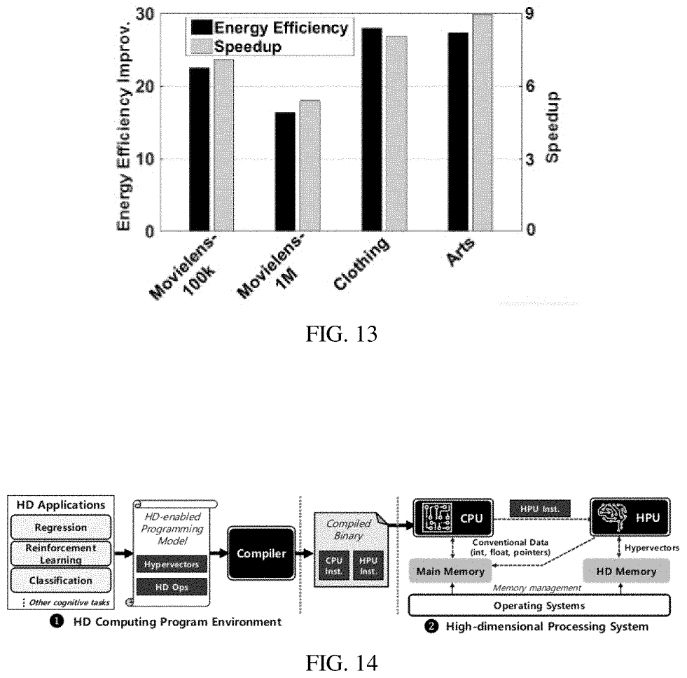

FIG. 13 compares the energy efficiency and performance speedup of the HyperRec (D=1000) running on the conventional core and ASIC design. Our results show that digital-based implementation can achieve 23.5× and 7.2× higher energy efficiency and speedup as compared to conventional cores.

### Part 3: Hyperdimensional Computer System Architecture and Exemplary Applications

As further appreciated by the present inventors, HDC is an efficient learning system that enables brain-inspired hyperdimensional computing (HDC) as a part of systems for cognitive tasks. HDC effectively mimics several essential functionalities of the human memory with high-dimensional vectors, allowing energy-efficient learning based on its massively parallel computation flow. We view HDC as a general computing method for machine learning and significantly enlarge applications to other learning tasks, including regression and reinforcement learning. On the disclosed system, user-level programs can implement diverse learning solutions using our augmented programming model. The core of the system architecture is the hyperdimensional processing unit (HPU), which accelerates the operations for high-dimensional vectors using in-memory processing technology with sparse processing optimization. We disclose how HPU can run as a general-purpose computing unit equipping specialized registers for high-dimensional vectors and utilize extensive parallelism offered by the in-memory processing. The experimental results show that the disclosed system efficiently processes diverse learning tasks, improving the performance and energy efficiency by 29.8′ and 173.9′ as compared to the GPU-based HDC implementation. We also disclose that the HDC can be a light-weight alternative to the deep learning, e.g., achieving 33.5′ speedup and 93.6′ energy efficiency improvement only with less than 1% accuracy loss, as compared to the state-of-the-art PIM-based deep learning accelerator.

### 3-I. Introduction

As appreciated by the present inventors, we face increasing needs of efficient processing for diverse cognitive tasks using a vast volume of data generated. However, running machine learning (ML) algorithms often results in extremely slow processing speed and high energy consumption on traditional systems, or needs a large cluster of application-specific integrated chips (ASIC), e.g., deep learning on TPU. Previous works have tried to accelerate the ML algorithms on emerging hardware technology, e.g., deep learning accelerators based on the processing in-memory (PIM) technique which utilizes the emerging resistive memory technology. However, the emerging memory devices have various reliability issues such as endurance, durability, and variability. Coupled with the high computational workloads of the ML algorithms, which create a large number of writes especially during training, it limits the applicability of the accelerators in practice.

Further, to achieve real-time performance with high energy efficiency and robustness, we need to rethink not only how we accelerate machine learning algorithms in hardware, but also, we need to redesign the algorithms themselves using strategies that more closely model the ultimate efficient learning machine: the human brain. Hyperdimensional Computing (HDC) is one such strategy developed by interdisciplinary research. It is based on a short-term human memory model, Sparse distributed memory, emerged from theoretical neuroscience. HDC is motivated by a biological observation that the human brain operates on a robust high-dimensional representation of data originated from the large size of brain circuits. It thereby models the human memory using points of a high-dimensional space. The points in the space are called as hypervectors, to emphasize their high-dimensionality. A hypervector H has D dimensional values, i.e., H∈ [symbol] D, where the dimensionality typically refers to tens of thousands dimensions. HDC incorporates learning capability along with typical memory functions of storing/loading information. It mimics several important cognitive functionalities of the human memory model with vector operations which are computationally tractable and mathematically rigorous in describing human cognition.

We examined herein the feasibility of HDC as an alternative computation model for cognitive tasks, which can be potentially integrated with today's general-purpose systems. For this goal, the disclosed learning system natively processes high-dimensional vectors as a part of the existing systems. It enables easy porting and accelerating of various learning tasks beyond the classification.

We further disclose herein, a novel learning solution suite that exploits HDC for a broader range of learning tasks, regression and reinforcement learning, and a PIM-based processor, called HPU, which executes HDC computation tasks. The disclosed system supports the hypervector as the primitive data type and the hypervector operations with a new instruction set architecture (ISA). The HPU processes the hypervector-related program codes as a supplementary core of the CPU. It thus can be viewed as special SIMD units for hypervectors; HPU is designed as a physically separated processor to substantially parallelize the HDC operations using the PIM technique. In the followings, we summarize our main contributions.

In the following, we disclose, among other aspects, the following:

1) A novel computing system which executes HDC-based learning. Unlike existing HDC application accelerators, it natively supports fundamental components of HDC such as data types and operations.

2) A novel method that solve regression and reinforcement learning based on HDC. The methods perform non-parametric estimation for the target function without a prior knowledge for the shape and trend of data points (e.g., linear/polynomial relation.)

3) A new processor design, called HPU, which accelerates HDC based on an optimized, sparse-processing PIM architecture. In this paper, based on the statistical nature of HDC, we disclose an optimization technique, called DBlink, which can reduce the amount of the computation along with the size of the ADC/DAC blocks which is one of the main overheads of the existing analog PIM accelerators. Also, we show how to optimize the analog PIM architecture to accelerate the HDC techniques using sparse processing.

4) We also disclose a new programming model and HPU ISA, which are compatible with the conventional general-purpose programming model. It enables implementing various HDC-based learning applications in a programmable way. We also demonstrate that the HPU integration can be seamlessly done with minimal modification of the system software.

We show our evaluation results focusing on two aspects: i) the learning quality and efficiency of the HPU architecture as an online learning system, and ii) the opportunity and limitation of the HDC as a prospective learning method. Our experimental result shows that the HPU system provides high accuracy for diverse learning tasks comparable to deep neural networks (DNN). The disclosed system also improves performance and energy efficiency by 29.8′ and 173.9′ as compared to the HDC running on the state-of-the-art GPU. We also present that the HDC can be a light-weight alternative to the deep learning, e.g., achieving 33.5′ speedup and 93.6′ higher energy efficiency only with accuracy loss of less than 1%, as compared to the PIM-based DNN accelerator. We also show that the disclosed system can offer robust learning against cell endurance issue and low data precision.

### 3-II. Overview

FIG. 14 demonstrates an overview of the disclosed learning system. Instead of using numbers, HDC uses the hypervector to represent a datum, information, and relations of different information. In some embodiments, the hypervector is a primitive data type like the integer and floating point used in the traditional computing. In the disclosed system, the user-level programs can implement solutions for diverse cognitive tasks, such as reinforcement learning, and classification, using the hypervectors. The compiler translates the programs written in the high-level language with the HPU ISA. At runtime, when the CPU decodes an HPU instruction, it invokes them on the HPU to accelerate using the analog PIM technology.

As described herein, the analog PIM technology used in the HPU design is a suitable hardware choice to accelerate the HDC. HDC performs cognitive tasks with a set of hypervector operations. The first set of operations are the hypervector addition and multiplication which are dimension-independent. Since the hypervector has a large dimensionality, e.g, D=10,000, there is a great opportunity for parallelization. Another major operation is the similarity computation, which is often the cosine similarity or dot product of two hypervectors. It involves parallel reduction to compute the grand sum for the large dimensions. Many parallel computing platforms can efficiently accelerate both element-wise operations and parallel reduction.

HPU adopts analog PIM technology. There are two major advantages of using the analog PIM for HDC over other platforms and technology. First, it can offer massive parallelism which is suitable for the element-wise operations. In contrast, the parallelism on the FPGA is typically limited by the number of DSP (a digital signal processing) units. Second, the analog PIM technology can also efficiently process the reduction of the similarity computations, i.e., adding all elements in a high-dimensional vector, unlike the CMOS architectures and digital PIM designs that need multiple additions and memory writes in order of O(log D) at best.

To leverage the HDC as a general computing model for diverse learning tasks, we fill two gaps: i) Programming model for HDC applications: The mainstream of HDC research have focused on the development of efficient classifiers for limited task types. However, many practical problems need other learning solutions. Systems should be capable of running various learning tasks assisted by a general programming model for HDC. ii) Programmable processor for HDC: In the PIM technology, the processed data should be stored in the right place before executing operations. Hence, the HPU should manage when/where to read the input hypervector and to store the output hypervector in its NVM (non-volatile memory) block. We tackle these issues through (i) a novel HDC learning with a programming model and (ii) a processor architecture that tailors multiple HDC operations explicitly considering the dependency.

### 3-III. Learning on HDC System

### 3-III.1 how HDC Mimics Human Memory Cognition

In this section, we discuss how HDC describes human cognition. HDC performs a general computation model, thus can be applicable for diverse problems other than ML solutions. We use an illustrative modeling problem: “when monitoring the launch sequence of applications (apps), how to predict the future app?”. This problem has been investigated for ML-based system optimization, e.g. program prefetching and resource management.

Hypervector generation: The human memory efficiently associates different information and understands their relationship and difference. HDC mimics the properties based on the idea that we can represent the information with a hypervector and the correlation with the distance in the hyperspace. HDC applications use high-dimensional vectors that have a fixed size dimensionally, D. When two D-components are randomly chosen from {−1, 1}, the two bipolar hypervectors are dissimilar in terms of the vector distance, i.e., near orthogonal, referring that the similarity in the vector space is almost zero. Thus, two distinct items can be represented with two randomly-generated hypervectors. In our example, we can map different apps with different near-orthogonal hypervectors, e.g., Aₐₚₚ₁, . . . , Aₐₚₚ₁. If a new app is observed in the sequence, we can simply draw a new random hypervector. Note that a hypervector is a distributed holographic representation for information modeling in that no dimension is more important than others. The independence enables robustness against a failure in components.

Similarity computation: Reasoning in HDC is done by measuring the similarity of hypervectors. We use the dot product as the distance metric. We denote the dot product similarity with δ(H₁, H₂) where H₁ and H₂ are two hypervectors. For example, δ (Aₐₚₚ₁, Aₐₚₚ₂) ≃0, since they are near-orthogonal.

Permutation: the permutation operation, ρⁿ(H), shuffles components of H with n-bit(s) rotation. The intriguing property of the permutation is that it creates a near-orthogonal and reversible hypervector to H, i.e., δ(pⁿ(H), H)≃0 when n≠0 and p⁻ⁿ(pⁿ(H))=H. Thus, we can use it to represent sequences and orders. For example, if we consider recent three apps launched sequentially, we may represent them by ρ¹(A_{appX}), ρ²(A_{appY}) and ρ³(A_{appZ}).

Addition/Multiplication: The human memory effectively combines and associates different information. HDC imitates the functionalities using the element-wise multiplication and addition. For example, the element-wise addition produces a hypervector preserving all similarities of the combined members. We can also associate two different information using multiplication, and as a result, the multiplied hypervector is mapped to another orthogonal position in the hyperspace.

In our example, we may add the three recent apps (3-grams) to memorize the short sequence: S=ρ¹(A_{appX})+ρ²(A_{appY})+ρ³(A_{appZ}). The hypervector, S, is similar to each of the three permuted hypervectors, bit near-orthogonal to hypervectors for any other apps. Let us assume that we observe a new app, A_{appN}, launches following the sequence S. We may associate the sequence-to-app relation with the multiplication: S×A_{appN}. HDC can continuously learn the whole app sequences as a memory item:

$$M = {\sum }_{i} {S}^{i} \times {A}_{appN}^{i}$$

With M, we can deduce which apps are more frequently used whenever we newly observe a short sequence of three apps encoded to S̅. Let us consider the following equation:

$$\overline{S} \times M = {\sum }_{i} \overline{S} \times {S}^{i} \times {A}_{appN}^{i}$$

If all three apps in S̅ are different from Si, the hypervectors are near-orthogonal. If any app in S̅ matches to one of Si, the hypervectors will be similar. We can check the similarity to query if an app A_{appQ} is likely to launch as a future app:

$$δ ( \overline{S} \times M , {A}_{appQ} ) = {\sum }_{i} \underbrace{δ ( \overline{S} \times {S}^{i} \times {A}_{appN}^{i} , {A}_{appQ} )}_{Subsequence Similarity}$$

If S̅ and Si are near-orthogonal, the subsequence similarity term is approximately zero regardless of A_{appN}ⁱ and A_{appQ}. In contrast, if they are the identical sequence and A_{appN}ⁱ and A_{appQ}, the term has a high similarity, i.e., 3 D where D is the dimension size. If the subsequences have a few matches, the term has non-zero similarity, e.g., M·D where M is the number of the matches apps. Thus, the higher value the total similarity has, the query app launched more frequently in the previous, inferring that the app is likely to launch in future.

### 3-III.2. Encoding

ML techniques in general train from a set of vectors whose elements are numerical values: v= [symbol] e₁, . . . , eₙ [symbol] . To map the problems in HDC, we first need to encode the feature values into the hypervectors. Let us assume that each feature is normalized in the range of [0.0, 1.0]. In existing works for classification tasks, it quantizes the range with multiple discrete levels and maps each level to a hypervector since the exact features do not need to be precisely represented. In contrast, for regression and reinforcement learning, we map continuous values to take into account absolute distances between different samples.

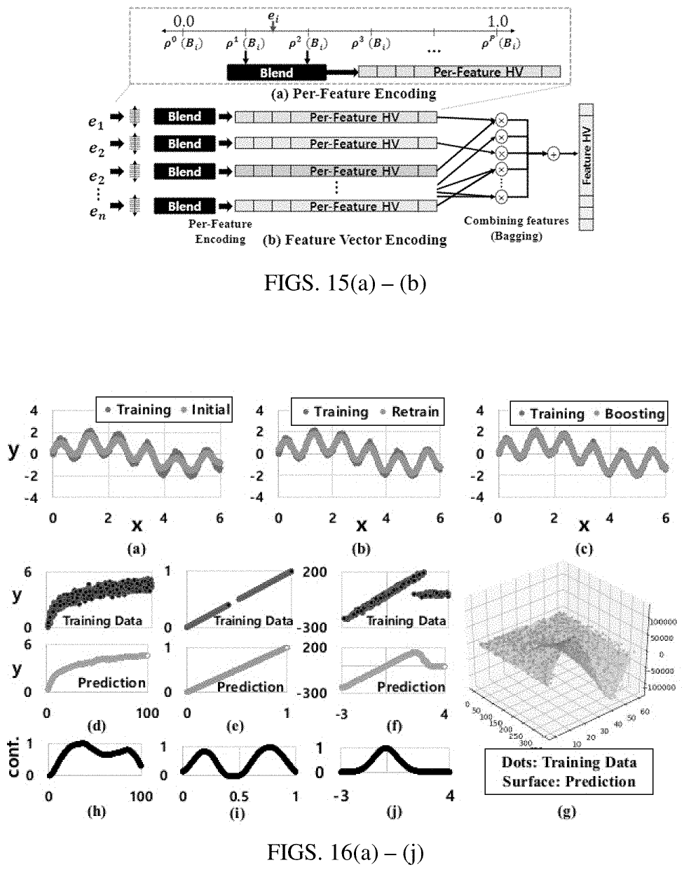

FIG. 15a illustrates the disclosed encoding scheme. We first divide the range of a feature value with multiple P partitions and assign a hypervector for each partition boundary: ρ⁰(Bi), ρ^{P}(Bᵢ) where Bᵢ is a random hypervector used to encode a i^{th} feature. A value in the p^{th} partition is encoded with the two boundary hypervectors, i.e., ρ^{P}(Bᵢ) and ρ^{p+1}(Bᵢ), so that it preserves the distance to each boundary in the hypervector similarity. To this end, we introduce a new HDC operation, called blend:

Blend: β(H₁, H₂, d) creates a new hypervector by taking the first d components from H₁ and the rest D−d components from H2. Intuitively, the blend operation for two random bipolar hypervectors satisfies the following properties: δ(β(H₁, H₂, d), Hi)=d and δ(β(H₁, H₂, d), H₂)=D−d. A feature value, eᵢ, is blended by β(ρ^{P}(Bᵢ) ρ^{p+1}(Bᵢ), (eᵢP−└eᵢP┘)·D). Thus, this encoding scheme can cover P·D fine-grained regions while preserving the original feature distances values with the similarity values in the HDC space. For any two different values, if the distance is smaller than the partitioning size, 1/P, the similarity is linearly dependent on the distance; otherwise, the hypervectors are near-orthogonal. These properties are satisfied across the boundaries.

As the next step, we combine multiple feature hypervectors. FIG. 15b illustrates how to combine the feature hypervectors. This procedure is inspired by the bagging method which randomly selects different features to avoid overfitting. It creates F feature sets which have random features. The features in the same set are combined with multiplication to consider the non-linear feature interactions. The multiplied results are combined with the addition. In our implementation, each feature set has at maximum log n features which is a common bagging criteria.

### 3-III.3. Regression

The typical regression problems are to train a function with the training datasets which include the feature vectors, v, and corresponding output values, y. The disclosed regression technique models the nonlinear surface, motivated by non-parametric local regression techniques and is able to approximate any smooth multivariate function.

Training: We first encode each i-th training sample with Xⁱ and Yⁱ, where Yⁱ is encoded without partitioning, i.e., P=1. We then train a pair of two hypervectors, (M, W), called regressor model hypervectors, as an initial regression solution formulated as follows:

$$M = {\sum }_{i} {X}^{i} \times {Y}^{i} and W = {\sum }_{i} {X}^{i}$$

Using the regressor model hypervectors and an input variable encoded with X̅, the regression function is defined as follows:

$$f ( \overline{X} ) = \frac{δ ( M , \overline{X} \times {Y}_{one} )}{δ ( W , \overline{X} )}$$

where Yₒₙₑ is the hypervector encoded for y=1.0, i.e., the maximum y value in the training dataset when normalized.

The regression procedure effectively models the problem space. δ(M, X̅) retrieves the weighted sum of the hypervector distance between X̅ and the corresponding distance Yₒₙₑ for each δ(W, X̅) is the sum of the hyperspace distances for every Xⁱ. Thereby, it locally approximates the function surface as a weighted interpolation of nearby training points.

FIG. 16a shows the results of the regression inference for a synthetic function with the initial regressor model. The results show that it follows the trend of the target function, while underfitting for extreme cases. The main reason of the underfitting is that the randomly generated hypervectors are not perfectly orthogonal. To compensate for this error, we run a retraining procedure for several epochs. In the retraining procedure, we update the regressor model with the observed error for each sample as follows:

M=M+(1−f(Xⁱ))×Xⁱ×Yⁱ.

FIG. 16b shows the results after 2 retraining epochs. The results show that the model better fits to the dataset.

Weighted boosting: An issue of the initial regressor is that it only uses fixed size hypervectors for the entire problem space. We observe that more complex problem spaces may need a larger dimension size. Instead of arbitrary increasing the dimensionality, we exploit adaptive boosting (Ad-aBoost.R2) to generate multiple hypervector models and predict the quantity using the weighted sum of each model. Once training an HDC regressor model, we compute the similarity for each training sample. AdaBoost.R2 algorithm, in turn, calculates the sample weights, wⁱ, using the similarity as the input, to assign larger weights for the samples predicted with higher error. Then, we train the multiple hypervector models by bootstrapping hypervectors for input variables, i.e., wⁱ·Xⁱ. When the boosting creates multiple regressor hyper-vectors, the inference is made with the weighted average of the multiple hypervector models. FIG. 16c shows that the weighted boosting improves accuracy (c). As shown in the figure, the disclosed regression method accurately models the problem space for other synthetic examples, e.g., noisy data (16d), inference with missing data points (16e), stepwise functions (16f), and multivariate problems (16g).

Confidence: Our regression provides the confidence of the prediction in a similar fashion to modern ML algorithms, e.g., Gaussian Process. We calculate the confidence by querying if we observe enough similar inputs during training:

$$conf ( \overline{X} ) = \frac{δ ( W , \overline{X} )}{{max}_{i} δ ( W , {X}^{i} )}$$

where the denominator can be precomputed during the training. FIGS. 16h-16j shows the confidence for the three examples. For example, FIG. 16i shows that the confidence is relatively small for the region that has missing data points.

### 3-III.4. Reinforcement Learning

The goal of reinforcement learning (RL) is to take a suitable action in a particular environment, where we can observe states. The agent who takes the actions obtains rewards, and it should train how to maximize the rewards after multiple trials. In this paper, we focus on a popular RL problem type which considers an episodic, policy-based situation. In these problems, after observing multiple states given as feature vectors, s₁, . . . , sₙ, and taking actions, a₁, . . . , aₙ, the agent gets a reward value for each episode. We can distribute the single reward value to each state and action with specific decaying rate, called discounted rewards, r₁, . . . , rₙ.

We solve this problem by extending the disclosed regression method as a continuous learning solution. Let us assume that there are A actions that the agent can take, i.e., 1≤aᵢ≤A. We train two hypervectors for each action, Mα and Wα, where their elements are initialized with zeros and 1≤α≤A. After each episode, we use the encoding method to map each observed state sᵢ to a hypervector Xⁱ. We then compute the previous reward estimated by the current model:

$${\hat{y}}_{i} = {f}_{α} ( {X}^{i} ) = \frac{δ ( {M}_{α} , {X}^{i} \times {Y}_{one} )}{δ ( {W}_{a} , {X}^{i} )}$$

in a similar fashion to the regression. The reward value to newly learn, yᵢ, is calculated considering the discounted reward rᵢ and previously estimated reward ŷᵢ as follows: yᵢ=λ·rᵢ+(1−λ)·ŷᵢ where λ is a learning rate. We then encode yᵢ to Yⁱ and accumulate Xⁱ×Yⁱ to Mₐᵢ and Xⁱ to Wₐᵢ. In other words, the hypervector model memorizes the rewards obtained for each action taken in the previous episodes. From the second episode, we choose an action using the hypervector model. Let us assume that we obtain expected rewards, e_{α}=ƒ_{α}(X̅), for all actions. We exploit the softmax function to covert ea to probability values, pi. The agent chooses an action randomly using pi as weighting factors. Thereby, through episode runs, the action that obtained larger rewards gets higher chances to be taken.

### 3-III.5. Classification

We adopt an HDC-based classification technique continuous encoding instead of the discrete quantization; we evaluate how the encoding affects prediction quality in Section 3-VI.8. The classification learning is also straightforward since we can linearly train and distinguish different classes with the hypervector nonlinearly encoded. Let us assume that the features of a sample are encoded as Xⁱ, and the corresponding label is yⁱ. In the initial training, we accumulate hypervectors for each class, creating the class hypervectors, Cₖ: Cₖ=Σ_{y}_{ⁱ}₌ₖXⁱ. For the inference, we identify the class hypervector that has the highest similarity (i.e., the highest dot product value) to the query hypervector. We also perform the retraining procedure. If a data sample Xⁱ is misclassified to \hat{k} class, we update two class hypervectors: C_{y}_{ⁱ}=C_{y}_{ⁱ}+Xⁱ and C_{\hat{k}}=C_{\hat{k}}−Xⁱ.

### 3-IV. Hyperdimensional Processing Architecture

### 3-IV.1. HPU Hyperdimensional Processing Unit

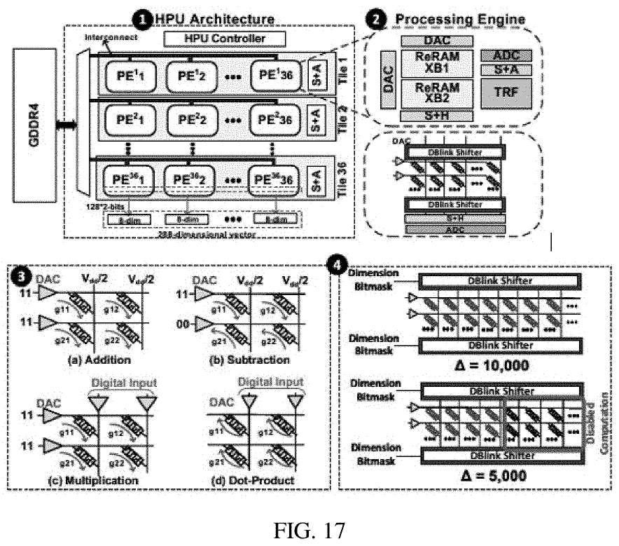

FIG. 17 shows the HPU architecture whose pipeline is carefully optimized to best utilize the characteristics of HDC and learning algorithms. The HPU core uses a tile-based structure where each tile process partial dimensions \textcircled{1}. Each tile has an array of multiple processing engines, and each processing engine (PE) has hypervector registers and computes the HDC operations for eight dimensions. For an HPU instruction issued by CPU into the instruction FIFO with corresponding operands and registers, the HPU controller processes it in order on all the PEs in parallel to cover entire dimensions. The HPU communicates with the off-chip memory (GDDR4) for memory-related HPU instructions.

The PE performs the HDC operations using PIM technology \textcircled{2}. The hypervectors are stored in either dual resistive The PE performs the HDC operations using PIM technol-crossbars (ReRAM XB1/XB2) or CMOS-based transient register files (TRF). Each crossbar has 128×128 cells where each cell represents 2 bits, while the TRF stores 16 hypervector registers with the same bit-width to the crossbar. We use 32-bit fixed-point value representation for each hypervector component, taking 16 cells. The in-memory computations start by initiating analog signals converted from digital inputs by DACs (digital-to-analog converter). After the results are made as analog signals, the ADC (analog-to-digital converter) converts it back to the digital signals. While the sample and hold (S+H) circuits maintain the digital signals, the shift and adder (S+A) circuits accumulate them so that the results can be eventually written back to the TRF.

### 3-IV.2. Instruction Set Architecture

The HPU instructions completely map the HDC operations explained in Section 3-III.1, and also support data transfers for the hypervector registers in the HPU memory hierarchy. Below describe each PIM-based instruction along with our register management scheme.

1) addition/subtraction (hadd, hsub): The PE performs the addition \textcircled{3}a and subtraction \textcircled{3}b for multiple rows and updates the results into the destination register. This computation happens by activating all addition and subtraction lines with 1 and 0 signals. The accumulated current through the vertical bitline has the result of the added/subtracted values.

2) multiplication (hmul, shmul): The multiplication happens by storing the inputs on different memory rows and passing the DAC located in each bitline \textcircled{3}c. With the full 32-bit another multiplication operand as an analog signal using precision, the multiplication takes 18 cycles; we show how to optimize the cycles for the HDC operations in Section 3-IV.4. Some HDC applications need the scala-vector multiplication (shmul), e.g., regression retraining and implementing the learning rate in RL. We implement the instruction as a simple extension of the vector multiplication so that the DAC feeds the same voltage for each bitline.

3) dot product (hdot, hmdot): This operation can perform by passing analog data to bitlines. The accumulated currents on each row is a dot product result which will be transferred to digital using ADC \textcircled{3}d. The similarity computation may happen for a hypervector and another set of multiple hypervectors (i.e., vector-matrix multiplication.) For example, in the classification, a query hypervector is compared with multiple class hypervectors; the regression computes the similarity for multiple boosted hypervectors. hmdot facilitates it by taking the address of the multiple hypervectors. We discuss how we optimize hmdot in Section 3-IV.4.

4) Permutation/Blend (perm, bind): The permutation and blend are non-arithmetic computation. We implement them using typical memory read and write mechanisms handled in the interconnects. For bind, HPU fetches the two operand hypervectors, i.e., d and D−d partial elements for each of them, and writes them back to the TRF.

5) Hypervector memory copy (hmov, hldr, hstr, hdraw): This instruction family implements the memory copy operations between registers or across the off-chip memory. For example, hmov copies a hypervector register to another register. hldr loads a hypervector data from the off-chip memory to the TRF, whereas hstr performs the off-chip writes. hdraw loads a random hypervector prestored in the off-chip memory.

Register file management: A naive way to manage the hypervector registers is to assign each of 2×128 rows for a single register statically; however it is not ideal in our architecture. First, since applications do not need all the 128 registers in general, the memory resources are likely to be under-utilized. Moreover, with the static assignment, they may frequently use the same rows, potentially degrading cell lifetime. Another reason is that the PIM instructions produce a hypervector in the form of digital signals, where the associated register can be used as an operand of future instructions. In many cases, writing the memory cells are unnecessary since the next instruction may feed the operand through DACs. For those reasons, HPU supports 16 general-purpose hypervector registers. Each register can be stored in either resistive cells or TRF. In the resistive memory region, no register is mapped to a specific row. HPU uses a lookup table to identify i) if a particular register is stored in the resistive memory instead of the TRF and ii) which resistive memory row stores it. Based on the lookup table, HPU decides where to read a hypervector register. For example, if the destination operand in shmul is stored in the TRF, HPU assigns a free row of the resistive memory. The new assignment is based on Round Robin policy to wear the memory cells out evenly. Once an instruction completes, the result is stored into the TRF again. The registers in the TRF are written back to the resistive memory only when required for a future instruction.

### 3-IV.3 Sparse Processing in HPU

One of the analog PIM concerns is the power and area efficiency due to the ADC/DAC blocks. We address this issue by utilizing the error-tolerant characteristic of HDC. In HDC, the hypervector elements are all independent and represent data in a holographic fashion, which means that we can successfully perform cognitive tasks by statistically using partial dimensions. By utilizing this characteristic, we disclose a contextual sparse processing technique, called DBlink (dimension-wise computation blink). As shown in FIG. 17, the HPU has a special component, called DBlink shifter, which consists of shifter and selector logic handling a bitmask, around the blocks connected with the DAC and ADCs. The DBlink selector chooses a column-wise set of consecutive fixed-point values, i.e., partial dimensional elements to compute, where the set is selected interchangeably for each operation in order. For example, as shown in \textcircled{4}, let us assume that it needs to only use Δ=5,000. In this case, the HPU controller activates the first half of the columns designated with the dimension bitmask, and it performs the current operation for the selected values. Then, for the next operation, the rest half, which were previously disabled, are engaged in the computation. In other words, all the dimensions are used in the whole execution statistically, while only a part of dimensions are computed in each operation.

Based on the DBlink technique, we reduce the number of ADC/DAC components by

$$\frac{Δ}{D} .$$

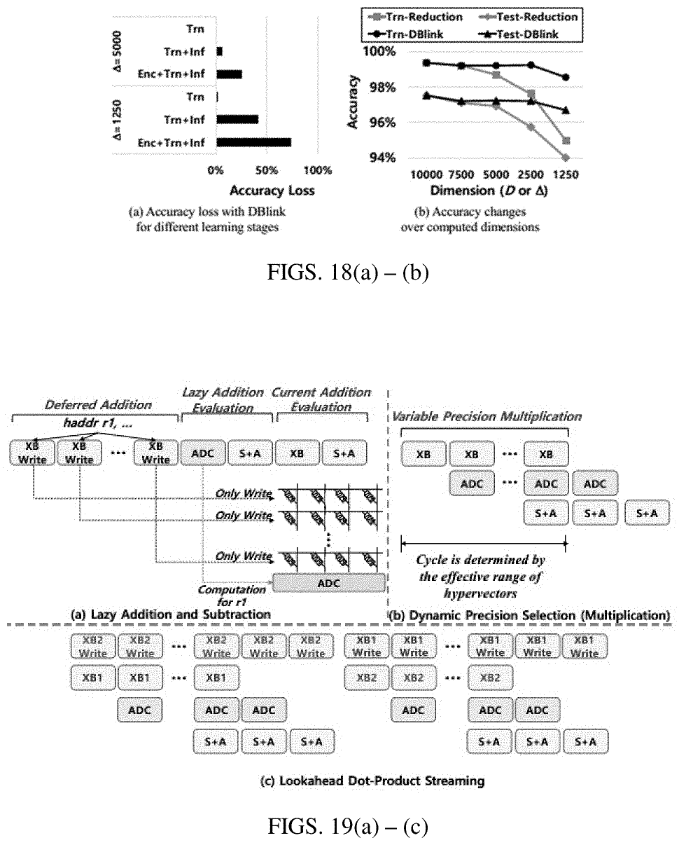

However, when the full dimensions should be computed, it may slow down the computation due to the insufficient ADC/DACs. To better understand when we should compute all dimensions, we conducted an experiment to examine how the accuracy changes over different Δ values when D=10,000. FIG. 18a summarizes the results. We observe that there is no huge accuracy loss when applying DBlink during the training, which takes the majority of the total execution time for common learning tasks; some procedures, e.g., encoding and inference are highly affected. Thus, we exploit DBlink only for the training procedures by controlling A with an additional instruction. Another interesting finding is that the sparse computation idea of DBlink is more effective than the dimension reduction in terms of the learning quality. FIG. 18b shows the results for the training and testing accuracy for MNIST. For example, when using a smaller dimension, e.g., D=2,500, we observed a notable accuracy drops, whereas with DBlink, which computes four groups of hypervector elements in order for every operation, we do not observe the significant drop until Δ=1,250. We thereby set Δ=2,500 since we have observed very negligible loss for all the tested benchmarks.

### 3-IV.4. Pipeline Optimization

Lazy Addition and Subtraction The addition/subtraction instruction takes two hypervector registers. A naive implementation is to write the registers to the resistive memory and compute the results for every issued instruction (3 cycles in total). However, this scheme does not utilize the advantage of multirow in-memory addition/subtraction operations. For example, since the HDC techniques discussed in Section 3-III often compute the sum of multiple hypervectors to combine information, we may process the multiple additions in a batch when the instructions are sequentially issued. FIG. 19a shows how the HPU performs the two operations in a lazy manner, called Lazy Addition and Subtraction. Instead of immediately evaluating hadd or hsub, the HPU writes the source hypervectors (second operand) in free memory rows for consecutive instructions based on the resister management scheme, while updating a bitmask array which keeps the row index for the hadd and hsub cases (1 cycle). The actual in-memory computation for all stored hypervectors is deferred until (i) either the corresponding destination register (first operand) is used by other instructions or (ii) the crossbar has no free memory row to store more source hypervectors. It takes 2 cycles to drive the ADC and S+A.

Dynamic Precision Selection HPU optimizes the pipeline of the HPU instructions by selecting the required precision dynamically. The underlying idea is that we can determine the value range of the hypervector elements computed by an HDC operation. For example, when adding two hypervectors which are randomly drawn from {−1,1}, the range of the added hypervector is [−2, 2]. In that case, we can obtain completely-accurate results by computing only 2 bits. By keeping tracks of the hypervector ranges, we can optimize the cycles for hmul, shmul, and hdot, and hmdot. FIG. 19b shows how this strategy, called dynamic precision selection, optimizes the pipeline stage for hmul as an example. In the first cycle (crossbar operation (XB)), HPU performs three main tasks: i) computing the required precision with the range of each register, ii) ensuring to store a hypervector register in the resistive memory, and iii) feeding a hypervector register to DACs. Let us assume that the final output here is computed to be in a range of [⊥, [symbol] ]. HPU identifies the minimal n which satisfies 2n−1−1³ max(abs(⊥), abs( [symbol] )). Then, it executes ADC and S+A stages over n/2 cycles to cover the required n bits. During this process, the ADC stage coverts the computed results using the ADCs and feed it to the S+A block to update the multiplied results. In total, it takes n/2+2 cycles. Note that this strategy guarantees correct results and faster performance than computing all 32 bits by processing partial necessary ReRAM cells for each processing engine.

Lookahead Dot-Product Streaming hmdot performs the dot product for multiple hypervectors stored in the off-chip memory. We optimize the pipeline stage of this instruction to hide the read latency for fetching the multiple hypervectors from the off-chip memory. FIG. 19c illustrates the optimization strategy, called Lookahead Dot-Product Streaming. The HPU starts the computation for the first crossbar (XB1), while fetching the next set of hypervectors into the free rows of the second crossbar (XB2). Once the computation is done on XB1, the HPU performs the next computation for the fetched hypervectors in XB2. They can be interleaved since the hypervector fetching and computation uses different hardware resources, i.e., the off-chip memory during the fetching and the ADCs/DACs/S+A during the computation. The number of hypervectors which can be fetched in parallel is dependent on the cycles to compute. For example, when computing all the 32 bits, we can process 18 look-ahead hypervectors since the HPU can load a hypervector for each cycle (100 ns.)

### 3-V. System Software

### 3-V.1 Programming Model

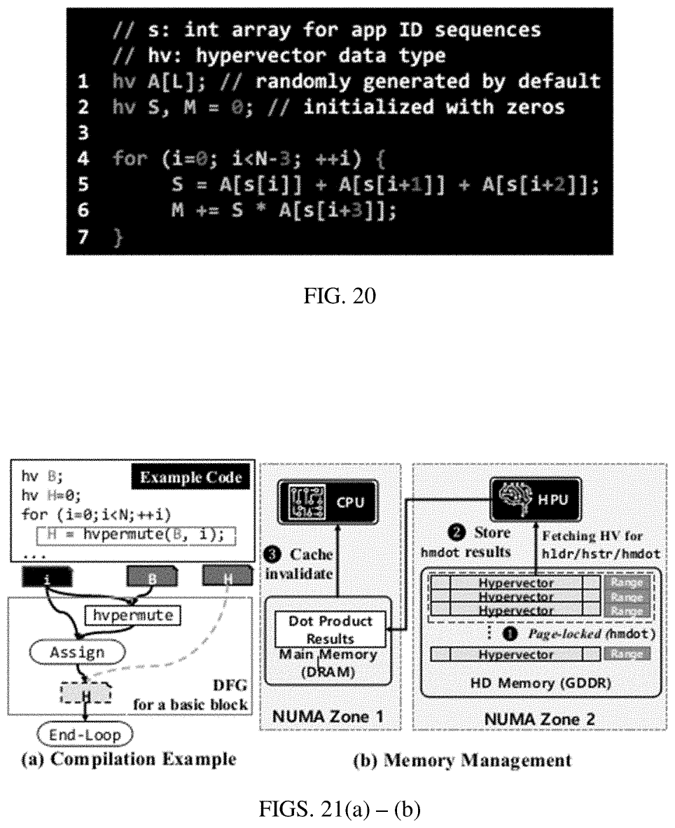

In the disclosed system, programmers can implement the HDC-based application using a simple augmentation to the generic sequence programming model commonly used in high-level programming languages. It offers flexibility to integrate HDC as a part of existing software. FIG. 20 shows a C-based program for the app prediction modeling discussed in Section 3-III.1. The programming model brings at least two benefits: 1) Simplicity: The programming model regards the hypervector as a primitive data type. We can declare the hypervectors in a similar way to integers/floats (Line 1˜2.) The HDC operations can also be mapped to familiar symbols, e.g., for multiplication and addition (Line 5 6.) It allows programmers easy to implement HDC programs on the same platform without a steep learning curve. 2) Compatibility: HDC applications may use existing syntax and data structures. In this example, we use the for-loop statements to encode the subsequence and an integer array to retrieve a hypervector.

### 3-V.2. Compiler

To implement the disclosed programming model, we extend an existing LLVM-based C compiler to generate the HPU ISA by mapping the hypervector and HDC operations as a primitive type and operators. The compiler generates the abstract syntax tree (AST) from the given programming code. During the evaluation procedure for the AST nodes, we define the hypervector type and target HDC operations to generate IR (Intermediate Representation) code. Our syntax definition is similar to the C syntax, e.g., the operators ‘+’/‘*’ for the HDC addition/multiplication. We also provide several built-in functions, e.g., hvdraw( ), hvsim( ) and hvpermute( ) and hvblend( ), for the random hypervector generation, similarity computation, permutation and blend. We map the generated IR code to the hypervector registers and HPU instructions.

The compiler also implements an additional optimization technique to assign the hypervector registers efficiently. As discussed in Section 3-IV.2, the first destination operand of an HPU instruction is updated by the in-memory processing, and the produced results are stored in the TRF, invalidating the register data stored in the resistive memory. Thus, to reduce the number of memory writes, it is advantageous to assign the second operand register with hypervectors which is unlikely to be updated. FIG. 21a illustrates how we identify such read-only hypervectors in the basic blocks for a sample program. We first convert the AST to the data flow graph (DFG) by annotating with the basic blocks. Each DFG node corresponding to a hypervector variable is connected to another node, indicating that the variable is used in the program flow. For example, if a hypervector variable node (B and H) has any incoming edge, the variable is accessed in the basic block. Similarly, if there is an outgoing edge, the hypervector is an updated variable (H). Any hypervector that only has the incoming edge does not require to be updated any longer in the rest of the program procedure, thus we can assume that it is a read-only variable (B). During the IR generation, we prioritize such hypervectors to assign to the second operands.

### 3-V.3. Operating Systems

We implement the disclosed system based on Linux 4.13, mainly modifying its memory management module. FIG. 21b shows how we manage the memory subsystems of the disclosed system. The two processors, CPU and HPU, have the individual main memory spaces. We enable this scheme by utilizing the NUMA (non-uniform memory architecture) zone implementation. The main memory serves the conventional data types, e.g., integer, floating-point values, and pointers, while the off-chip memory of the HPU only stores the hypervectors where each hypervector entry also maintains its range for the dynamic precision selection technique. The HPU interacts with the memory spaces for two following reasons: (i) HPU fetches the hypervectors from the off-chip memory with the memory copy instructions, i.e., hldr and hstr. (ii) HPU also needs to stream multiple hypervectors for hmdot. In particular, during the hmdot operation, the hypervectors are page-locked using mlock( ) system call to prevent that the related memory pages are not swapped out (1). After the in-memory computation, HPU interacts with the main memory to store the dot product results (2). In this case, we also invalidate the CPU caches to guarantee the correct cache coherence (3).

### 3-VI. Evaluation

### 3-VI.1. Experimental Setup

To evaluate the HPU system in the circuit level, we use HSPICE and estimate energy consumption and performance using 45 nm technology. The power consumption and performance are validated with the ReRAM-based architecture developed in. For reliable computations, we used ReRAM devices with 2-bit precision. The robustness of all in-memory operations is verified by considering 10% process variations. To experiment the integrated system with the HPU core, we developed a cycle-accurate simulation infrastructure which performs the functionality for each HPU instruction on NVIDIA GTX 1080 Ti. Our experimental infrastructure assumes that HPU interfaces with CPU using PCIe; the issue of the bandwidth is negligible in the disclosed systems since the interface only delivers instructions and 32-bit numbers while all hypervectors are stored in the HPU and HDC memory side. The simulation infrastructure runs a custom Linux 4.13 on Intel i7-8700K, while the HPU compiler is implemented based on Clang 5.0. During the code compilation, each HPU instruction is mapped to a CUDA function call implemented in the simulator library where each CUDA core performs the functionality for a single PE. The simulator produces the record of the execution instructions and the memory cell usage, so that we can estimate the power and performance based on the data obtained in the circuit-level simulation. Since HPU utilizes GDDR memory used in the modern GPU system, we can estimate the memory communication overhead precisely while simulating the power/performance of PEs in a cycle-accurate way. We measure power consumption of the existing systems using Hioki3334 power meter.

TABLE 3-I
Datasets
F: # of features, A: # of actions, K: # of classes Ntrain/Ntest: # of training/test samples

| Regression | | | | RL | | | Classification | | | | |
|---|---|---|---|---|---|---|---|---|---|---|---|
| Name | F | Nₜᵣₐᵢₙ | Nₜₑₛₜ | Name | F | A | Name | F | K | Nₜᵣₐᵢₙ | Nₜₑₛₜ |
| BOSTON [48] | 13 | 506 | 506 | CARTPOLE [49] | 4 | 2 | PAMAP2 [50] | 75 | 5 | 611142 | 101582 |
| DIABETE [51] | 10 | 442 | 442 | MOUNTAIN [49] | 2 | 3 | MNIST [46] | 392 | 10 | 60000 | 10000 |
| P4PERF [52] | 60 | 17385 | 7344 | LUNAR [49] | 8 | 4 | FACE [53, 54] | 608 | 2 | 522441 | 2494 |
| BUZZ [55] | 96 | 25361 | 2818 | | | | UCIHAR [56] | 561 | 12 | 6213 | 1554 |
| SUPER [57] | 81 | 19136 | 2127 | | | | AUDIO [58] | 388 | 7 | 38513 | 2027 |

Benchmarks: Table 3-I summarizes datasets used to evaluate the disclosed learning solutions. For the regression task, we include canonical datasets for reference (BOSTON and DIABETE) and practical datasets (P4PERF: program performance prediction on high-performance systems, BUZZ: predicting popular events in social media, and SUPER: critical temperature prediction for superconductivity). For RL, which HDC could be well-suited as a lightweight online learning solution, we utilize three tasks provided in OpenAI gym. The classification datasets include medium-to-large sizes including various practical learning problems: human activity recognition (PAMAP2), text recognition (MNIST), face recognition (FACE), motion detection (UCIHAR) and music genre identification (Google Audio Set, AUDIO).

TABLE 3-II
HPU configuration & platform comparison

| | Spec | Power | Area (μm²) | | Spec | Power | Area (mm²) |
|---|---|---|---|---|---|---|---|
| ADC | 8-bits, 1.2 Gb/s | 4 mW | 2400 μm² | HPU Tile | 36 Pes | 356 mW | 0.28 mm² |
| DAC | 1-bit | 1 mW | 106 μm² | HPU Total | Cores | 12.8 W | 10.2 mm² |
| S + H | 8 × 128 | 10 μW | 40 μm² | | GDDR | 14 W | (4 GBytes) |
| XB | 2 × 128 × 128 | 2.5 mW | 400 μm² | CPU | Xeon E5 | 290 W | 912 mm² |
| S + A | 1 | 0.2 mW | 240 μm² | GPU | GTX 1080ti | 240 W | 471 mm² |
| TRF | 2K | 2.2 mW | 280 μm² | FPGA | Kintex-7 | 25 W | 169 mm² |

### 3-VI.2. HPU Configuration Study

Table 3-II summarizes the configurations of HPU evaluated in this work with comparison to other platforms. The HPU processes D=10,000 dimensions in parallel, which are the typical hypervector dimensionality known to be enough accurate. In this setting, the HPU can offer a significantly higher degree of parallelism, e.g., as compared to SIMD slots of CPU (448 for Intel Xeon E5), CUDA cores of GPU (3840 on NVIDIA GTX 1080ti), and FPGA DSPs (1,920 on Kintex-7). In addition, the HPU is an area-effective design, taking 10.2 mm2 with the efficient thermal design power (TDP) of 1.3 W/mm2. This high efficiency is largely contributed by the DBlink technique which reduces the power and area consumption of the ADC and DAC. If the HPU system does not exploit the technique, we need to compute the full 10,000 dimensions every time, which results in 1.9 times less than TDP. When considering the required resource, the TRF in total needs 640 Kbytes which is smaller than the typical last-level cache used in the conventional CPU core. We use GDDR for the off-chip memory and assume that it serves inter-block bandwidth of 384 GB/s which we measured on NVIDIA GTX 1080ti. This bandwidth is enough to load/store one hypervector in each HPU cycle as discussed in Section 3-IV.4.

### 3-VI.3. Quality of Learning Techniques

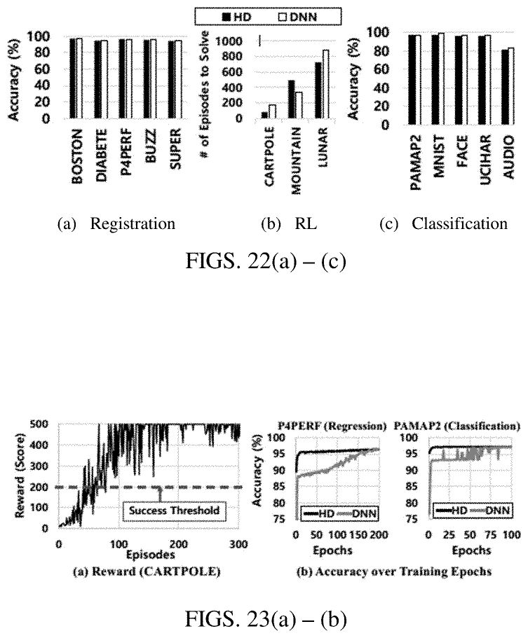

FIG. 22 summarizes the quality of the three learning algorithms. For RL, we report the number of episodes taken to achieve a ‘solving’ score defined in OpenAI gym. For DNN models, we use a standard grid search for hyperparmeter tuning (up to 7 hidden layers and 512 neurons for each layer) and use the models with the best accuracy for each benchmark. The results show that the HDC-based techniques comparable accuracy to the DNN models. For example, when testing with the recent challenging dataset, Google Audio Set (AUDIO), the HDC-based classifier achieves 81.1% accuracy. To summarize, the HDC technique performs the regression and classification tasks with accuracy differences of 0.39% and 0.94% on average. FIG. 23a shows how the HDC RL technique solves the CARTPOLE problem, achieving higher scores over trials. The results show that the disclosed technique successfully solves the problem, exceeding the threshold score (195) after 80 epochs. FIG. 23b show the accuracy changes over training epochs, where the initial training/each retraining during the boosting is counted as a single epoch. We observe that the HDC-based techniques can learn suitable models with much less epochs than DNN. For example, only with 1 epoch (no retraining) also known as single-pass learning, the HDC techniques achieve high accuracy. It also converges quickly only with several epochs.

### 3-VI.4. Efficiency Comparison

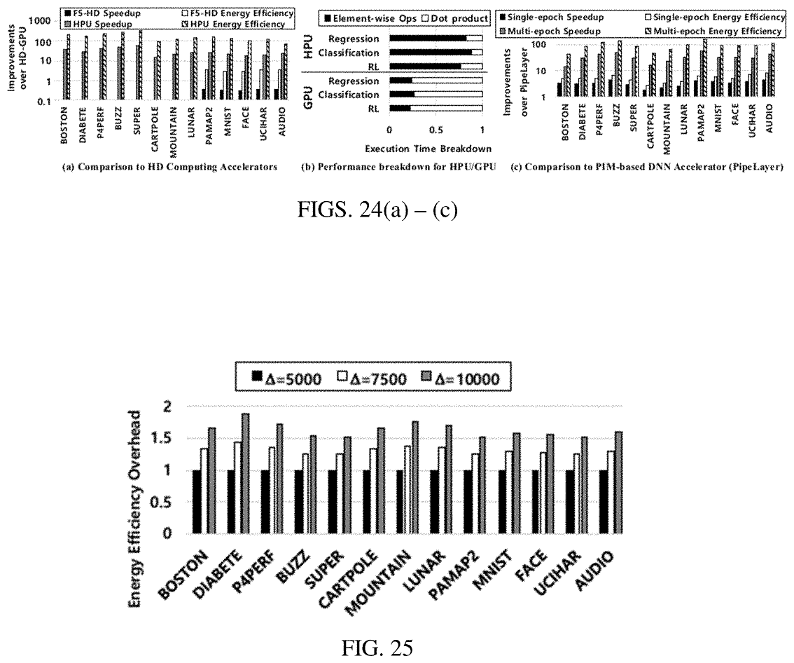

We next evaluate the efficiency of HDC-based learning techniques as compared to the three platforms: (i) HD-GPU which we implement the disclosed procedures on GTX 1080 Ti, (ii) F5-HD which is a state-of-the-art accelerator design running on Kintex-7 FPGA, and (iii) PipeLayer which runs the DNN using PIM technology. FIG. 24a shows that the HPU system surpasses other designs in both performance and energy efficiency. For example, as compared to HD-GPU, the HPU system achieves 29.8 times speedup and 173.9 times energy-efficiency improvements. F5-HDC is customized hardware which only supports the HDC classification procedure; while the HPU system is a programmable architecture that covers diverse HDC tasks. Because of this reason, we could compare the efficiency only for the classification tasks. We observe that F5-HDC is slower than HD-GPU due to the limited DSP resources, but the energy efficiency is higher than HD-GPU. To better understand why HPU delivers the higher efficiency than the CMOS-based designs, FIG. 24b compares the execution time of the dot product operations with all other element-wise operations for HPU and GPU. We observed that the GPU spends a large execution time to compute the dot products (67% on average). In contrast, HPU that utilizes ReRAM-based analog computing efficiently computes the dot products (only taking 14.6% of the execution time) while also parallelizing the dimension-wise computations on PEs.

For the comparison with PipeLayer (FIG. 24c), we report both single and multi-epoch cases. The multi-epoch models are learned until meeting the accuracy of the counterpart HDC models which are trained for 20 epochs to converge. As discussed in Section 3-VI.3, HDC-based learning procedures takes much fewer epochs, and the HPU achieves higher efficiency, e.g., 33.5× speedup and 93.6× energy efficiency improvements. Furthermore, the HDC operations for one epoch are much simpler than the deep learning which have multiple layers to train all weights using the backpropagation. As discussed in Section 3-VI.3, the HDC model can create highly-accurate models even for the single-pass learning case, with 3.4× speedup and 5.4× energy-efficiency improvement.

### 3-VI-5. Impact of DBLink

The one of the main contribution of our work is the DBlink technique which reduces the amount of computations with the less size of ADC/DAC components. FIG. 25 shows how much overhead we required if we do not use the DBlink. For this experiment, we examine three cases by changing Δ in the configuration, Δ=10;000 (full dimension), Δ=7;500, and Δ=5;000 (Default configuration). The results show that the DBlink technique reduces the energy consumption by 1.6× as compared to the case that uses the full dimension.

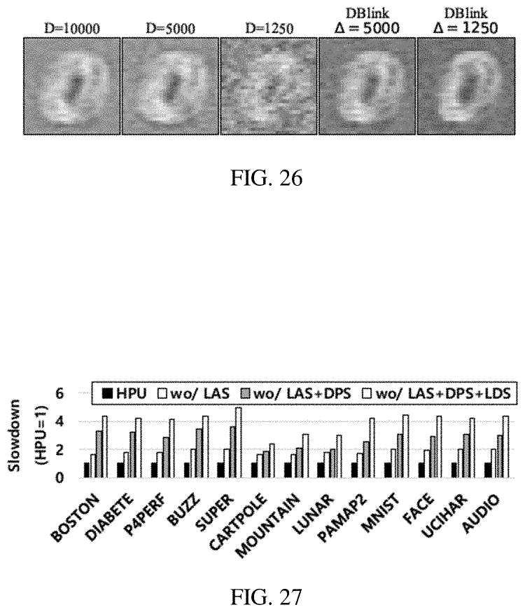

To better understand how the DBlink technique affects the learning accuracy, we examine the trained model for MNIST. To this end, we utilize the hypervector decoding technique, which extracts the data in the original space from an encoded hypervector. We examine how the learned model represents the class 0, which should be similar to the digit 0. FIG. 26 compares our DBlink technique with the dimension reduction technique. The results shows that the learned model accurately captures the shape of the zero digit although the 1250 dimensions are statistically selected for each instruction. In contrast, we observe a high degree of noises if we simply use the dimension reduction technique.

### 3-VI.6. Impact of Pipeline Optimization

To understand the impact of the disclosed pipeline optimization (Section 3-IV.4) we evaluate three variants of the HPU architecture by excluding each pipeline optimization, lazy addition (LAS), dynamic precision selection (DPS), and lookahead dot-product streaming (LDS). FIG. 27 compares the normalized performance for each variant. As shown, the pipeline optimization impacts on the performance by 4× in total. The most important optimization technique is lazy addition since all the learning procedures require to combine many feature hypervectors into the model hypervectors. On average, the LAS technique improves performance by 1.86×.

### 3-VI.7. HDC Resilience

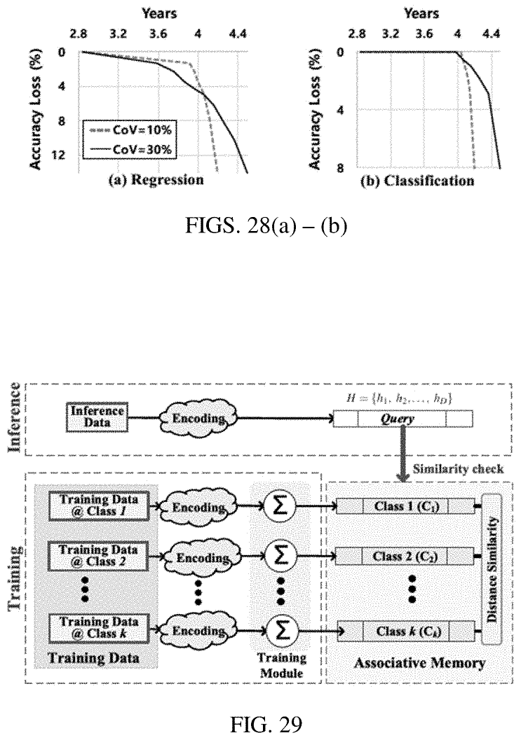

Many advanced technologies typically pose issues for hardware robustness, e.g., production variation, yield, and signal-to-noise ratio (SNR) margin. These issues could be critical to deploy learning accelerators, e.g., general DNNs are known as vulnerable to noise when designing analog hardware. The resistive memory also has endurance problems, i.e., each cell may wear out after an amount of memory writes. The HPU system can be a resilient solution for these technologies. HDC is robust against the existence of faulty components in hypervectors as the hypervector represents information in a fully distributed manner. A recent work also reported that with some noises injected into the hypervectors, it still can perform the learning tasks successfully. To assess such computation robustness, we simulate memory cell failures with a Gaussian distribution of 10E11 writes for two coefficient of variations (CoV): 10% (low) and 30% (high). FIG. 28 reports the average accuracy loss over time, assuming that the HPU continuously runs the regression and classification. We observe that the HPU does not fail even though it cannot update values for some cells (after 2.8 years).

For example, when even 50% of the cells are corrupted after 4.1 years, it can still perform the regression and classification tasks with 5% and 0.5% loss, respectively. The HPU performs the classification more robustly than the regression since the classification needs less-precise computations.

TABLE 3-IIIa-b
HDC implications

| | (a) Component Precision | | | (b) Encoding | | |
|---|---|---|---|---|---|---|
| | Float-32 | Fixed-16 | | HPU | F5-HD [15] | Felix [19] |
| BOSTON | 0% | −0.55% | PAMAP2 | 97.2% | 94.4% | 88.7% |
| DIABETE | 0% | 0% | MNIST | 96.8% | 90.8% | 88.3% |
| P4PERF | 0.05% | −0.18% | FACE | 96.1% | 92.6% | 93.7% |
| BUZZ | 0.38% | −4.66% | UCIHAR | 95.8% | 94.3% | 91.8% |
| SUPER | 0.05% | −3.26% | AUDIO | 81.1% | 78.3% | 69.1% |

### 3-VI.8. Implications of HDC

Hypervector component precision The sparse distributed memory, the basis of HDC, originally employed the binary hypervectors unlike the HPU system using 32-bit fixed-point values (Fixed-32). It implies that less precision would be enough in representing the hypervectors. Table 3-IIIa reports accuracy differences to Fixed-32 when using two component precisions. As compared to the regression tasks computed with the 32-bit floating points (Float-32), the HPU system shows minor quality degradation. Even when using less precision, i.e., Fixed-16, we can still obtain accurate results for some benchmarks. Note that in contrast, the DNN training is known to be sensitive to the value precision. Such HDC characteristic impervious to the precision may enable highly-efficient computing solutions and further optimization with various architectures. For example, we may reduce the overhead of ADCs/DACs, which is a key issue of PIM designs in practical deployment, by either selecting an appropriate resolution or utilizing voltage over-scaling.

Encoding The quality of HDC-based learning is sensitive to the underlying encoding method. Table 3-IIIb compares the classification accuracy of the disclosed method to the existing encoding used in the state-of-the-art accelerator designs, F5-HD (HDC-based classifier) and Felix (encoding accelerator.) We observe that the disclosed encoding method increases the accuracy by 3.2% (6.9%) as compared to F5-HDC (Felix) since we benefit fine-grained representations and consider non-linear feature interactions; it still suggests that a better encoding method would achieve higher accuracy. For example, the disclosed method achieves the higher accuracy although it statically maps the feature vectors to the HDC space; it would be natural to ask other HDC encoding, e.g., adaptive learnable encoding and convolution-like encoding.

### Part 4: SearchHD: Searching Using Hyperdimensional Computing

As further appreciated by the present inventors, brain-inspired Hyperdimensional (HD) computing emulates cognitive tasks by computing with long binary vectors—aka hypervectors-as opposed to computing with numbers. However, in order to provide acceptable classification accuracy on practical applications, HD algorithms need to be trained and tested on non-binary hypervectors.

Accordingly, we disclose SearcHD, a fully binarized HD computing algorithm with a fully binary training. SearcHD maps every data points to a high-dimensional space with binary elements. Instead of training an HD model with non-binary elements, SearcHD implements a full binary training method which generates multiple binary hypervectors for each class. SearcHD also uses the analog characteristic of non-volatile memories (NVMs) to perform all encoding, training, and inference computations in memory. We evaluate the efficiency and accuracy of SearcHD on a wide range of classification applications. Our evaluation shows that SearcHD can provide on average 31.1 times higher energy efficiency and 12.8 times faster training as compared to the state-of-the-art HD computing algorithms.

### 4-I. Introduction to SearcHD

The existing learning algorithms have been shown to be effective for many different tasks, e.g., object tracking, speech recognition, image classification, etc. For instance, Deep Neural Networks (DNNs) have shown great potential to be used for complicated classification problems. DNN architectures such as AlexNet and GoogleNet provide high classification accuracy for complex image classification tasks, e.g., ImageNet dataset. However, the computational complexity and memory requirement of DNNs makes them inefficient for a broad variety of real-life (embedded) applications where the device resources and power budget is limited.

Brain-inspired computing models in conjunction with recent advancements in memory technologies have opened new avenues for efficient execution of a wide variety of cognitive tasks on nano-scale fabrics. Hyperdimensional (HD) computing is based on the understanding that brains compute with patterns of neural activity that are not readily associated with numbers. HD computing builds upon a well-defined set of operations with random HD vectors and is extremely robust in the presence of hardware failures. HD computing offers a computational paradigm that can be easily applied to learning problems. Its main differentiation from conventional computing system is that in HD computing, data is represented as approximate patterns, which can favorably scale for many learning applications.

HD computation runs in three steps: encoding, training, and inference.
The encoding module maps input data into high-dimensional space using a set of randomly generated hypervectors.
In training, a traditional HD algorithm combines the encoded hypervectors in order to generate a hypervector representing each class. The algorithm simply performs element-wise additions on the hypervectors which belong to the same class.
In inference, an associative search checks the similarity of an encoded test hypervector with all trained class hypervectors and returns the class with the highest similarity score.

While HD computing can be implemented in conventional digital hardware, implementation on approximate hardware can yield substantial efficiency gains with minimal to zero loss in accuracy.

Processing in-memory (PIM) is a promising solution to accelerate HD computations running for memory-centric applications by enabling parallelism. PIM performs some or all of a set of computation tasks (e.g., bit-wise or search computations) inside the memory without using any processing cores. Thus application performance may be accelerated significantly by avoiding the memory access bottleneck. In addition, PIM architectures enable analog-based computation in order to perform approximate but ultra-fast computation (i.e., existing PIM architectures perform computation with binary vectors stored in memory rows). Past efforts have tried to accelerate HD computing via PIM. For example, in-memory hardware can be designed to accelerate the encoding module. A content-addressable memory can perform the associative search operations for inference over binary hypervectors using a Hamming distance metric. However, the aforementioned accelerators can only work with binary vectors, which in turns only provide high classification accuracies on simpler problems, e.g., language recognition which uses small n-gram windows of size five to detect words in a language. In this work, we observed that acceptable classification accuracy can be achieved using non-binary encoded hypervectors, non-binary training and associative search on a non-binary model using metrics such as such as cosine similarity. This hinders the implementation of many steps of the existing HD computing algorithms using in-memory operations.

In order to fully exploit the advantage of in-memory architecture, we disclose SearcHD, a fully binary HD computing algorithm with probability-based training. SearcHD maps every data point to high-dimensional space with binary elements and then assigns multiple vectors representing each class. Instead of performing addition, SearcHD performs binary training by changing each class hypervector depending on how well it matches with a class that it belongs to. Unlike most recent learning algorithms, e.g., neural networks, SearcHD supports a single-pass training, where it trains a model by one time passing through a training dataset. The inference step is performed by using a Hamming distance similarity check of a binary query with all prestored class hypervectors. All HD computing blocks, including encoding, training, and inference are implemented fully in memory without using any nonbinary operation. SearcHD exploits the analog characteristic of ReRAMs to perform the encoding functionalities, such as XOR and majority functions, and training/inference functionalities such as the associative search on ReRAMs.

We tested the accuracy and efficiency of the disclosed SearcHD on four practical classification applications. Our evaluation shows that SearcHD can provide on average 31.1× higher energy efficiency and 12.8× faster training as compared to the state-of-the-art HD computing algorithms. In addition, during inference, SearcHD can achieve 178.7× higher energy efficiency and 14.1× faster computation while providing 6.5% higher classification accuracy than state-of-the-art HD computing algorithms.

### 4-II. SearcHD Landscape

HD computation is a computational paradigm inspired by how the brain represents data. HD computing has previously shown to address energy bounds which plague deterministic computing. HD computing replaces the conventional computing approach with patterns of neural activity that are not readily associated with numbers. Due to the large size of brain circuits, this neurons pattern can be represented using vectors in thousands of dimensions, which are called hypervectors. Hypervectors are holographic and (pseudo)random with i.i.d. components. Each hypervector stores the information across all its components, where no component has more responsibility to store any piece of information than another. This makes HD computing extremely robust against failures. HD computing supports a well-defined set of operations, such as binding that forms a new hypervector which associates two hypervectors, and bundling that combines several hypervectors into a single composite hypervector. Reasoning in HD computing is based on the similarity between the hypervectors.

FIG. 29 shows an overview of how HD computing performs a classification task. The first step in HD computing is to map (encode) raw data into a high-dimensional space. Various encoding methods have been proposed to handle different data types, such as time series, text-like data, and feature vectors. Regardless of the data type, the encoded data is represented with a D-dimensional vector (H∈ [symbol] D). Training is performed by computing the element-wise sum of all hypervectors corresponding to the same class ({C1, . . . , CK}, Ci∈ [symbol] D), as shown in FIG. 29. For example, in an application with k classes, the ith class hypervector can be computed as:

$${C}_{i} = {\sum }_{∀ j ∈ {class}_{i}} {H}_{j} .$$

This training operation involves many integer (nonbinary) additions, which makes the HD computation costly. During inference, we simply compare a similarity score between an encoded query hypervector and each class hypervector, returning the most similar class. Prior work has typically used the cosine similarity (inner product) which involves a large number of nonbinary additions and multiplications. For example, for an application with k classes, this similarity check involves k×D multiplication and addition operations, where the hypervector dimension is D, commonly 10,000.

TABLE 4-I
CLASSIFICATION ACCURACY AND EFFICIENCY OF
HD COMPUTING USING BINARY AND NONBINARY MODELS

| | Accuracy | | Inference Execution (ms) | | |
|---|---|---|---|---|---|
| | Non- | | Non- | | |
| Applications | Binary | Binary | Binary | Binary | Analog |
| Speech Recognition | 834% | 78.6% | 3240.5 | 538.4 | 74.1 |
| Cardiotocograms | 78.7% | 73.5% | 791.0 | 131.8 | 18.2 |
| Activity Recognition | 82.3% | 79.2% | 2025.2 | 337.7 | 50.9 |
| Security Prediction | 94.0% | 91.4% | 494.3 | 272.9 | 13.2 |

Table 4-I shows the classification accuracy and the inference efficiency of HD computing on four practical applications (large feature size) when using binary and nonbinary models. All efficiency results are reported for running the applications on digital ASIC hardware. Our evaluation shows that HD computing with the binary model has 4% lower classification accuracy than the nonbinary model. However, in terms of efficiency, HD computing with the binary model can achieve on average 6.1× faster computation than the nonbinary model. In addition, HD computing with the binary model can use Hamming distance for similarity check of a query and class hypervectors which can be accelerated in a content addressable memory (CAM). Our evaluation shows that such analog design can further speedup the inference performance by 6.9× as compared to digital design.

### 4-III. SearcHD: Fully Binary HD Computing

We disclose herein SearcHD, a fully binary HD computing algorithm, which can perform all HD computing operations, i.e., encoding, training, and inference, using binary operations. In the rest of the section, we explain the details of the disclosed approach. We first explain the functionality of the encoding, training, and inference modules, and then illustrate how module functionality can be supported in hardware.

### 4-III.1 SearcHD Encoding

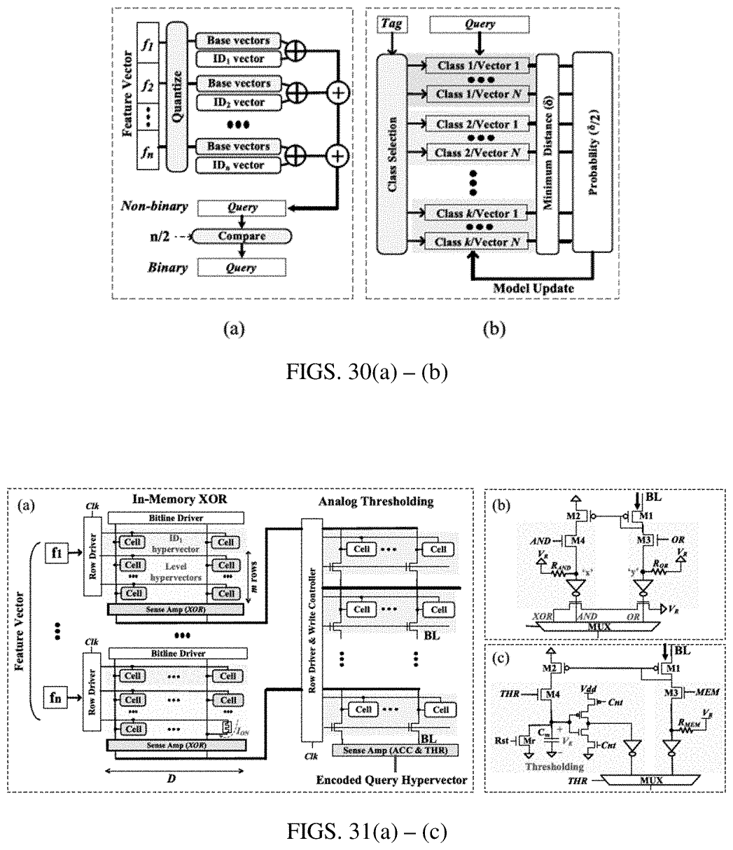

There are different types of encoding methods to map data points into an HD space. For a general form of feature vectors, there are two popular encoding approaches: 1) record-based and 2) n-gram-based encoding. Although SearcHD functionality is independent of the encoding module here we use a record-based encoding which is more hardware friendly and only involves bitwise operations as shown in FIG. 30a. This encoding maps any feature vector F={ƒ₁, ƒ₂, . . . , ƒₙ} with n features (ƒ∈ [symbol] ), into H={h₁, h2, . . . , h_{D}} with D dimensions (hᵢ∈{0,1}). This encoding finds the minimum and maximum feature values and quantizes that range linearly into m levels. Then, it assigns a random binary hypervector with D dimensions to each of the quantized level {L₁, . . . , Lₘ}. The level hypervectors need to have correlation, such that the neighbor levels are assigned to similar hypervectors. For example, we generate the first level hypervector, L₁, by sampling uniformly at random from 0 or 1 values. The next level hypervectors are created by flipping D/m random bits of the previous level. As a result, the level hypervectors have similar values if the corresponding original data are closer, while L₁ and Lₘ will be nearly orthogonal. The orthogonality between the bipolar/binary hypervectors defines when two vectors have exactly 50% similar bits. This results in a zero cosine similarity between the orthogonal vectors.

Similarly, the encoding module assigns a random binary hypervector to each existing feature index, {ID₁, . . . , IDₙ}, where ID∈{0,1}D. The encoding linearly combines the feature values over different indices:

H=ID₁⊕L̅₁+ID₂⊕L̅₂+ . . . +IDₙ⊕L̅ₙ

where H is the nonbinary encoded hypervector, ⊕ is XOR operation, and L̅ᵢ∈{L1, . . . , Lm} is the binary hypervector corresponding to the ith feature of vector F. In this encoding, IDs preserve the position of each feature value in a combined set. SearcHD encodes this hypervector by passing each dimension through a majority function. This approach compares each dimension with a threshold value, where a threshold value is equal to half of the number of features (THR=n/2).

### 4-III.2. Binary Stochastic Training

In HD computing, when two data hypervectors are randomly generated, the probability that their hypervectors are orthogonal to each other is high. In training, hypervectors of data in the same class are made appropriately more or less similar to each other. In more recent HD computing algorithms, training consists of additions of the encoded hypervectors, thus requiring a large number of arithmetic operations to generate nonbinary class hypervectors. Our disclosed SearcHD is a framework for binarization of the HD computing technique during both training and inference. SearcHD removes the addition operation from training by exploiting bitwise substitution which trains a model by stochastically sharing the query hypervectors elements with each class hypervector. Since HD computing with a binary model provides low classification accuracy, SearcHD exploits vector quantization to represent an HD model using multiple vectors per class. This enables SearcHD to store more information in each class while keeping the model as binary vectors.

1) SearcHD Bitwise Substitution: SearcHD removes all arithmetic operations from training by replacing addition with bitwise substitution. Assume A and B are two randomly generated vectors. In order to bring vector A closer to vector B, a random (typically small) subset of vector B's indices is forced onto vector A by setting those indices in vector A to match the bits in vector B. Therefore, the Hamming distance between vector A and B is made smaller through partial cloning. When vector A and B are already similar, then indices selected probably contain the same bits, and thus the information in A does not change. This operation is blind since we do not search for indices where A and B differ, and then “fix” those indices. Indices are chosen randomly and independently of whatever is in vector A or vector B. In addition, the operation is one-directional. Only the bits in vector A are transformed to match those in vector B, while the bits in vector B stay the same. In this sense, A inherits an arbitrary section of vector B. We call vector A the binary accumulator and vector B the operand. We refer to this process as bitwise substitution.

2) SearcHD Vector Quantization: Here, we present our fully binary stochastic training approach, which enables the entire HD training process to be performed in the binary domain. Similar to traditional HD computing techniques, SearcHD trains a model by combining the encoded training hypervectors. As we explained in Section 4-II, HD computing using binary model results in very low classification accuracy. In addition, moving to the nonbinary domain makes HD computing significantly more costly and inefficient. In this work, we disclose vector quantization. We exploit multiple vectors to represent each class in the training of SearcHD. The training keeps distinct information of each class in separated hypervectors, resulting in the learning of a more complex model when using multiple vectors per class. For each class, we generate N models (where N is generally between 4 and 64). Below we explain the details of the methods of operating SearcHD.
Initialize the N model vectors to a class by randomly sampling from the encoded training hypervector of that class as shown in FIG. 30b. For an application with k classes, the approach needs to store N×k binary hypervectors as the HD model. For example, we can represent the wi^{th} class using N initial binary hypervectors {C₁ⁱ, C₂ⁱ, . . . , C_{N}ⁱ}, where Cⁱ∈{0,1}^{D}
The training in HD computing starts by checking the similarity of each encoded data point (training dataset) to the initial model. The similarity check only happens between the encoded data and N class hypervectors corresponding to that label. For each piece of training data Q in a class, find the model with the lowest Hamming distance and update the model using bitwise substitution (explained in Section 4-III-B1). For example, in the i^{th} class, if Cik is selected as a class with the highest similarity, we can update the model using:

Cₖⁱ=Cₖⁱ(+)Q

In the above equation, (+) is the bitwise substitution operation, Q is the operand, and Cₖⁱ is the binary accumulator. This technique helps reduce the memory access overhead introduced by using bitwise substitution. This approach accumulates training data more intelligently: given the choice of adding an incoming piece of data to one of N model vectors, we can select the model with the lowest Hamming distance to ensure that we do not needlessly encode information in our models.

3) SearcHD Training Process: Binary substitution updates each dimension of the selected class stochastically with p=α×(1−δ) probability, where δ is a similarity between the query and the class hypervector and α is a learning rate. In other words, with flip probability p, each element of the selected class hypervector will be replaced with the elements of the query hypervector. α is the learning rate (0<α) which determines how frequently the model needs to be updated during the training. Using a small learning rate is conservative, as the model will have minor changes during the training. A larger learning rate will result in a major change to a model after each iteration, resulting in a higher probability of divergence.

### 4-III.3. Inference:

After updating the model on the entire training dataset, SearcHD uses the trained model for the rest of the classification during inference. The classification checks the similarity of each encoded test data vector to all class hypervectors. In other words, a query hypervector is compared with all N×k class hyprevectors. Finally, a query identifies a class with the maximum Hamming distance similarity with the query data.

### 4-IV. In-Memory Classification in Hd Space

SearcHD uses bitwise computations over hypervectors in both training and inference modes. These operations are fast and efficient when compared to floating point operations used by neural networks or other classification algorithms. This enables HD computing to be trained and tested on light-weight embedded devices. However, as traditional CPU/GPU cores have not been designed to efficiently perform bitwise operations over long vectors, we provide a custom hardware realization of SearcHD. Here, we show how to use the analog characteristics of ReRAMs, in particular ReRAM devices, to process all HD computing functionality within a memory.

### 4-IV.1. Overview

HD computing operations can be supported using two main encoding and associative search blocks. In Section 4-IV.2, we explain the details of the in-memory implementation of the encoding module.

During training, SearcHD performs a single pass over the training set. For each class, SearcHD first randomly selects N data points from the training dataset as representative class hypervectors. Then, SearcHD uses CAM blocks to check the similarity of each encoded hypervector (from the training dataset) with the class hypervectors. Depending on the tag of input data, SearcHD only needs to perform the similarity check on N hypervectors of the same class as input data. For each training sample, we find a hypervector in a class which has the highest similarity with the encoded hypervector using a memory block which supports the nearest Hamming distance search. Then, we update the class hypervector depending on how well/close it is matched with the query hypervector (δ). To implement this, we exploit an analog characteristic of ReRAMs to identify how well a query data is matched with the most similar class. We exploit the feature of ReRAM devices to generate a random stochastic sequence with the desired probability. This sequence needs to have a similar number of zeros as the difference between a query and the class hypervector. Finally, we update the elements of a selected class by performing an in-memory XNOR operation between: (i) the class and (ii) the stochastically generated hypervector. In the following section, we explain how SearcHD can support all of these operations in an analog fashion.

During inference, we employ the same CAM block used in training to implement the nearest Hamming distance search between a query and all class hypervectors. For an application with k classes and N class hypervectors, SearcHD requires similarity comparisons between the query and k×N stored class hypervectors. The hardware introduced in Section 4-IV.3, explains the details of in-memory search implementation.

### 4-IV.2. In-Memory Encoding

The encoder, shown in FIG. 31a, implements bitwise XOR operations between hypervectors P and L over different features, and thresholds the results. To support this functionality, our analog design assigns a small size crossbar memory (m+1 rows with D dimensions) to each input feature, where the crossbar memory stores the corresponding position hypervector (ID) along with all m possible level hypervectors that each feature can take (m is the number of level hypervectors, as defined in Section 4-III). The results of all XOR operations are written to another crossbar memory. Next, the memory that stores the XOR results perform the bitwise majority operation on the entire memory. In conventional crossbar memory, the write-in the majority block needs to perform serially over different features. However, in this work, we use switches (shown in FIG. 31a) that enables parallel write in the majority block. These switches portioned memory rows into a separated block, enabling all XOR results to be written in majority block independently. We accomplish this operation by designing a sense amplifier for the crossbar memory that can detect whether the number of 1's is above a certain threshold (THR). This Majority function does not involve actual counting but uses the analog characteristics of ReRAM devices, making it a significantly faster and more efficient design.

In-Memory XOR: To enable an XOR operation as required by the encoding module, the row driver must activate the line corresponding to the position hypervector (ID shown in FIG. 31a). Depending on the feature value, the row driver activates one more row in the crossbar memory which corresponds to the feature value. Our analog design supports bitwise XOR operations inside the crossbar memory among two activated rows. This design enables in-memory XOR operations by making a small modification to the sense amplifier of the crossbar memory, as shown in FIG. 31b. We place a modified sense amplifier at the tail of each vertical bitline (BL). The BL current passes through the R_{OR} and R_{AND}, and changes the voltage in node ‘x’ and ‘y’. A voltage larger than a threshold in node ‘x’ and ‘y’ results in inverting the output values of the inverters, realizing the AND and OR operations. We use the combination of AND and OR operations to generate XOR. In our design, R_{OR}, R_{AND}, and V_{R} are tuned to ensure the correct functionality of the design considering process variations. It should be noted that the same XOR functionality could be implemented using a series of MAGIC NOR operation. The advantage of this approach is that we do not need to make any changes to the sense amplifier. However, the clock cycle of MAGIC NOR is at the order of 1 ns, while the disclosed approach computes XOR in less than 300 ps.

In-Memory Majority: FIG. 31c shows the sense amplifier designed to implement the majority function. To evaluate this function, a row driver activates all rows of the crossbar memory. Any cell with low resistance injects current into the corresponding vertical BL. The number of 0s in each column determines the amount of current in the BL. The charging rate of the capacitor Cₘ in the disclosed sense amplifier depends on the number of zeroes in each column. The sense amplifier samples the capacitor voltage at a specific time, which intuitively is the same as comparing the BL current with a THR=n/2 value. Since the charging current is constant, the voltage grows linearly with time, thus the “specific time” can be equal to twice the time where Cₘ is charged by the maximum current. Our design can use different predetermined THR values in order to tune the level of thresholding for applications with different feature sizes.

### 4-IV.3. In-Memory Associative Search

The goal of this search operation is to find a class with the highest similarity. We employ crossbar CAMs, which can search the nearest Hamming distance vector with respect to the stored class hypervectors. Traditionally, CAMs are only designed to search for an exact match and cannot look for a row with the smallest Hamming distance.

FIG. 32a shows an architectural schematic of a conventional CAM. A search operation in CAM starts with precharging all CAM match-lines (MLs). An input data vector is applied to a CAM after passing through an input buffer. The goal of the buffer is to increase the driving strength of the input data and distribute the input data across the entire memory at approximately the same time. Finally, each CAM row is compared with the input data. Conventional CAM can detect a row that contains an exact matching, i.e., where all bits of the row exactly match with the bits in the input data.

In this work, we exploit the analog characteristics of CAM blocks to detect the row that has the minimum Hamming distance with the query vector. Each CAM row with stored bits that are different from the provided input will discharge the associated ML. The rate of ML discharging depends on the number of mismatch bits in each CAM row. A row with the nearest Hamming distance to the input data is the one with the lowest ML discharging current, resulting in the longest discharging time. To find this row, we need to keep track of all other MLs and determine when only a single ML is still discharging.

FIG. 32b shows the general structure of the disclosed CAM sense amplifier. We implement the nearest Hamming distance search functionality by detecting the CAM row (most closely matched line) which discharges last. This is realized with three main blocks: (i) detector circuitry which samples the voltage of all MLs and detects the ML with the slowest discharge rate; (ii) a buffer stage which delays the ML voltage propagation to the output node; and (iii) a latch block which samples buffer output when the detector circuit detects that all MLs are discharged. The last edge detection can be easily implemented by NORing the outputs of all matched lines, which is set when all MLs are discharged to zero. However, a conventional implementation of NOR leads to a huge number of transistors and increased latency as the number of inputs rises beyond 3.

Here, we disclose the use of a Ganged CMOS-based NOR circuit, which not only provides faster results but can also support larger fan-in with acceptable noise margin. FIGS. 32b and 32c shows the circuit consisting of skewed inverters with their outputs shorted together. The behavior of the circuit is defined by the ratio r=I/J, where I and J are the sizes of the pull-up and pull-down transistors, respectively. For r>q, the inverter is highly skewed and has a stronger pull-up, while for r<q, it is lowly skewed and has a stronger pull-down. (q is a technology-dependent parameter.) If r is sufficiently small, outputs of multiple skewed inverters can be shorted together to implement the NOR operation. FIGS. 32b and 32c shows that the output of the circuit is set only when all the nMOS devices are off, i.e., all MLs are zero. The output of ganged NOR circuit controls the latch. The buffer stage used in the sense circuit adds delay to the ML voltage. This delay should be sufficiently large to ensure that we can latch on the last falling ML, when the ganged logic senses that all MLs have fallen to zero.

### 4-IV.4. In-Memory Distance Detector

In training, SearcHD uses the disclosed CAM block to find a hypervector which has the highest similarity with a query data. Then, SearcHD needs to update the selected class hypervector with the probability that is proportional to how well a query is matched with the class. After finding a class hypervector with the highest similarity, SearcHD performs the search operation on the selected row. This search operation finds how closely the selected row matches with the query data. This can be sensed by the distance detector circuit shown in FIG. 32d. Our analog implementation transfers the discharging current of a CAM row into a voltage (Vₖ) and compares it with a reference voltage (V_{TH}). The reference voltage is the minimum voltage that V_{K} can take when all query dimensions of a query hypervector match with the class hypervector.

### 4-IV.5. In-Memory Random Generation and Model Update

Depending on the distance similarity difference between a query and the class hypervector, SearcHD generates a random sequence of a bit stream which has a proportional number of is. For example, for a query with δ similarity between the query and the class hypervector, SearcHD generates a random sequence with p=α×(1−δ) probability of “1” bits. During training, SearcHD selects the class hypervector with the minimum Hamming distance from the query data and updates the selected class hypervector by bitwise substitution of a query and the class hypervector. This bitwise substitution is performed stochastically on random p×D of the class dimensions. This requires generating a random number with a specific probability.

ReRAM switching is a stochastic process, thus the write operation in a memristor device happens with a probability which follows a Poisson distribution. This probability depends on several factors, such as programming voltage and write pulse time. For a given programming voltage, we can define the switching probability as:

$$P ( t ) = 1 - {e}^{- t / τ} τ ( V ) = {τ}_{0} {e}^{- V / {V}_{0}}$$

where τ is the characterized switching time that depends on the programming voltage, V, and τ₀ and V₀ are the fitting parameters. To ensure memristor switching with high probability, the pulse width should be long enough. For example, using t=τ, the switching probability is as low as P (t=τ)=63%, while using t=10τ increases this probability to P (t=10τ)=99.995%. We exploit the nondeterministic ReRAM switching property to generate random numbers. Depending on the applied voltage, a pulse time is assigned to set the device switching probability to the desired percentage. For example, to generate numbers with 50% probability, the pulse time (α) has been set to ensure p (t=ατ)=50%.

Assume a class hypervector with D dimensions, Cⁱ={c₁, c₂, . . . , c_{D}}. Random generation creates a bit sequence with D dimensions, R={r₁, r₂, . . . , r_{D}} but with p probability of bits to be “1.” We update the selected class hypervector in two steps: (i) we read the random hypervector R using a memory sense amplifier to select the bits for the bitwise substitution operation. Then, we activate the row of a selected class hypervector and apply R as a bitline buffer to reset corresponding class elements where R has “1” values there. (ii) SearcHD reads the query hypervector (Q) and calculates the AND of the query and R hypervector. Our design uses the result of the AND operation as a bitline buffer in order to set the class elements in all dimensions where the bitline buffer has a “1” value. This is equivalent to injecting the query elements into a class hypervector in all dimensions where R has nonzero values.

### 4-V. Evaluation

We tested the functionality of SearcHD in both software and hardware implementations. We first discuss the impact of learning rate and class configurations on SearcHD classification accuracy. We then compare the energy efficiency and performance of SearcHD with baseline HD computing during training and inference. We finally discuss the accuracy-efficiency tradeoff with respect to hypervector dimensions.

### 4-V.1. Experimental Setup

We tested the functionality of SearcHD in both software and hardware implementations. In software, we verify SearcHD training and inference functionalities by a C++ implementation of the stochastic technique on an Intel Core i7 7600 CPU. For the hardware implementation, we have designed a cycle-accurate simulator which emulates HD computing functionality. Our simulator prestores the randomly generated level and position hypervectors in memory and performs the training and inference operations fully in the disclosed in-memory architecture. We extract the circuit level characteristic of the hardware design from simulations based on a 45-nm CMOS process technology using the Hewlett simulation program with integrated circuit emphasis (HSPICE) simulator. We use the VTEAM ReRAM model for our memory. The model parameters of the device, as listed in Table 4-II, are chosen to produce switching delay of Ins, a voltage pulse of 1V and 2V for RESET and SET operations in order to fit practical devices. The energy of set and reset operations are Eₛₑₜ=23.8 fJ and Eᵣₑₛₑₜ=0.32 fJ, respectively. The functionality of all the circuits has been validated considering 10% process variations on threshold voltage, transistor sizes, and ReRAM OFF/ON resistance using 5000 Monte Carlo simulations. Table 4-III lists the design parameters, including the transistor sizes and AND/OR resistance values.

TABLE 4-II
VTEAM MODEL PARAMETERS FOR MEMRISTOR

| kₒₙ | 216.2 m/sec | V_{T,ON} | −1.5 V | x_{off} | 3 nm |
|---|---|---|---|---|---|
| k_{off} | 0.091 m/sec | V_{T,OFF} | 0.3 V | R_{ON} | 10 kΩ |
| αₒₙ, α_{off} | 4 | Xₒₙ | 0 | R_{OFF} | 10 MΩ |

TABLE 4-III
Circuit Parameters

| Transistor Size (W/L) | | | | | Resistance Values (Ω) | | | Voltage |
|---|---|---|---|---|---|---|---|---|
| M1 | M2 | M3 | M4 | Mr | AND | OR | MEM | V_{R} |
| 2 | 4 | 2 | 4 | 1 | 1.2 k | 5 k | 5 k | 1 V |

We tested SearcHD accuracy and energy/performance efficiency on four practical classification applications. Table 4-IV summarizes the configurations with various evaluation datasets.

TABLE 4-IV
DATASETS (n: FEATURE SIZE, k: NUMBER OF CLASSES)

| | | | Train | Test | |
|---|---|---|---|---|---|
| | n | K | Size | Size | Description |
| ISOLET | 617 | 26 | 6,238 | 1,559 | Speech recognition |
| FACE | 608 | 2 | 22,441 | 2,494 | Face recognition |
| UCIHAR | 561 | 12 | 6,213 | 1,554 | Activity recognition |
| IOT | 115 | 2 | 40,000 | 2,494 | IoT Botnet detection |

### 4-V.2. SearcHD and Learning Rate

Table 4-V shows the impact of the learning rate a on SearcHD classification accuracy. Our evaluation shows that using a very small learning rate reduces the capability of a model to learn since each new data can only have a minor impact on the model update. Larger learning rates result in more substantial changes to a model, which can result in possible divergence. In other words, large α values indicate that there is a higher chance that the latest training data point will change the model, but it does not preserve the changes that earlier training data made on the model. In this article, our evaluation shows that using a values of 1 and 2 provide the maximum accuracy for all tested datasets.

TABLE 4-V
Impact Of Learning Rate On SearcHD Classification Accuracy

| α | 0.1 | 0.5 | 1 | 2 | 3 |
|---|---|---|---|---|---|
| ISOLET | 83.6% | 85.2% | 85.2% | 82.9% | 81.4% |
| FACE | 88.4% | 90.1% | 90.2% | 89.5% | 88.7% |
| UCIHAR | 90.2% | 91.1% | 91.3% | 90.8% | 90.0% |
| IOT | 98.5% | 99.7% | 99.9% | 97.9% | 96.8% |

### 4-V.3. SearcHD Accuracy in Different Configurations

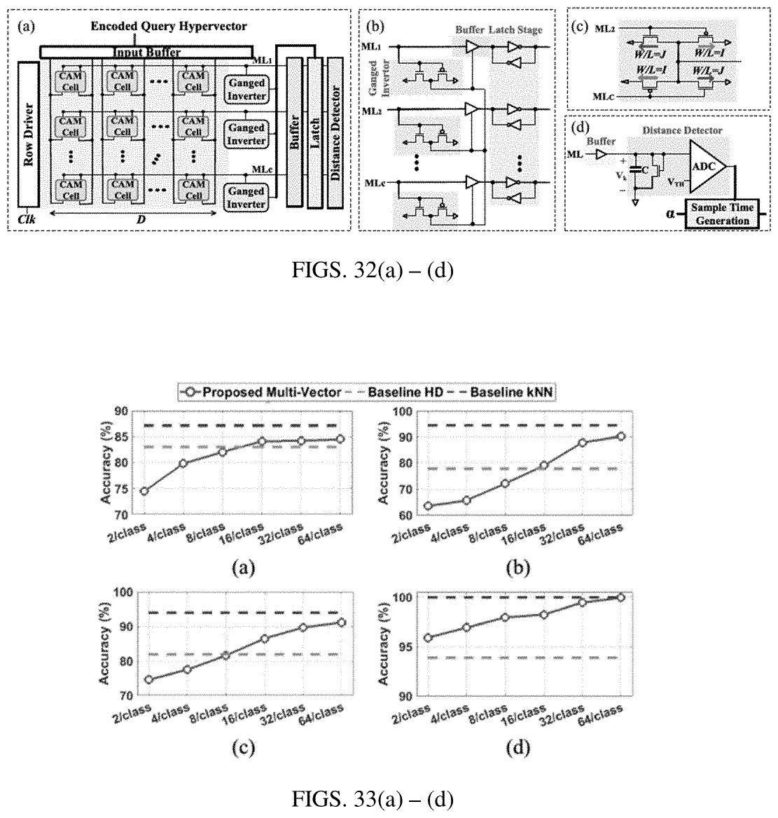

FIG. 33 shows the impact of the number of hypervectors per each class N on SearcHD classification accuracy in comparison with other approaches. The state-of-the-art HD computing approaches use a single hypervector representing each class. As the figure shows, for all applications, increasing the number of hypervectors per class improves classification accuracy. For example, SearcHD using eight hypervectors per class (8/class) and 16 hypervectors per class (16/class) can achieve on average 9.2% and 12.7% higher classification accuracy, respectively, as compared to the case of using 1/class hypervector when running on four tested applications. However, SearcHD accuracy saturates when the number of hypervectors is larger than 32/class. In fact, 32/class is enough to get most common patterns in our datasets, thus adding new vectors cannot capture different patterns than the existing vectors in the class.

The red line in each graph shows the classification accuracy that a k-Nearest Neighbor (kNN) algorithm can achieve. kNN does not have a training mode. During Inference, kNN looks at the similarity of a data point with all other training data. However, kNN is computationally expensive and requires a large memory footprint. In contrast, SearcHD provides similar classification accuracy by performing classification on a trained model. FIG. 33 also compares SearcHD classification accuracy with the best baseline HD computing technique using nonbinary class hypervectors. The baseline HD model is trained using nonbinary encoded hypervectors. After the training, it uses a cosine similarity check for classification. Our evaluation shows that SearcHD with 32/class and 64/class provide 5.7% and 7.2% higher classification accuracy, respectively, as compared to the baseline HD computing with the nonbinary model.

Table 4-VI compares the memory footprint of SearcHD, kNN, and the baseline HD technique (nonbinary model). As we expect, kNN has the highest memory requirement, by taking on average 11.4 MB for each application. After that, SearcHD 32/class and the baseline HD technique require similar memory footprints, which are on average about 28.2× lower than kNN. SearcHD can further reduce the memory footprint by reducing the number of hypervectors per class. For example, SearcHD with 8/class configuration provides 117.1× and 4.1× lower memory than kNN and the baseline HD technique while providing similar classification accuracy.

TABLE 4-VI
MEMORY FOOTPRINT OF DIFFERENT ALGORITHMS (MB)

| | | | SearcHD | | | | |
|---|---|---|---|---|---|---|---|
| | | Baseline | 64/ | 32/ | | | |
| | kNN | HD | class | class | 16/class | 8/class | 4/class |
| UISOLET | 14.67 | 0.99 | 1.98 | 0.99 | 0.49 | 0.24 | 0.12 |
| CARDIO | 0.15 | 0.11 | 0.22 | 0.11 | 0.05 | 0.02 | 0.01 |
| UCHIAR | 13.29 | 0.45 | 0.91 | 0.45 | 0.22 | 0.11 | 0.05 |
| IOT | 17.54 | 0.07 | 0.15 | 0.07 | 0.04 | 0.02 | 0.01 |

### 4-V.4. Training Efficiency

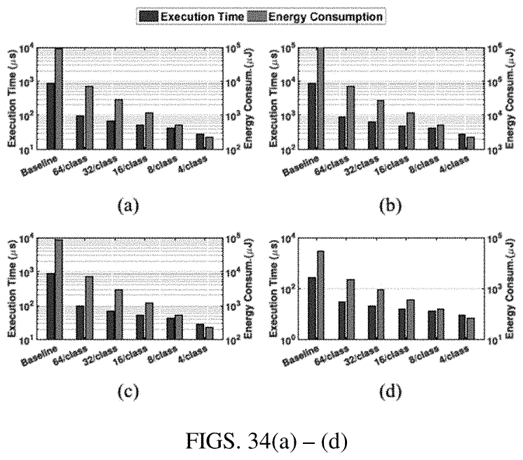

FIG. 34 compares the energy efficiency and performance of SearcHD training and the baseline HD computing technique. Regardless of whether binary or nonbinary models are employed, the baseline HD computing approach has the same training cost. Baseline HD computing encodes data in the nonbinary domain and then adds the input data in order to create a hypervector for each class. This operation cannot map into a crossbar memory architecture as the memory only supports the bit-wise operation. In contrast, SearcHD simplifies the training operation by eliminating all nonbinary operations from HD training. Our evaluation showed that SearcHD with 64/class (32/class) configuration can achieve on average 12.2× and 9.3× (31.1× and 12.8×) higher energy efficiency and speedup as compared to the baseline HD computing technique.

### 4-V.5. Inference Efficiency

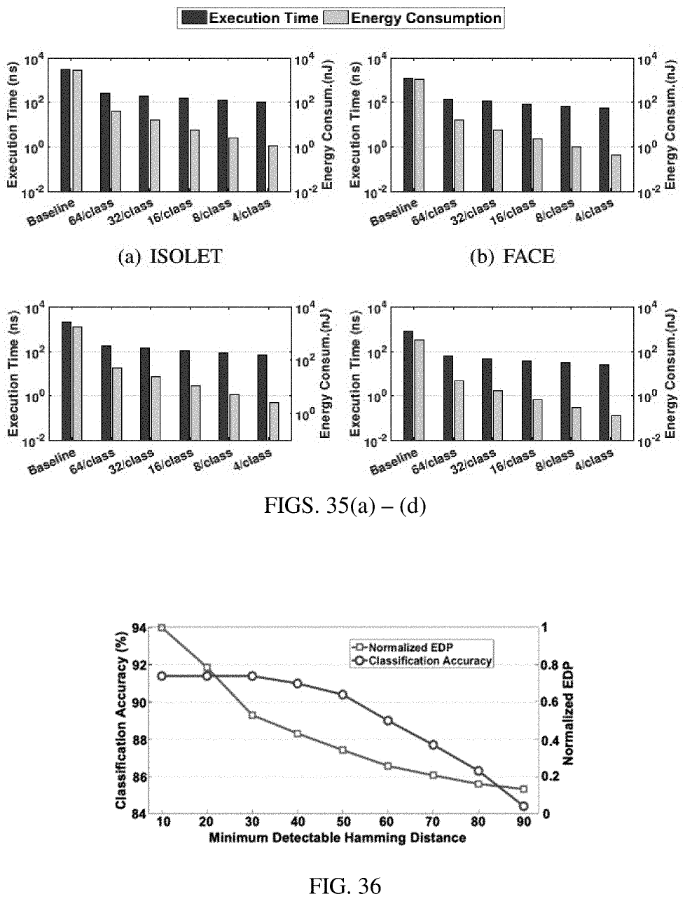

FIG. 35 compares SearcHD and baseline HD computing efficiency during inference. The y-axis shows the energy consumptions and execution times of the baseline HD computing and SearcHD technique with the number of hypervectors per class ranging from 4 to 64. The baseline HD technique uses cosine as the similarity metric, while SearcHD uses Hamming distance and accelerates this computation via analog, in-memory hardware. Our evaluation shows that SearcHD with all configurations can provide significantly faster and more energy-efficient computation as compared to the baseline HD technique. For example, SearcHD with 64/class (32/class) configuration can provide on average 66.2× and 10.8× (178.7× and 14.1×) energy efficiency and speedup as compared to a baseline HD technique, while providing 7.9% (6.5%) higher classification accuracy. The higher energy and performance efficiency of SearcHD comes from the in-memory capability in parallelizing the similarity check among different rows. In addition, the approximate search in analog memory eliminates slower digital-based counting operations.

In SearcHD, the computation cost grows with the number of hypervectors in a class. For example, SearcHD with 32/class configuration consumes 14.1× more energy and has 1.9× slower execution time as compared to SearcHD with 4/class configuration. In addition, we already observed that SearcHD accuracy saturates when using models with more than 32/class hypervector.

1) Detectable Hamming Distance: The accuracy of the associative search depends on the bit precision of ganged-logic design. Using large-size transistors in the ganged logic will result in a faster response to ML discharging, thus improving the detection accuracy of the row with the minimum Hamming distance to the input. FIG. 36 shows the HD classification accuracy and the energy-delay product (EDP) of SearcHD associative memory, when we change the minimum detectable bits in design from 10 to 90 bits. The results are reported for the activity recognition dataset (UCIHAR). The EDP values are normalized to SearcHD using ten detectable Hamming distance.

As the graph shows, the design can provide acceptable accuracy when the minimum detectable number of bits is below 32. In this configuration, the associative memory can achieve an EDP improvement of 2.3× when compared to using the design with a 10-bit minimum detectable Hamming distance. That said, ganged logic in low bit precision improves the EDP efficiency while degrading the classification accuracy. For instance, 50-bits and 70-bits minimum detectable Hamming distances can provide 3× and 4.8×EDP improvement as compared to the design with 10-bit detectable Hamming distances, while providing 1% and 3.7% lower than maximum SearcHD accuracy. To find the maximum required precision in CAM circuitry, we cross-checked the distances between all stored class hypervectors. We observed that the distance between any two stored classes is always higher than 71 bits. In other words, 71 is the minimum Hamming distance which needs to be detected in our design. This feature allows us to relax the bit precision of the analog search sense amplifier which results in further improvement in its efficiency.

Prior work tried to modify the CAM structure in order to enable the nearest Hamming distance search capability. However, that design is very sensitive to dimensionality and process variations. Our evaluation on a CAM with 10 000 bits shows that SearcHD associative memory can provide 8 bits Hamming-detectable error under 10% process variations, while work in works with 22 bits Hamming-detectable error. In addition, our disclosed approach provides 3.2× higher energy efficiency and 2.0× faster as compared to work in.

### 4-V.6. Accuracy-Efficiency Tradeoff

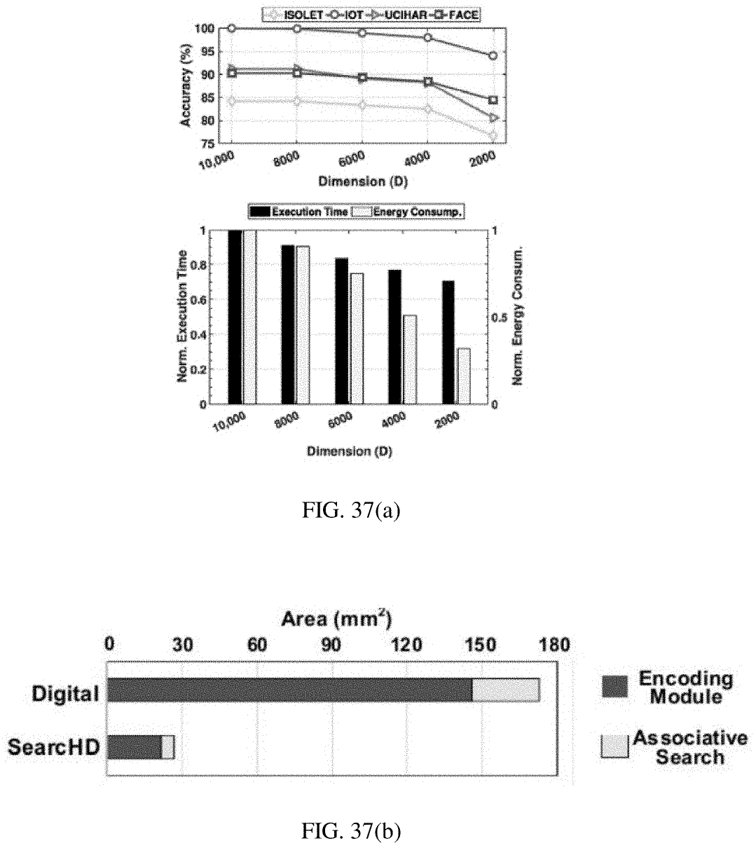

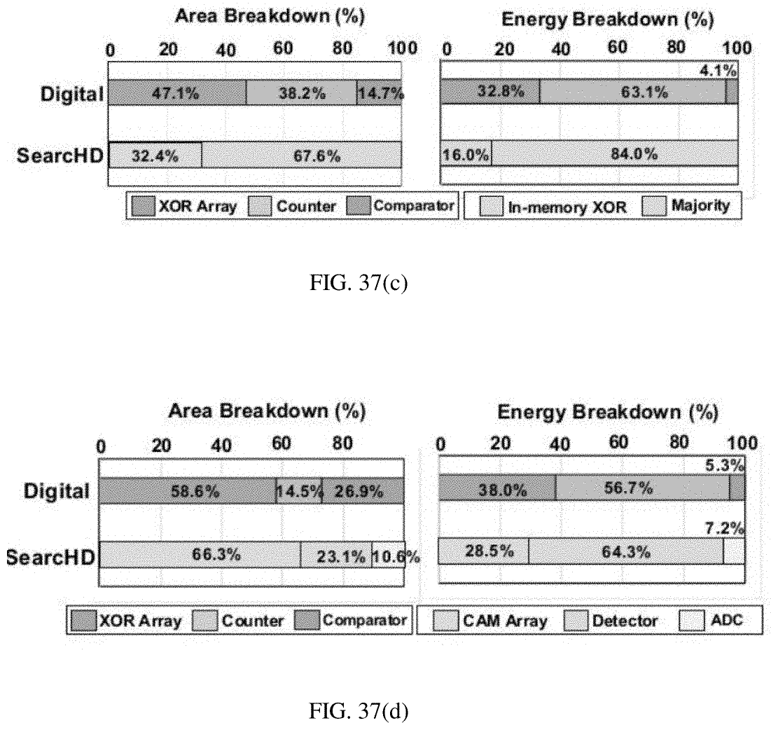

SearcHD can exploit hypervector dimensions as a parameter to trade efficiency and accuracy. Regardless of the dimension of the model at training, SearcHD can use a model in lower dimensions in order to accelerate SearcHD inference. In HD computing, the dimensions are independent, thus SearcHD can drop any arbitrary dimension in order to accelerate the computation. FIG. 37a shows the classification accuracy, normalized energy consumption, and normalized execution time of SearcHD when the hypervector dimension changes from D=2000 to 10 000. Our evaluation shows that SearcHD can achieve maximum accuracy using dimensions around D=8000. In addition, SearcHD with D=4000 (D=6000) can achieve 2.0× and 1.3× (1.3× and 1.2×) higher energy efficiency and speedup than SearcHD with D=10000 while providing only 2.1% (1.2%) lower classification accuracy.

### 4-V.7. Area/Energy Breakdown

Here, we compare the area and energy breakdown of digital HD computing with SearcHD analog implementation. FIG. 37b shows the area occupied by the encoding and associative search modules. In a digital implementation, encoding takes a large amount of chip area, as it requires to encode data points with up to 800 features. In contrast, analog implementation takes significantly lower area in both encoding and associative search modules. The analog majority computation in the encoding modules and the analog detector circuit in the associative search module eliminate large circuits for digital accumulation. This results in 6.5× area efficiency of the analog as compared to digital implementation.

FIG. 37c shows the area and energy breakdown of the encoding module in digital and analog implementations. In digital, XOR array and accumulator are taking the majority of the area and energy consumption. The accumulator has a higher portion of energy, as this block requires to sequentially add the XOR results. In analog implementation, the majority function dominating the total area and energy, while XOR computation takes about 32% of the area and 16% of energy. This is because the majority module uses a large sense amplifier and exploits switches to split the memory rows (enabling parallel write). FIG. 37d shows the area and energy breakdown of the associative search module in both digital and analog implementation. Similar to the encoding module, in digital implementation, XOR array and accumulator are dominating the total area and energy consumption. In analog, the CAM block is dominating the area, as it requires to store all class hypervectors. However, in terms of energy, the detector circuit takes over 64% of total energy. The ADC block takes about 10% area and 7.2% of the energy, as we only require a single ADC block in each associative search module.

### 4-V.8. Hardware Efficiency

To show the advantage of the in-memory implementation, we compare the efficiency of SearcHD with the digital implementation in two configurations: (i) optimized digital implementation with 6.5× larger area than analog and (ii) digital which takes the similar area as analog. The results in Table 4-VII are reported for both training and inference phases, when our implementation provides a similar accuracy as the baseline digital implementation. Our evaluation shows that analog design provides 25.4× and 357.5× (23.5× and 1243.4×) speedup and energy efficiency as compared to optimized digital implementation during training (inference). In the same area, analog training (inference) efficiency improves to 99.4× and 458.0× (91.4× and 1883.7×) speedup and energy efficiency, respectively.

TABLE 4-VII
EFFICIENCY OF SEARCHD AS COMPARED TO DIGITAL IMPLEMENTATION:
@ OPTIMIZED AND @ SAME AREA CONFIGURATIONS

| | | Speedup | | | | Energy Efficiency | | | |
|---|---|---|---|---|---|---|---|---|---|
| | | ISOLET | FACE | UCIHAR | IOT | ISOLET | FACE | UCHIAR | IOT |
| Training | Optimized | 20.8 | 15.8 | 18.2 | 47.1 | 174.5 | 163.3 | 206.9 | 884.9 |
| | @ Area | 76.9 | 66.4 | 69.7 | 184.7 | 218.2 | 213.9 | 258.6 | 1141.5 |
| Inference | Optimized | 25.6 | 18.4 | 18.7 | 31.3 | 1093.9 | 908.0 | 455.8 | 2516.1 |
| | @ Area | 94.6 | 70.9 | 78.5 | 121.8 | 1312.7 | 1125.9 | 542.4 | 4554.1 |

### 4-V.9. SearcHD and OFF/ON Ratio

In practice, the value of OFF/ON resistance ratio has important impact on the performance of SearcHD functionality. Although we used the VTEAM model with 1000 OFF/ON resistance ratio, in practice we may have memristor devices with a lower OFF/ON ratio. Using a lower OFF/ON ratio has direct impact on the SearcHD performance. In other words, a lower ratio makes the functionality of the detector circuit more complicated, specially, for thresholding functionality. We evaluate the impact of variation on resistance ratio when the OFF/ON ration reduces to 100. Our results show that this reduction results in 5.8× and 12.5× slower XOR and thresholding functionality, respectively.

### Part 5: Associative Search Using Hyperdimensional Computing

As appreciated by the present inventors, brain-inspired Hyperdimensional (HD) computing exploits hypervector operations, such as cosine similarity, to perform cognitive tasks. In inference, cosine similarity involves a large number of computations which grows with the number of classes, this results in significant overhead. In some embodiments, a grouping approach is used to reduce inference computations by checking a subset of classes during inference. In addition, a quantization approach is used to remove multiplications by using the power of two weights. In some embodiments, computations are also removed by caching hypervector magnitudes to reduce cosine similarity operations to dot products. In some embodiments, 11.6× energy efficiency and 8.3× speedup can be achieved as compared to the baseline HD design.

### 5-I. Introduction

The emergence of the Internet of Things has created an abundance of small embedded devices. Many of these devices may be used for cognitive tasks such as: face detection, speech recognition, image classification, activity monitoring, etc. Learning algorithms such as Deep Neural Networks (DNNs) give accurate results for cognitive tasks. However, these embedded devices have limited resources and cannot run such resource-intensive algorithms. Instead, many of them send the data they collect to the cloud server, for feature analysis. However, this is not desirable due to privacy concerns, security concerns, and network resources. Thus, we need more efficient light-weight classifiers in order to perform such cognitive tasks on the embedded systems.

Brain-inspired Hyperdimensional (HD) computing can be used as a light-weight classifier to perform cognitive tasks on resource-limited systems. HD computing is modeled after how the brain works, using patterns of neural activity instead of computational arithmetic. Past research utilized high-dimension vectors (D>10,000) called hypervectors, to represent neural patterns. It showed that HD computing is capable of providing high accuracy results for a variety of tasks such as: language recognition, face detection, speech recognition, classification of time-series signals, and clustering. Results are obtained at a much lower computational cost as compared to other learning algorithms.

HD computing performs the classification task after encoding all data points to high-dimensional space. The HD training happens by linearly combining the encoded hypervectors and creating a hypervector representing each class. In inference, HD uses the same encoding module to map a test data point to high-dimensional space. Then the classification task checks the similarity of the encoded test hypervector with all pre-trained class hypervectors. This similarity check is the main HD computation during the inference. Often done with a cosine, which involves a large number of costly multiplications that grows with the number of classes. Given an application with k classes, inference requires k*D additions and multiplications to perform, where D is the hypervector dimension. Thus, this similarity check can be costly for embedded devices with limited resources.

As appreciated by the present inventors, a robust and efficient solution can reduce the computational complexity and cost of HD computing while maintaining comparable accuracy. The disclosed HD framework exploits the mathematics in high dimensional space in order to limit the number of classes checked upon inference, thus reducing the number of computations needed for query requests. We add a new layer before the primary HD layer to decide which subset of class hypervectors should be checked as possible classes for the output class. This reduces the number of additions and multiplications needed for inference. In addition, the framework removes the costly multiplication from the similarity check by quantizing the values in the trained HD model with power of two values. Our approach integrates quantization with the training process in order to adapt the HD model to work with the quantized values. We have evaluated our disclosed approach on three practical classification problems. Evaluations show that the disclosed design is 11.6× more energy efficient and 8.3× faster as compared to the baseline HD while providing similar classification accuracy.

### 5-II. Hyperdimensional Computing

HD computing uses long vectors with dimensionality in the thousands. There are many nearly orthogonal vectors in high-dimensional space. HD combines these hypervectors with well-defined vector operations while preserving most of their information. No component has more responsibility to store any piece of information than any other component because hypervectors are holographic and (pseudo) random with i.i.d. components and a full holistic representation. The mathematics governing the high-dimensional space computations enables HD to be easily applied to many different learning problems.

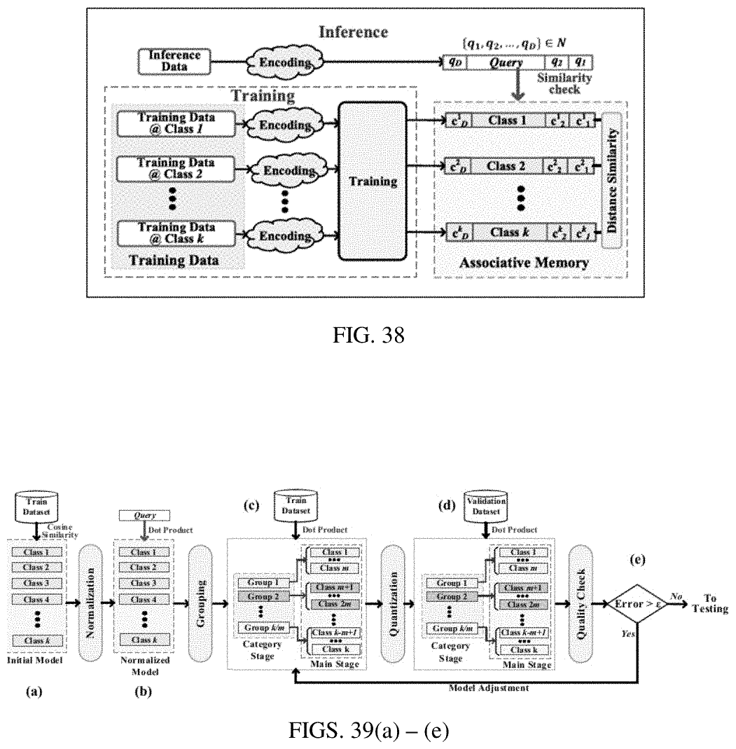

FIG. 38 shows an overview of the structure of the HD model. HD consists of an encoder, trainer, and associative search block. The encoder maps data points into high-dimensional space. These hypervectors are then combined in a trainer block to form class hypervectors, which are then stored in an associative search block. In inference, an input test data is encoded to high-dimensional space using the same encoder as the training module. The classifier uses cosine similarity to check the similarity of the encoded hypervector with all class hypervectors and find the most similar one.

### 5-II.1. Encoding

Consider a feature vector v=(v₁, . . . vₙ). The encoding module takes this n-dimensional vector and converts it into a D-dimensional hypervector (D>>n). The encoding is performed in three steps, which we describe below.

We use a set of pre-computed level or base hypervectors to consider the impact of each feature value. To create these level hypervectors, we compute the minimum and maximum feature values among all data points, vₘᵢₙ and vₘₐₓ, then quantize the range of [vₘᵢₙ, vₘₐₓ] into Q levels, L={L₁, . . . , L_{Q}}. Each of these quantized scalars corresponds to a D-dimensional hypervector.

Once the base hypervectors are generated, each of the n elements of the vector v are independently quantized and mapped to one of the base hypervectors. The result of this step is n different binary hypervectors, each of which is D-dimensional. In the last step, the n (binary) hypervectors are combined into a single D-dimensional (non-binary) hypervector. To differentiate the impact of each feature index, we devise ID hypervectors, {ID₁, . . . , IDₙ}. An ID hypervector has the binarized dimensions, i.e., IDᵢ∈{0, 1}^{D}. We create IDs with random binary values so that the ID hypervectors of different feature indexes are nearly orthogonal:

δ(IDᵢ,IDⱼ)≃D/2(i≠j&0<i,j≤n)

where the similarity metric, δ (IDᵢ, IDⱼ), is the Hamming distance between the two ID hypervectors.

The orthogonality of ID hypervectors is ensured as long as the hypervector dimensionality is large enough compared to the number of features in the original data point (D>>n). As FIG. 38 shows, the aggregation of the n binary hypervectors is computed as follows:

H=ID₁⊕L̅₁+ID₂⊕L̅₂+ . . . +IDₙ⊕L̅ₙ

where, ⊕ is XOR operation, H is the aggregation, and L̅ᵢ is the binary hypervector corresponding to the i^{th} feature of vector v.

### 5-II.2. Classification in HD Space

In HD, training is performed in high-dimensional space by element-wise addition of all encoded hypervectors in each existing class. The result of training will be k hypervectors with D dimensions, where k is the number of classes. For example, the i^{th} class hypervector can be computed as: Cⁱ=Σ_{∀j∈class}, Hⱼ

In inference, HD uses encoding and associative search for classification. First, HD uses the same encoding module as the training module to map a test data point to a query hypervector. In HD space, the classification task then checks the similarity of the query with all class hypervectors. The class with the highest similarity to the query is selected as the output class. Since in HD information is stored as the pattern of values, the cosine is a suitable metric for similarity check.

### 5-II.3. HD Computing Challenges

To understand the main bottleneck of HD computing during inference, we evaluate the HD inference on three practical classification applications, including: speech recognition, activity recognition, and image recognition. All evaluations are performed on Intel i7 7600 CPU with 16 GB memory. Our results show that the associative search takes about 83% of the total inference execution. This is because the cosine similarity has many multiplications between a query and the class hypervectors. Prior work tried to binarize the HD model after the training. This method simplifies the cosine similarity to Hamming distance measurement, which can run faster and more efficiently in hardware. However, our evaluation of three practical applications shows that binarization reduces the classification accuracy of HD with integer model by 11.4% on average. This large accuracy drop forces HD to use cosine similarity which has a significant cost when running on embedded devices.

### 5-III. HD Computing Acceleration

Disclosed herein are three optimization methods that reduce the cost of associative search during inference by at least an order of magnitude. FIG. 39 shows the overview of the disclosed optimizations. The first approach simplifies the cosine similarity calculations to dot products between the query and class hypervectors. The second reduces the number of required operations in the associative search by adding a category layer to HD computing that decides what subset of class hypervectors needs to be checked for the output class. The third removes the costly multiplications from the similarity check by quantizing the HD model after training. In the following subsections, we explain the details of each approach.

5-III.1. Similarity Check: Cosine Vs. Dot Product

During inference, HD computation encodes input data to a query hypervector, H={h_{D}, . . . , h₂, h₁}. Associative memory then measures the cosine similarity of this query with k stored class hypervectors {C¹, . . . , C^{k}}, where Cⁱ={cⁱ_{D}, . . . , cⁱ₂, cⁱ₁} is the class hypervector corresponding to the i^{th} class (FIG. 39a). The cosine similarity can be expressed as δ=H·Cⁱ/|H∥Cⁱ|, where H Cⁱ indicates the dot product between the hypervectors, and |H|=H·H and |Cⁱ|=Cⁱ·Cⁱ show the magnitudes of the query and class hypervector. However, it is very expensive to calculate the operand magnitude every time. During the similarity check, the query hypervector is common between all classes. Thus, we can skip the calculation of the query magnitude, since the goal of HD is to find the maximum relative similarity, not the exact cosine values. On the other hand, as FIG. 39b shows, the magnitude of each class hypervector can be computed once after the training. Therefore, the associative search can store the normalized class hypervectors (Cⁱ/|Cⁱ| for i∈1, . . . , k). This speeds up the similarity at inference by about 3 times as compared to cosine.

### 5-III.2. Two Level Search

Although the dot product reduces the cost of the associative search, this similarity check still involves many computations. For example, for an application with k classes, associative search computes k×D multiplication/addition operations, where D is the hypervector dimension. In addition, in existing HD computing approaches, the cost of associative search increases linearly with the number of classes. For example, speech recognition with k=26 classes has 13× more computations and 5.2× slower inference as compared to face detection with k=2 classes. Since embedded devices often do not have enough memory and computing resources, processing HD applications with large numbers of classes are more inefficient.

A method is disclosed which has two layer classification: category and main stages. FIG. 39c shows the overview of the disclosed approach. First, we group the trained class hypervectors into k/m categories based on their similarity, where k and m are the number of classes and group size respectively. For example, m=2 indicates that we group every two class hypervectors into a single hypervector. Next, we build a new HD model, called category stage, which stores all k/m group hypervectors. Instead of searching k hypervectors to classify a data point, we first search in the category stage to identify a group of classes that the query belongs to (among k/m group hypervectors). Afterwards, we continue the search in the main HD stage but only with the class hypervectors corresponding to the selected group.

### 5-III.3. Quantization

Although grouping the class hypervectors reduces the number of computations, the dot product similarity check still has many costly multiplications. We disclose a method which removes the majority of the multiplications from the HD similarity check. After training the HD model, we quantize each class value to the closest power of two (2′, i E Z). This eliminates the multiplication by allowing bit shift operations. However, this quantization is not error free. For example, the closest power of two for the number 46 would be either 32 or 64. Both of these numbers are far from the actual value. This approximation can add large errors to HD computing. The amount of error depends on the number of classes and how similar the classes are. For applications with many classes or highly correlated class hypervectors, this quantization can have a large impact of the classification accuracy.

In some embodiments, a more precise but lower power quantization approach (FIG. 39d) can be used. Each class element is assigned to a combination of 2 power of two values (2ⁱ+2^{j}, i & j∈ [symbol] ). This quantization can assign each trained class element to a value which is much closer to the actual element. For example, using this approach the number 46 can be assigned to 48=2³+2⁴, which is very close to the actual value. This enables more precise quantization with correspondingly lower impact on accuracy. This strategy implements multiplication using two shifts and a single add operation, which is still faster and more efficient than the actual multiplication. After training the HD model, we assign the class elements in both category and main stage to the closest quantized value.

Since class hypervectors are highly correlated, even this quantization can have a large impact on the classification accuracy. Quantization introduces this quality loss because the HD model is not trained to work with the quantized values. In order to ensure a minimum quality loss, we integrate quantization with the HD model retraining. This enables the HD model to learn how to work with quantized values. In the method explained in Section 5-III-D, after getting a new adjusted model, we quantize all hypervector values in the category and main stage. This approach reduces the possible quality loss due to quantization. In Section 5-IV-B, we discuss the impact of quantization on HD classification accuracy.

### 5-III.4. Training & Inference in Disclosed Design

Training. FIG. 39 shows the training process of HD with grouped hypervectors. We first train a normal HD computing model, where each hypervector represents an existing class (FIG. 39a). Next, we normalize the class hypervectors (FIG. 39b) and then check the similarity of the trained class hypervectors in order to group the classes. In our approach, we group every m class hypervectors into a single hypervector, so in the end, we have k/m group hypervectors (FIG. 39c). The grouping happens by checking the similarity of class hypervectors in pairs and merging classes with the highest similarity. The selected class hypervectors are added together to generate a group hypervector. We store these k/m group hypervectors into the category stage. After that, we quantize the values of the grouped model (FIG. 39d). This one-shot trained model can be used to perform the classification task at inference.

Model Adjustment. To get better classification accuracy, we can adjust the HD model with the training dataset for a few iterations (FIG. 39e). The model adjustment starts in the main HD stage. During a single iteration, HD checks the similarity of all training data points, say H, with the current HD model. If data is wrongly classified by the model, HD updates the model by (i) adding the data hypervector to a class that it belongs to, and (ii) subtracting it from a class which it was wrongly matched with:

$$Main \{ \begin{matrix}{\tilde{C}}_{main}^{c} = {C}_{main}^{c} + H , & where {C}_{main}^{c} is correct \\ {\tilde{C}}_{main}^{w} = {C}_{main}^{w} - H , & where {C}_{main}^{w} is wrong\end{matrix}$$

We similarly update two corresponding hypervectors in the category stage by adding and subtracting the query hypervector:

$$Category \{ \begin{matrix}{\tilde{C}}_{category}^{c} = {C}_{category}^{c} + H , & where {C}_{main}^{c} ∈ {C}_{category}^{c} \\ {\tilde{C}}_{category}^{w} = {C}_{category}^{w} - H , & where {C}_{main}^{w} ∈ {C}_{category}^{w}\end{matrix}$$

The model adjustment needs to be continued for a few iterations until the HD accuracy stabilizes over the validation data, which is a part of the training dataset. After training and adjusting the model offline, it can be loaded onto embedded devices to be used for inference.

Inference. The disclosed approach works very similarly to the baseline HD computing, except now there are two stages. First, we check the similarity of a query hypervector in the category stage. A category hypervector with the highest cosine similarity is selected to continue the search in the main stage. Here, we check the similarity of the query hypervector against the classes within the selected category. For example, in FIG. 39c, if group 2 had the highest cosine similarity with the query hypervector, then only the green class hypervectors are selected for search in the main stage. Finally, a class with the highest cosine similarity in the main stage is selected as the output class. This approach reduces the number of required operations. For an application with k classes, our approach reduces the number of required similarity checks from k to k/m+m hypervectors. For example, for an application with k=16 and m=4, the number of required operations is reduced by a factor of 2.

### 5-IV. Evaluation

### 5-IV.1. Experimental Setup

We performed HD training and retraining using C++ implementation on Intel Core i7 processor with 16 GB memory (4-core, 2.8 GHz). We describe the inference functionality using RTL System-Verilog and use standard digital ASIC flow to design dedicated hardware. For the synthesis, we use Synopsys Design Compiler with the FreePDK 45 nm technology library. We extract the design switching activity using ModelSim and measured the power consumption of HD designs using Synopsys Prime-Time.

We tested the efficiency of the disclosed approach on three practical applications:

Speech Recognition (ISOLET): Recognize voice audio of the 26 letters of the English alphabet. The training and testing datasets are taken from the Isolet dataset. This dataset consists of 150 subjects speaking each letter of the alphabet twice. The speakers are grouped into sets of 30 speakers. The training of hypervectors is performed on Isolet 1, 2, 3, 4, and tested on Isolet 5.

Activity Recognition (UCIHAR): Detect human activity based on 3-axial linear acceleration and 3-axial angular velocity that has been captured at a constant rate of 50 Hz. The training and testing datasets are taken from the Human Activity Recognition dataset. This dataset contains 10,299 samples each with 561 attributes.

Image Recognition (IMAGE): Recognize hand-written digits 0 through 9. The training and testing datasets are taken from the Pen-Based Recognition of Handwritten Digits dataset. This dataset consists of 44 subjects writing each numerical digit 250 times. The samples from 30 subjects are used for training and the other 14 are used for testing.

TABLE 5-I
Classification Accuracy Of HD With Integer (Baseline) And Quantized Model

| # of Classes | Integer Model | | | | Quantized (2ⁱ) | | | | Quantized (2ⁱ + 2^{j}) | | | |
|---|---|---|---|---|---|---|---|---|---|---|---|---|
| in a Group | 1 | 2 | 3 | 4 | 1 | 2 | 3 | 4 | 1 | 2 | 3 | 4 |
| Speech Recognition | 91.72% | 88.39% | 88.0 [symbol] % | 87.04% | 91.73% | 83.0 [symbol] % | 85.70% | 83.39% | 90.64% | 88.45% | 88.26% | 88.39% |
| Activity Recognition | 95.80% | 95.49% | 95.37% | 94.98% | 93.50% | 92.73% | 94.92% | 94.72% | 94.27% | 94.34% | 93.62% | 94.72% |
| Image Recognition | 92.97% | 9 [symbol] .25% | 91.02% | 89.11% | 89.99% | 92.54% | 91.05% | 80.62% | 91.51% | 93.00% | 92.28% | 89.31% |

[symbol]

indicates data missing or illegible when filed

### 5-IV.2. Accuracy

Table 5-I shows the HD classification accuracy for four different configurations when we categorize the class hypervectors into groups of m=1 to 4. The configuration m=1 is the baseline HD, where we do not have any grouping. HD in m=2 configuration is where each group consists of two class hypervectors. This generates k/m hypervectors in category stage. Our evaluation shows that grouping has a minor impact on the classification accuracy (0.6% on average). HD classification accuracy is also a weak function of grouping configurations. However, the number of hypervectors in the category stage affects the number of computations needed for inference. Therefore, we choose the grouping approach that minimizes the number of required operations for a given application. For example, for activity recognition with k=12 classes, the grouping with n=4 results in maximum efficiency, since it reduces the number of effective hypervectors from k=12 to k/m+n=7.

Table 5-I also shows the HD classification accuracy for two types of quantization. Our results show that HD on average loses 3.7% in accuracy when quantizing the trained model values to power of two values (2ⁱ). However, quantizing the values to 2ⁱ+2^{j} values enables HD to provide similar accuracy to HD with integers with less than 0.5% error. This quantization results in 2.2× energy efficiency improvement and 1.6× speedup by modeling the multiplication with two shifts and a single add operation.

### 5-IV.3. Efficiency

The goal is to have HD be small and scalable so that it can be stored and processed on embedded devices with limited resources. In the conventional HD, each class is represented using a single hypervector. In some embodiments, this issue is addressed by grouping classes together, which significantly lowers the number of computations, and with quantization, which removes costly multiplications from the similarity check.

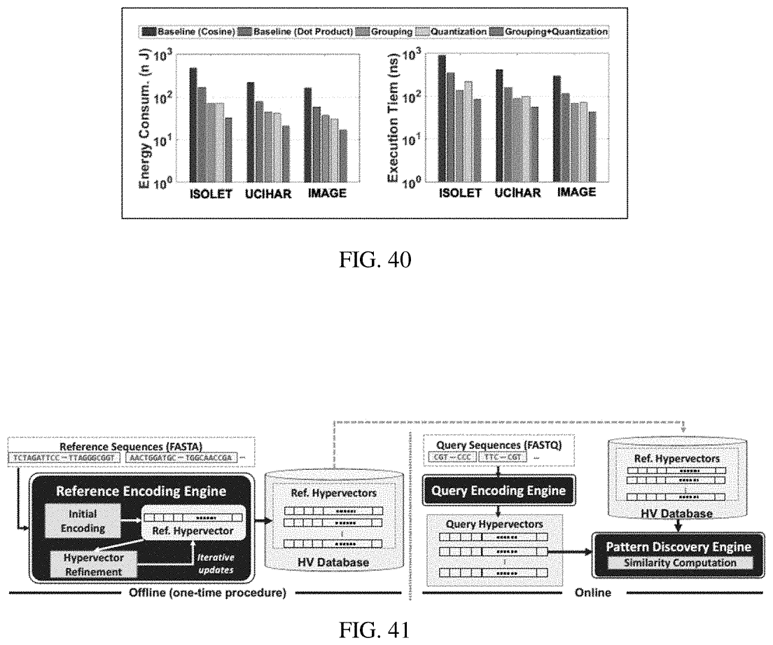

FIG. 40 compares the energy consumption and execution time of the disclosed approach with the baseline HD computing during inference. We reported results such that reader can see the impact of different optimizations. To have fair comparison, the baseline HD uses the same encoding and number of retraining iterations as the disclosed design. Our evaluation shows that grouping of class hypervectors can achieve on average 5.3× energy efficiency improvement and 4.9× faster as compared to the baseline HD using cosine similarity. In addition, quantization (2ⁱ+2^{j}) of class elements can further improve the HD efficiency by removing costly multiplications. Our evaluations show that HD enhancing with both grouping and quantization achieves 11.6× energy efficiency and 8.3× speedup as compared to baseline HD using cosine while providing similar classification accuracy.

### Part 6: GenieHD: DNA Pattern Matching Using Hyperdimensional Computing

As appreciated by the present inventors, DNA pattern matching is widely applied in many bioinformatics applications. The increasing volume of the DNA data exacerbates the runtime and power consumption to discover DNA patterns. A hardware-software co-design, called GenieHD, is disclosed herein which efficiently parallelizes the DNA pattern matching task, exploits brain-inspired hyperdimensional (HD) computing which mimics pattern-based computations in human memory. We transform inherent sequential processes of the DNA pattern matching to highly parallelizable computation tasks using HD computing. The disclosed technique first encodes the whole genome sequence and target DNA pattern to high-dimensional vectors. Once encoded, a light-weight operation on the high-dimensional vectors can identify if the target pattern exists in the whole sequence. Also disclosed is an accelerator architecture which effectively parallelizes the HD-based DNA pattern matching while significantly reducing the number of memory accesses. The architecture can be implemented on various parallel computing platforms to meet target system requirements, e.g., FPGA for low-power devices and ASIC for high-performance systems. We evaluate GenieHD on practical large-size DNA datasets such as human and Escherichia Coli genomes. Our evaluation shows that GenieHD significantly accelerates the DNA matching procedure, e.g., 44.4× speedup and 54.1× higher energy efficiency as compared to a state-of-the-art FPGA-based design.

### 6-I. Introduction

DNA pattern matching is an essential technique in many applications of bioinformatics. In general, a DNA sequence is represented by a string consisting of four nucleotide characters, A, C, G, and T. The pattern matching problem is to examine the occurrence of a given query string in a reference string. For example, the technique can discover possible diseases by identifying which reads (short strings) match a reference human genome consisting of 100 millions of DNA bases. The pattern matching is also an important ingredient of many DNA alignment techniques. BLAST, one of the best DNA local alignment search tools, uses the pattern matching as a key step of their processing pipeline to find representative k-mers before running subsequent alignment steps.

Despite of the importance, the efficient acceleration of the DNA pattern matching is still an open question. Although prior researchers have developed acceleration systems on parallel computing platforms, e.g., GPU and FPGA, they offer only limited improvements. The primary reason is that existing pattern matching algorithms they relied on, e.g., Boyer-Moore (BM) and Knuth-Morris-Pratt (KMP) algorithms, are at heart sequential processes, resulting in high memory requirements and runtime.

Accordingly, in some embodiments, a novel hardware-software codesign of GenieHD (Genome identity extractor using hyperdimensional computing) is disclosed, which includes a new pattern matching method and the accelerator design. The disclosed design is based on brain-inspired hyperdimensional (HD) computing. HD computing is a computing method which mimics the human memory efficient in pattern-oriented computations. In HD computing, we first encode raw data to patterns in a high-dimensional space, i.e., high-dimensional vectors, also called hypervectors. HD computing can then imitate essential functionalities of the human memory with hypervector operations. For example, with the hypervector addition, a single hypervector can effectively combine multiple patterns. We can also check the similarity of different patterns efficiently by computing the vector distances. Since the HD operations are expressed with simple arithmetic computations which are often dimension-independent, parallel computing platforms can significantly accelerate HD-based algorithms in a scalable way.

Based on HD computing, GenieHD transforms the inherent sequential processes of the pattern matching task to highly-parallelizable computations. For example:

1) GenieHD has a novel hardware-friendly pattern matching technique based on HD computing. GenieHD encodes DNA sequences to hypervectors and discover multiple patterns with a light-weight HD operation. The encoded hypervectors can be reused to query many DNA sequences newly sampled which are common in practice.

2) Genie can include an acceleration architecture to execute the disclosed technique efficiently on general parallel computing platforms. The design significantly reduces the number of memory accesses to process the HD operations, while fully utilizing the available parallel computing resources. We also present how to implement the disclosed acceleration architecture on the three parallel computing platforms, GPGPU, FPGA, and ASIC.

3) We evaluated GenieHD with practical datasets, human and Escherichia Coli (E. coli) genome sequences. The experimental results show that GenieHD significantly accelerates the DNA matching technique, e.g., 44.4× speedup and 54.1× higher energy efficiency when comparing our FPGA-based design to a state-of-the-art FPGA-based design. As compared to an existing GPU-based implementation, our ASIC design which has the similar die size outperforms the performance and energy efficiency by 122× and 707×. We also show that the power consumption can be further saved by 50% by allowing minimal accuracy loss of 1%.

### 6-II. Landscape of GenieHD

Hyperdimensional Computing: HD computing is originated from a human memory model, called sparse distributed memory developed in neuroscience. Recently, computer scientists recapped the memory model as a cognitive, pattern-oriented computing method. For example, prior researchers showed that the HD computing-based classifier is effective for diverse applications, e.g., text classification, multimodal sensor fusion, speech recognition, and human activity classification. Prior work shows application-specific accelerators on different platforms, e.g., FPGA and ASIC. Processing in-memory chips were also fabricated based on 3D VRRAM technology. The previous works mostly utilize HD computing as a solution for classification problems. In this paper, we show that HD computing is an effective method for other pattern-centric problems and disclose a novel DNA pattern matching technique.

DNA Pattern Matching Acceleration: The efficient pattern matching is an important task in many bioinformatics applications, e.g., single nucleotide polymorphism (SNP) identification, onsite disease detection and precision medicine development. Many acceleration systems have been proposed on diverse platforms, e.g., multiprocessor and FPGA. For example, some work proposes an FPGA accelerator that parallelizes partial matches for a long DNA sequence based on KMP algorithm. In contrast, GenieHD provides an accelerator using a new HD computing-based technique which is specialized for parallel systems and also effectively scales for the number of queries to process.

### 6-III. GenieHD Overview

FIG. 41 illustrates the overview of the disclosed GenieHD design. GenieHD exploits HD computing to design an efficient DNA pattern matching solution (Section 6-IV.) During the offline stage, we convert the reference genome sequence into hypervectors and store into the HV database. In the online stage, we also encode the query sequence given as an input. GenieHD in turn identifies if the query exists in the reference or not, using a light-weight HD operation that computes hypervector similarities between the query and reference hypervectors. All the three processing engines perform the computations with highly parallelizable HD operations. Thus, many parallel computing platforms can accelerate the disclosed technique. We present the implementation on GPGPU, FPGA, and ASIC based on a general acceleration architecture (Section 6-V.)

Raw DNA sequences are publicly downloadable in standard formats, e.g., FASTA for references. Likewise, the HV databases can provide the reference hypervectors encoded in advance, so that users can efficiently examine different queries without performing the offline encoding procedure repeatedly. For example, it is typical to perform the pattern matching for billions of queries streamed by a DNA sequencing machine. In this context, we also evaluate how GenieHD scales better than state-of-the-art methods when handling multiple queries (Section 6-VI.)

### 6-IV. DNA Pattern Matching Using HD Computing

The major difference between HD and conventional computing is the computed data elements. Instead of Booleans and numbers, HD computing performs the computations on ultra-wide words, i.e., hypervectors, where all words are responsible to represent a datum in a distributed manner. HD computing mimics important functionalities of the human memory. For example, the brain efficiently aggregates/associates different data and understands similarity between data. The HD computing implements the aggregation and association using the hypervector addition and multiplication, while measuring the similarity based on a distance metric between hypervectors. The HD operations can be effectively parallelized in the granularity of the dimension level.

In some embodiments, DNA sequences are represented with hypervectors, and the pattern matching procedure is performed using the similarity computation. To encode a DNA sequence to hypervectors, GenieHD uses four hypervectors corresponding to each base alphabet in Σ={A, C, G, T}. We call the four hypervectors as base hypervectors, and denote with Σ_{HV}={A, C, G, T}. Each of the hypervectors has D dimensions where a component is either −1 or +1 (bipolar), i.e., {−1, +1}^{D}. The four hypervectors should be uncorrelated to represent their differences in sequences. For example, δ(A, C) should be nearly zero, where δ is the dot-product similarity. The base hypervectors can be easily created, since any two hypervectors whose components are randomly selected in {−1, 1} have almost zero similarity, i.e., nearly orthogonal.

### 6-IV.1. DNA Sequence Encoding

DNA pattern encoding: GenieHD maps a DNA pattern by combining the base hypervectors. Let us consider a short query string, ‘GTACG’. We represent the string with G×ρ¹ (T)×ρ² (A)×ρ³ (C)×ρ⁴ (G), where ρⁿ(H) is a permutation function that shuffles components of H (∈ΣHV) with n-bit(s) rotation. For the sake of simplicity, we denote ρⁿ(H) as Hⁿ. Hⁿ is nearly orthogonal to H=H⁰ if n≠0, since the components of a base hypervector are randomly selected and independent of each other. Hence, the hypervector representations for any two different strings, H_{α} and H_{β}, are also nearly orthogonal, i.e., δ(H_{α}, H_{β})≃0. The hyperspace of D dimensions can represent 2^{D} possibilities. The enormous representations are sufficient to map different DNA patterns to near orthogonal hypervectors.

Since the query sequence is typically short, e.g., 100 to 200 characters, the cost for the online query encoding step is negligible. In the followings, we discuss how GenieHD can efficiently encode the long-length reference sequence.

Reference encoding: The goal of the reference encoding is to create hypervectors that include all combinations of patterns. In practice, the approximate lengths of the query sequences are known, e.g., the DNA read length of the sequencing technology. Let us define that the lengths of the queries are in a range of [⊥, [symbol] ]. The length of the reference sequence, [symbol] , is denoted by N. We also use following notations: (i) Bₜ denotes the base hypervector for the t-th character in [symbol] (0-base indexing), and (ii) H_{(a,b)} denotes the hypervector for a subsequence, Bₐ⁰×Bₐ₊₁¹× . . . ×B_{a+b-1}^{b-1}.

Method 1 Reference Encoding

1 S ← H_{(0, ⊥)} + H_{(0, ⊥} _{+ 1)} + ··· + H_{(0, T)}
2 F ← H_{(0, ⊥)}; L ← H_{(0, T)}
3 R ← S
4 for t ← 0 to N − T do
5 | L ← Bₜ⁻¹ × L⁻¹ × B_{t+T}^{T}
6 | S ← Bₜ⁻¹ × (S − F)⁻¹ + L; R ← R + S
7 | F ← Bₜ⁻¹ × F⁻¹ × B_{t+⊥}^{⊥}
8 end

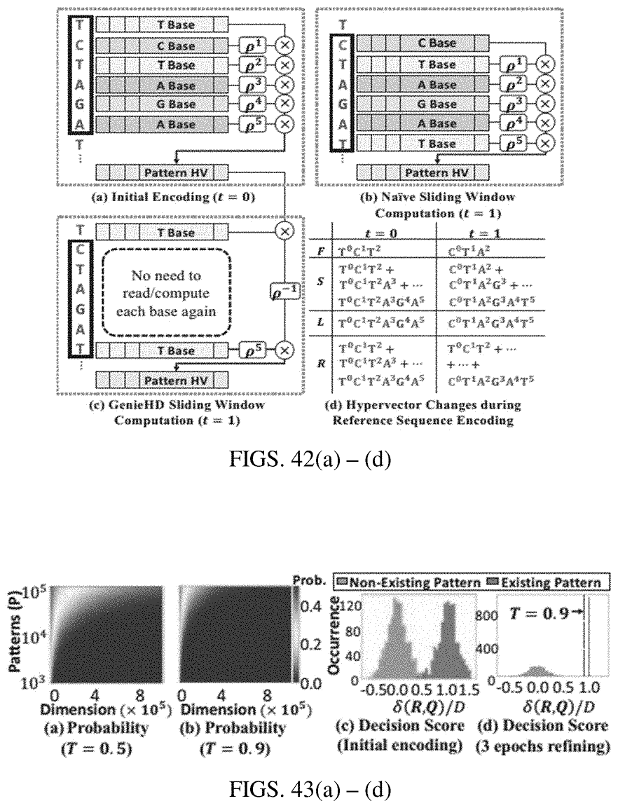

Let us first consider a special case that encodes every substring of the size n from the reference sequence, i.e., n=⊥= [symbol] . The substring can be extracted using a sliding window of the size n to encode H_{(t,n)}. FIG. 42a illustrates the encoding method for the first substring, i.e., t=0, when n=6. A naive way to encode the next substring, H_{(l,n)}, is to run the permutations and multiplications again for each base, as shown in FIG. 42b. FIG. 42c shows how GenieHD optimizes it based on HD computing specialized to remove and insert new information. We first multiply T⁰ with the previously encoded hypervector, T⁰C¹T²A³G⁴A⁵. The multiplication of two identical base hypervectors yields the hypervector whose elements are all is. Thus, it removes the first base from H_{0,n}, producing C¹T²A³G⁴A⁵. After performing the rotational shift (ρ⁻¹) and element-wise multiplication for the new base of the sliding window (T⁵), we obtain the desired hypervector, C⁰T¹A²G³A⁴T⁵. This scheme only needs two permutations and multiplications regardless of the substring size n.

Method 1 describes how GenieHD encode the reference sequence in the optimized fashion; FIG. 42d shows how Method 1 runs for the first two iterations when ⊥=3 and [symbol] =6. The outcome is R, i.e., the reference hypervector, which combines all substrings whose sizes are in [⊥, [symbol] ]. The method starts with creating three hypervectors, S, F, and L, (Line 1˜3). S includes all patterns of [⊥, [symbol] ] in each sliding window; F and L keep tracks of the first and last hypervectors for the ⊥-length and [symbol] -length patterns, respectively. Intuitively, this initialization needs O( [symbol] ) hypervector operations. The main loop implements the sliding window scheme for multiple lengths in [⊥, [symbol] ]. It computes the next L using the optimized scheme (Line 5). In Line 6, it subtracts F, i.e., the shortest pattern in the previous iteration, and multiply Bₜ⁻¹ to remove the first base from all patterns combined in S. Then, S includes the patterns in the range of [⊥, [symbol] −1] for the current window. After adding L whose length is [symbol] , we accumulate S to R. Lastly, we update the first pattern F in the same way to L (Line 7). The entire iterations need O(N) operations regardless of the pattern length range, thus the total complexity of this technique2 is O(N+ [symbol] ). Finally, R includes all the hypervector representations of the desired lengths existing in the reference.

### 6-IV.2. Pattern Matching

GenieHD performs the pattern matching by computing the similarity between R and Q. Let us assume that R is the addition of P hypervectors (i.e., P distinct patterns), H₁+ . . . +H_{P}. The dot product similarity is computed as follows:

$$δ ( R , Q ) = δ ( {H}_{λ} , Q ) + \underbrace{{\sum }_{i = 1 , i \neq λ}^{P} δ ( {H}_{i} , Q )}_{Noise} .$$

If H_{λ} is equal to Q, since the similarity for the two identical bipolar hypervectors are D, i.e., δ(H_{λ}, Q)=D. The similarity between any two different patterns is nearly zero, i.e., δ(Hᵢ, Q)≃0 of the noise term. Thus, the following criteria checks if Q exists in R:

$$\frac{δ ( R , Q )}{𝒟} > T \qquad ( 6 \text{-} 1 )$$

where T is a threshold. We call

$$\frac{δ ( R , Q )}{D}$$

as the decision score.

The accuracy of this decision process depends on (i) the amount of the noise and (ii) threshold value, T. To precisely identify patterns in GenieHD, we develop a concrete statistical method that estimates the worst-case accuracy. The similarity metric computes how many components of Q are the same to the corresponding components for each Hᵢ in R. There are P·D component pairs for Q and Hᵢ (0≤i<P). The probability that each pair is ½ the same is for all components if Q is a random hypervector. The similarity, δ(R, Q), can be then viewed as a random variable, X, which follows a binomial distribution, X˜B(P·D). Since D is large enough, X can be approximated with the normal distribution:

$$x \text{∼} N ( \frac{P \cdot D}{2} , \frac{P \cdot D}{4} )$$

When x component pairs of [symbol] and Q have the same value, (P·D−x) pairs have different values, thus δ( [symbol] , Q)=2x−P·D. Hence, the probability that satisfies Equation 6-1 is

$$P r ( X > \frac{( T + P ) \cdot D}{2} ) .$$

We can convert X to the standard normal distribution, Z:

$$Pr ( Z > T \cdot \sqrt{\frac{D}{P}} ) = \frac{1}{\sqrt{2 π}} {\int }_{T \cdot \sqrt{\frac{D}{P}}}^{∞} {e}^{- {t}^{2} / 2} dt \qquad ( 6 \text{-} 2 )$$

In other words, Equation 6-2 represents the probability that mistakenly determines that Q exists in [symbol] , i.e., false positive.

FIGS. 43a and 43b visualizes the probability of the error for different D and P combinations. For example, when D=100,000 and T=0.5, we can identify P=10,000 with 5.7% error using a single similarity computation operation. The results also show that using larger D values can improve the accuracy. However, the larger dimensionality requires more hardware resources. Another option to improve the accuracy is using a larger similarity threshold, T, however it may increase true negatives. GenieHD uses the following two techniques to address this issue.

Hypervector refinement: The first technique is to refine the reference hypervector. Let us recall Method 1. In the refining step, GenieHD reruns the technique to update [symbol] . Instead of accumulating S to [symbol] (Line 6), we add S×(1−δ(S, [symbol] )/D). The refinement is performed for multiple epochs. FIGS. 43c and 43d show how the distribution of the decision scores changes for the existing and non-existing cases by the refinement. The results show that the refinement makes the decision scores of the existing cases close to 1. Thus, we can use a larger T for higher accuracy. The successful convergence depends on i) the number of patterns included in [symbol] with D dimensions, i.e., D/P, and ii) the training epochs. In our evaluation, we observe that, when [symbol] includes P=D1 patterns and use T=0.9, we only need five epochs, and GenieHD can find all patterns with the error of less than 0.003%.

Multivector generation: To precisely discover patterns of the reference sequence, we also use multiple hypervectors so that they cover every pattern existing in the reference without loss. During the initial encoding, whenever [symbol] reaches the maximum capacity, i.e., accumulating P distinct patterns, we store the current [symbol] and reset its components to 0s to start computing a new [symbol] . GenieHD accordingly fetches the stored [symbol] during the refinement. Even though it needs to compute the similarity values for the multiple [symbol] hypervectors, GenieHD can still fully utilize the parallel computing units by setting D to a sufficiently large number.

### 6-V. Hardware Acceleration Design

### 6-V.1. Acceleration Architecture

Encoding Engine: The encoding procedure runs i) the element-wise addition/multiplication and ii) permutation. The parallelized implementation of the element-wise operations is straight-forward, i.e., computing each dimension on different computing units. For example, if a computing platform can compute d dimensions (out of D) independently in parallel, the single operation can be calculated with [D/d] stages. In contrast, the permutation is more challenging due to memory accesses. For example, a naive implementation may access all hypervector components from memory, but on-chip caches usually have no such capacity.

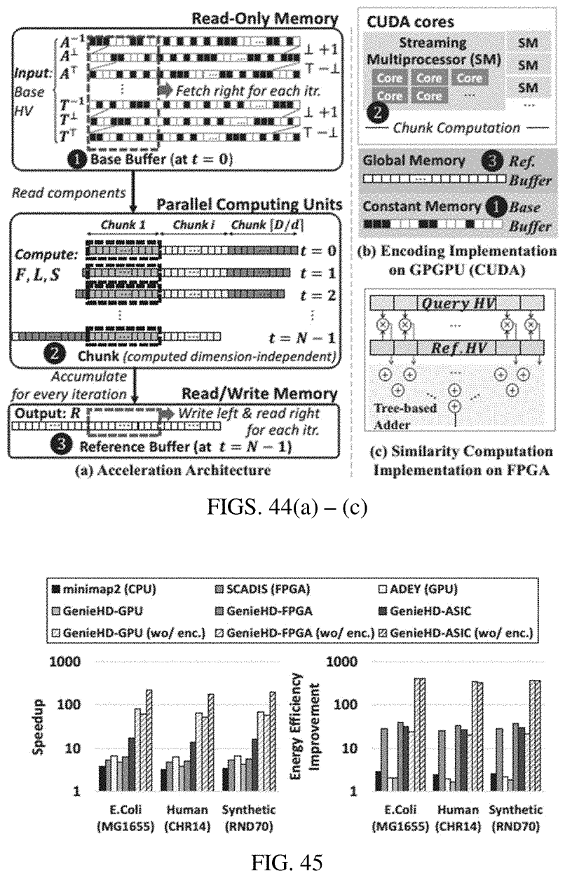

The disclosed method significantly reduces the amount of memory accesses. FIG. 44a illustrates our acceleration architecture for the initial reference encoding procedure as an example. The acceleration architecture represents typical parallel computing platforms which have many computing units and memory. As discussed in Section 6-IV-A, the encoding procedures uses the permuted bipolar base hypervectors, B⁻¹, B^{⊥} and B [symbol] , as the inputs. Since there are four DNA alphabets, the inputs are 12 near-orthogonal hypervectors. It calculates the three intermediate hypervectors, F, L and S while accumulating S into the output reference hypervector, [symbol] .

Consider that the permuted base hypervectors and initial reference hypervector are pre-stored in the off-chip memory. To compute all components of [symbol] , we run the main loop of the reference encoding [D/d] times by dividing the dimensions into multiple groups, called chunks. In the first iteration, the base buffer stores the first d components of the 12 input hypervectors \textcircled{1}. The same d dimensions of F, L and S for the first chunk are stored in the local memory of each processing unit, e.g., registers of each GPU core \textcircled{2}. For each iteration, the processing units compute the dimensions of the chunk in parallel, and accumulate to the reference buffer that stores the d components of [symbol] \textcircled{3}. Then, the base buffer fetches the next elements for the 12 input hypervectors from the off-chip memory. Similarly, the reference buffer flushes its first element to the off-chip memory and reads the next element. When it needs to reset R for the multivector generation, the reference buffer is stored to the off-chip memory and filled with zeros. The key advantage of this method is that we do not need to know entire D components of F, L and S for the permutation. Instead, we can regard that they are the d components starting from the r-th dimension where τ=t mod D, and accumulate them in the reference buffer which already has the corresponding dimensions. Every iteration only needs to read a single element for each base and a single read/write for the reference, while fully utilizing the computing units for the HD operations. Once completing N iterations, we repeat the same procedure for the next chunk until covering all dimensions.

The similar method is generally applicable for the other procedures, the query encoding and refinement. For example, for the query encoding, we compute each chunk of Q by reading an element for each base hypervector and multiplying d components.

Similarity Computation: The pattern discovery engine and refinement procedures use the similarity computation. The dot product is decomposed with the element-wise multiplication and the grand sum of the multiplied components. The element-wise multiplication can be parallelized on the different computing units, and then we can compute the grand sum by adding multiple pairs in parallel with O(log D) steps. The implementation depends on the parallel platforms. We explain the details in the following section.

### 6-V.2. Implementation on Parallel Computing Platforms

GenieHD-GPU: We implement the encoding engine by utilizing the parallel cores and different memory resources in CUDA systems (refer to FIG. 44b.) The base buffer is stored in the constant memory, which offers high bandwidth for read-only data. Each streaming core stores the intermediate hypervector components of the chunk in their registers; the reference buffer is located in the global memory (DRAM on GPU card). The data reading and writing to the constant and global memory are implemented with CUDA streams which concurrently copy data during computations. We implement the similarity computation using the parallel reduction technique. Each stream core fetches and adds multiple components into the shared memory which provide high performance for inter-thread memory accesses. We then perform the tree-based reduction in the shared memory.

GenieHD-FPGA: We implement the FPGA encoding engine by using Lookup Table (LUT) resources. We store the base hypervectors into block RAMs (BRAM), the on-chip FPGA memory. The base hypervectors are loaded to a distributed memory designed by the LUT resources. Depending on the reading sequence, GenieHD loads the corresponding base hypervector and combines them using LUT resources. In the pattern discovery, we use the DSP blocks of FPGA to perform the multiplications of the dot product and a tree-based adder to accumulate the multiplication results (refer to FIG. 44c.) Since the query encoding and discovery use different FPGA resources, we implement the whole procedure in a pipeline structure to handle multiple queries. Depending on the FPGA available resources, it can process a different number of dimensions in parallel. For example, for Kintex-7 FPGA with 800 DSPs, we can parallelize the computation of 320 dimensions.

GenieHD-ASIC: The ASIC design has three major subcomponents: SRAM, interconnect, and computing block. We used the SRAM-based memory to keep all base hypervectors. The memory is connected to the computing block with the interconnect. To reduce the memory writes to SRAM, the interconnect implements n-bit shifts to fetch the hypervector components to the computing block with a single cycle. The computing units parallelize the element-wise operations. For the query discovery, it forwards the execution results to the tree-based adder structure located in the computing block in a similar way to the FPGA design. The efficiency depends on the number of parallel computing units. We design GenieHD-ASIC with the same size of the experimented GPU core, 471 mm2. In this setting, our implementation parallelizes the computations for 8000 components.

### 6-VI. Evaluation

### 6-VI.1. Experimental Setup

We evaluate GenieHD on parallel various computing platforms. We implement GenieHD-GPU on NVIDIA GTX 1080 Ti (3584 CUDA cores) and Intel i7-8700K CPU (12 multithreads) and measure power consumption using Hioki 3334 power meter. GenieHD-FPGA is synthesized on Kintex-7 FPGA KC705 using Xilinx Vivado Design Suite. We used Vivado XPower tool to estimate the device power. We design and simulate GenieHD-ASIC using RTL System-Verilog. For the synthesis, we use Synopsys Design Compiler with the FreePDK 45 nm technology library. We estimate the power consumption using Synopsys PrimeTime. The GenieHD family is evaluated using D=100,000 and P=10,000 with five refinement epochs.

Table 6-I summarizes the evaluated DNA sequence datasets. We use E. coli DNA data (MG1655) and the human reference genome, chromosome 14 (CHR14). We also create a random synthetic DNA sequence (RND70) having a length of 70 million characters. The query sequence reads with the length in [⊥, [symbol] ] are extracted using SRA toolkit from the FASTQ format. The total size of the generated hypervectors for each sequence (HV size) is linearly proportional to the length of the reference sequence. Note that state-of-the-art bioinformatics tools also have the peak memory footprint in up to two orders of gigabytes for the human genome.

TABLE 6-I
EVALUATED DNA SEQUENCE DATASETS

| | Description | Length | ⊥, T | HV size |
|---|---|---|---|---|
| E. Coli | Escherichia coli | 4.6M | 199, 201 | 53 MB |
| Human (CHR14) | Human chromosome 14 | 107M | 99, 101 | 1.2 GB |
| Synthetic (RND70) | Random sequence | 70M | 99, 101 | 0.8 GB |

### 6-VI.2. Efficiency Comparison

We compare the efficiency of GenieHD with state-of-the-art programs and accelerators, i) Bowtie2 running on Intel i7-8700K CPU and ii) minimap2, which runs on the same CPU, but tens of times faster than the previous mainstream such as BLASR and GMAP, iii) GPU-based design (ADEY), and iv) FPGA-based design (SCADIS) evaluated on the same chip to GenieHD-FPGA. FIG. 45 presents that GenieHD outperforms the state-of-the-art methods. For example, even though including the overhead of the offline reference encoding, GenieHD-ASIC achieves up to 16× speedup and 40× higher energy efficiency as compared to Bowtie2. GenieHD can offer higher improvements if the references are encoded in advance. For example, when the encoded hypervectors are available, by eliminating the offline encoding costs, GenieHD-ASIC is 199.7× faster and 369.9× more energy efficient than Bowtie2. When comparing the same platforms, GenieHD-FPGA (GenieHD-GPU) achieves 11.1× (10.9×) speedup and 13.5× (10.6×) higher energy efficiency as compared to SCADIS running on FPGA (ADEY on the GPGPU).

### 6-VI.3. Pattern Matching for Multiple Queries

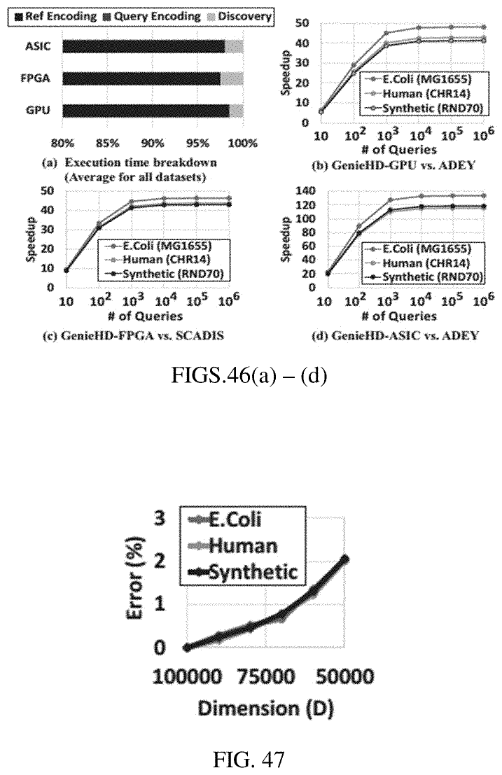

FIG. 46a shows the breakdown of the GenieHD procedures. The results show that most execution costs come from the reference encoding procedure, e.g., more than 97.6% on average. It is because i) the query sequence is relatively very short and ii) the discovery procedure examines multiple patterns using a single similarity computation in a highly parallel manner. As discussed in Section 6-III, GenieHD can reuse the same reference hypervectors for different queries newly sampled. FIGS. 46b-d shows the speedup of the accumulated execution time for multiple queries over the state-of-the-art counterparts. For fair comparison, we evaluate the performance of GenieHD based on the total execution costs including the reference/query encoding and query discovery engines. The results show that, by reusing the encoded reference hypervector, GenieHD achieves higher speedup as the number of queries increases. For example, when comparing the designs running on the same platform, we observe 43.9× and 44.4× speedup on average for 10E6 queries on (b) GPU and (c) FPGA, respectively. The energy-efficiency improvement for each case is 42.5× and 54.1×. As compared to ADEY, GenieHD-ASIC offers 122× speedup and 707× energy-efficiency improvements with the same area (d). It is because GenieHD consumes much less cost from the second run. The speedup converges at around 10E3 queries as the query discovery takes a more portion of the execution time for a larger number of queries.

### 6-VI.4. Dimensionality Exploitation

In practice, the higher efficiency would be more desired than the perfect discovery, since DNA sequences are often error-prone. The statistical nature of GenieHD facilitates such optimization. FIG. 47 shows how much the additional error occurs from the baseline accuracy of 0.003% as decreasing the dimensionality. As anticipated with the estimation model shown in Section 6-IV-B, the error increases with a less dimensionality. Note that it does not need to encode the hypervectors again; instead, we can use only a part of components in the similarity computation. The results suggest that we can significantly improve the efficiency with minimal accuracy loss. For example, we can achieve 2× speedup for all the GenieHD family with 2% loss as it only needs the computation for half dimensions. We can also exploit this characteristic for power optimization. Table 6-II shows the power consumption for the hardware components of GenieHD-ASIC, SRAM, interconnect (ITC), and computing block (CB) along with the throughput. We evaluated two power optimization schemes, i) Gating which does not use half of the resources, and ii) voltage over scaling (VoS) which uses all resources at a lower frequency. The frequency is set to obtain the same throughput of 640K/sec (the number of similarity computations per second.) The results show that VoS is the more effective method since the frequency non-linearly influences the speed. GenieHD-ASIC with VoS saves 50% and 61% power with accuracy loss of 1% and 2%, respectively.

TABLE 6-II
GENIEHD-ASIC DESIGNS UNDER LOSS

| | 0% | 1% | | 2% | |
|---|---|---|---|---|---|
| | Base | Gating | VoS | Gating | VoS |
| Power(W) | | | | | |
| SRAM | 3.4 | 2.5 | 3.4 | 1.8 | 3.4 |
| ITC | 0.6 | 0.4 | 0.6 | 0.3 | 0.6 |
| CB | 21.5 | 13.7 | 8.8 | 10.9 | 6.0 |
| Total | 25.4 | 16.6 | 12.8 | 13.1 | 10.0 |

| | |
|---|---|
| Throughput | 640 K/sec |

As described herein, GenieHD can perform the DNA pattern matching technique using HD computing. The disclosed technique maps DNA sequences to hypervectors, and accelerates the pattern matching procedure in a highly parallelized way. We show an acceleration architecture to optimize the memory access patterns and perform pattern matching tasks with dimension-independent operations in parallel. The results show that GenieHD significantly accelerates the pattern matching procedure, e.g., 44.4× speedup with 54.1× energy-efficiency improvements when comparing to the existing design on the same FPGA.

### Part 7: RAPID: DNA Sequence Alignment Using ReRAM Based In-Memory Processing

As appreciated by the present inventors, sequence alignment is a core component of many biological application. As the advancement in sequencing technologies produces a tremendous amount of data on an hourly basis, this alignment is becoming the critical bottleneck in bioinformatics analysis. Even though large clusters and highly parallel processing nodes can carry out sequence alignment, in addition to the exacerbated power consumption, they cannot afford to concurrently process the massive amount of data generated by sequencing machines. We disclose a processing in-memory (PIM) architecture suited for DNA sequence alignment, referred herein as RAPID, which is compatible with in-memory parallel computations, and can provide process DNA data completely inside memory without requiring additional processing units. In some embodiments, the main advantage of RAPID is a dramatic reduction in internal data movement while maintaining a remarkable degree of parallelism provided by PIM. The disclosed architecture is also highly scalable, facilitating precise alignment chromosome sequences from human and chimpanzee genomes. The results show that RAPID is at least 2× faster and 7× more power efficient than BioSEAL.

### 7-I. Introduction

DNA comprises long paired-to strands of nucleotide bases, and DNA sequencing is the process of identifying the order of these bases in the given molecule. Demonstration of nucleotide bases is abstracted away by four representative letters, A, C, G, and T, respectively standing for adenine, cytosine, guanine, and thymine nucleobases. Modern techniques can be applied to human DNA to diagnose genetic diseases by identifying disease-associated structural variants. DNA sequencing also plays a crucial role in phylogenetics, where sequencing information can be used to infer the evolutionary history of an organism over time. These sequences can also be analyzed to provide information on populations of viruses within individuals, allowing for a profound understanding of underlying viral selection pressures.

Sequence alignment is central to a multitude of these biological applications and is gaining increasing significance with the advent of nowadays high-throughput sequencing techniques which can produce billions of base pairs in hours, and output hundreds of gigabytes of data, requiring enormous computing effort. Different variants of alignment problems have been introduced. However, they eventually decompose the problem to pairwise (i.e., between two sequences) alignment. The global sequence alignment can be formulated as finding the optimal edit operations, including deletion, insertion, substituting of the character, required to transform sequence x to sequence y (and vice versa). The cost of insertion (deletion), however, may depend on the length of the consecutive insertions (deletions).

The search space of evaluating all possible alignments is exponentially proportional to the length of the sequences and becomes computationally intractable even for sequences as small as having just 20 bases. To resolve this, the Needleman-Wunsch algorithm employs dynamic-programming (DP) to divide the problem into smaller ones and construct the solution by using the results obtained from solving the sub-problems, reducing the worst-case performance and space down to O(mn) while delivering higher accuracy compared to the heuristic counterparts such as BLAST. The Needleman-Wunsch, however, needs to create a scoring matrix M_{m×n} that has a quadratic time and space complexity dependent on the lengths of input sequences and is still compute intensive. For instance, aligning the human's largest chromosome (among 23 pairs) with the corresponding chromosome in chimpanzee (to get evolutionary insights) results in a score matrix with ˜56.9 peta-elements. Parallelized versions of Needleman-Wunsch rely on the fact that computing the elements on the same diagonal of the scoring matrix need only the elements of the previous two diagonals. The level of parallelism offered by large sequence lengths often cannot be effectively exploited by conventional processor architecture. Some effort has been made to accelerate DNA alignment using different hardware techniques to exploit the parallelism in the application.

Processing in-memory (PIM) architectures are promising solutions to mitigate the data movement issue and provide a large amount of parallelism. PIM enables in-situ computation on the data stored in the memory, hence, throttling the latency of data movement. Nevertheless, PIM-based acceleration demands a cautious understanding of the target application and the underlying architecture. PIM operations, e.g., addition and multiplication, are considerably slower than conventional CMOS-based operations. The advantage of PIM stems from the high degree of parallelism provided and minimal data movement overhead. In some embodiments, RAPID, effectively exploits the properties of PIM to enable a highly scalable, accurate and energy-efficient solution for DNA alignment.

For Example:

RAPID can make well-known dynamic programming-based DNA alignment algorithms, e.g., Needleman-Wunsch, compatible with and more efficient for operation using PIM by separating the query and reference sequence matching from the computation of the corresponding score matrix.

RAPID provides a highly scalable H-tree connected architecture for RAPID. It allows low-energy within-the-memory data transfers between adjacent memory units. Also, it enables us to combine multiple RAPID chips to store huge databases and support database-wide alignment.

A RAPID memory unit, comprising a plurality of blocks, provides the capability to perform exact and highly parallel matrix-diagonal-wide forward computation while storing only two diagonals of substitution matrix rather than the whole matrix. It also stores traceback information in the form of direction of computation, instead of element-to-element relation.

We evaluated the efficiency of the disclosed architecture by aligning real-world chromosome sequences, i.e., from human and chimpanzee genomes. The results show that RAPID is at least 2× faster and 7× more power efficient than BioSEAL, the best DNA sequence alignment accelerator.

### 7-II. Landscape of Rapid

### 7-II.1. Sequence Alignment

Natural evolution and mutation as well as experimental errors during sequencing poses two kinds of changes in sequences—substitutions and indels. A substitution changes a base of the sequence with another, leading to a mismatch whereas an indel either inserts or deletes a base. Substitutions are easily recognizable by Hamming distance. However, indels can be mischaracterized as multiple differences, if one merely applies Hamming distance as the similarity metric. The following figure shows comparison of two sequences x=ATGTTATA and y=ATCGTCC. The left figure rigidly compares the i^{th} base of x with y, while the right figure assumes a different alignment which leads to higher number of matches, taking account the fact that not only bases might change (mismatch) from one sequence to another, insertions and deletions are quite probable. Note that the notation of dashes (-) is conceptual, i.e., there is no dash (-) base in a read sequence.

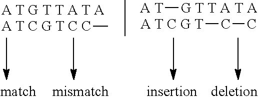

Dashes are used to illustrate a potential scenario that one sequence has been (or can be) evolved to the other. In short, sequence alignment aims to find out the best number and location of the dashes such that the resultant sequences yield the best similarity score.

As comparing all possible scenarios of aligning is exponentially proportional to the aggregate length of the sequences, hence computationally intractable, more efficient alignment approaches have been proposed. These methods can be categorized to heuristic methods and those based on dynamic programming, namely, Needleman-Wunsch for global and Smith-Waterman for local alignment. Heuristic techniques are computationally lighter but do not guarantee to find an optimal alignment solution, especially in sequences that contain a large number of indels. However, these techniques are still employed because the exact methods (based on dynamic programming) were computationally feasible. Though they might also utilize the Smith-Waterman dynamic programming approach to build-up the final gapped alignment.

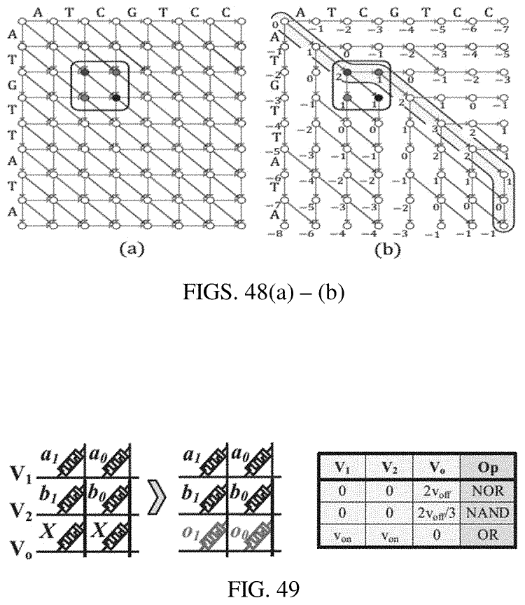

Dynamic programming-based methods involve forming a substitution matrix of the sequences. This matrix computes scores of various possible alignments based on a scoring reward and mismatch penalty. These methods avoid redundant computations by using the information already obtained for alignment of the shorter subsequences. The problem of sequence alignment is analogous to the Manhattan tourist problem: starting from coordinate (0. 0), i.e., left upper corner, we need to maximize the overall weights of the edges down to the (m,n), wherein the weights are the rewards/costs of matches, mismatches, and indels. FIG. 48a demonstrates the alignment of our previous example. The reference sequence x=ATGTTATA is put as the left column and the query sequence y=ATCGTCC as the first row. Diagonal moves indicate traversing a base in both sequences, which results in either a match ( [symbol] ) or mismatch ( [symbol] ). Each → (right) and ↓ (down) edge in the alignment graph denotes an insertion and deletion, respectively.

FIG. 48b shows the art of dynamic programming (Needleman-Wunsch), wherein every solution point has been calculated based on the best previous solution. The number adjacent to each vertex shows the score of the alignment up to that point, assuming a score of +1 for matches and −1 for the substitutions and indels. As an instance, alignment of x=ATG with y=ATC corresponds to the coordinate (3,3) in FIG. 48, denoted by •. This alignment, recursively, can be achieved in three different ways. The first approach is to first align x′=AT and y′=AT, denoted by • in the figure, followed by concatenation of G and C into the x′ and y′, which causes a mismatch ( [symbol] ) and score deduction by −1. Another approach could be moving from • to • meaning that align ATG with ATC from x′=AT− with y′=ATC by deletion (↓), i.e., making x′=AT−G and y′=ATC−. The third approach was forming • by inserting C while moving from •. As it can be perceived, though we need to solve the three immediate previous alignments, we do not need to calculate them from scratch as they would be obtained already if we fill out the alignment graph diagonally, moving from the first diagonal (which has a single element) towards the last diagonal in a baroque manner. This grants us diagonal-level parallelism as we can calculate all elements of a diagonal independently.

All in all, the Needleman-Wunsch global alignment can be formulated as follows. Matrix M holds the best alignment score for all pairwise alignments and score (xᵢ,-) and score (-, yᵢ) denote the cost of deletion and insertion. It essentially assumes the scenarios above when recursively aligning two sequences: whether either x or y ends with -, or a base. The difference of Smith-Waterman algorithm is it changes the negative edges to 0 to account for local alignments.

$${M}_{i , j} = max \{ \begin{matrix}{M}_{i - 1 , i} + score ( {x}_{i} , - ) & deletion \\ {M}_{i , j - 1} + score ( - , {y}_{i} ) & insertion \\ {M}_{i - 1 , j - 1} + score ( {x}_{i} , {y}_{i} ) & match / mismatch\end{matrix}$$

### 7-II.2. Digital Processing In-Memory

Traditionally, processing with memristors is based on reading currents through different cells. However, some recent work has demonstrated ways, both in literature and by fabricating chips, to implement logic using memristor switching. Digital processing in-memory exploits variable switching of memristors. The output device switches whenever the voltage across it exceeds a threshold. This property can be exploited to implement a variety of logic functions inside memory. FIG. 49 shows the latest work in this direction where the output of operation changes with the applied voltage. In-memory operations are in general slower than the corresponding CMOS-based implementations because memristor devices switch slowly. However, PIM architectures can provide significant speedup when running applications with massive parallelism. For example, it takes the same amount of time for PIM to perform operations in a single row or all rows.

The PIM based designs proposed in PRINS and BioSEAL accelerates the Smith-Waterman algorithm based on associative computing. The major issue with these works is their large amount of write operation and internal data movement to perform the sequential associative search. Another set of work accelerates short read alignment, where large sequences are broken down into smaller sequences and one of the heuristic methods is applied. The work in RADAR and AligneR exploited the same ReRAM to design a new architecture to accelerate BLASTN and FM-indexing for DNA alignment. The work in and Darwin propose new ASIC accelerators and algorithm for short read alignment. Some implementations have been done on FPGAs, of which ASAP proposed a programmable hardware by using circuit delays proposed by RaceLogic.

### 7-II. In-Memory Implementation of Rapid

RAPID, which implements the DNA sequence alignment technique is disclosed. It adopts a holistic approach where it changes the traditional implementation of the technique to make it compatible with memory. RAPID also discloses an architecture which takes into account the structure of and the data dependencies in DNA alignment. The disclosed architecture is scalable and minimizes internal data movement.

### 7-III.1. Implementation Using PIM

In order to optimize the DP techniques for in-memory computation, we made some modifications to the implementation of the substitution-matrix buildup. The score of aligning two characters depends if they do match or not. First, we avoid additional branching during the computation by pre-computing a matrix C, which separates the input sequence matching stage from the corresponding forward computation phase, allowing RAPID to achieve high parallelism. The matrix C is defined as follows:

$$C [ i , j ] = \{ \begin{matrix}0 & x [ i ] = y [ j ] \\ m & x [ i ] \neq y [ j ]\end{matrix} \qquad ( 7 \text{-} 1 )$$

DP techniques for sequence alignment are inherently parallelizable in a diagonal-wise manner. To make it compatible with the column-parallel operations in PIM, we map each diagonal of the matrix M to a row of memory. Let us consider the set of diagonals {d₀, d₁, d₂, . . . , dₙ}, where n′=n+m, equal to the total length of the sequences. Let M[i, j] correspond to dₖ[l]. Then, M[i−1, j], M[i, j−1], and M[i−1, j−1] correspond to dₖ₋₁[l], dₖ₋₁[l−1], and dₖ₋₂[l−1] respectively.

Second, we deal solely within the domain of unsigned integers, based on the observation that writing ‘1’ to the memory is both slower as well as more energy consuming than writing ‘0’. Since negative numbers are sign-extended with ‘1,’ writing small negative numbers in the form of 32-bit words has a significantly higher number of 1's. Especially, −10≤m<0, which sets >90% of bits to ‘1’ as compared to ˜5% for their positive counterparts. We enable this by changing the definition of matrix M as follows.

$$M [ 0 , i ] = σ \times i i ∈ [ 1 , {L}_{x} ] M [ j , 0 ] = σ \times j j ∈ [ 1 , {L}_{y} ] \qquad ( 7 \text{-} 2 )$$

with σ being the cost of indels. This modification makes two changes in the matrix build-up procedure. First, instead of subtracting the matrix elements by a in the case of indels, now we need to add sigma with those elements. Consequently, we replace maximum operation with a minimum function between the three matrix elements. Hence, when x[i]=y[j], the element updates as follow (note that, as shown by Equation 1, the cost of aligning the same bases is 0).

min(M[i−1,j−1],M[i,j−1]+σ,M[i−1,j]+σ)

Using these modifications, we can reformulate the technique in terms of in-memory row operations as follows:

M[i, j]=min(M[i−1, j−1]+C[i, j], M[i, j−1]+σ, M[i−1, j]+σ) which is equivalent to, dₖ[l]=min(dₖ₋₂[l−1]+C[k−2, l−1], dₖ₋₁[l]+σ, dₖ₋₁[l−1]+σ). Since we already have dₖ₋₂ and dₖ₋₁ while computing dₖ, we can express the computation of dₖ as:

### Technique-1:

1) Add σ to every element in dₖ₋₁ and store it in row A

2) Copy row A to row B, then shift row B right by one

3) Element-wise add Cₖ₋₂ to dₖ₋₂. and store it in row C

4) Set dₖ to be the element-wise minimum of A, B and C

We perform all steps of Technique-1 using only shift, addition, and minimum operations.

Once the matrix computation completes, the backtracking step must occur. RAPID enables backtracking efficiently in memory by dedicating small memory blocks that store the direction of traceback computation.

### 7-III.2. RAPID Architecture

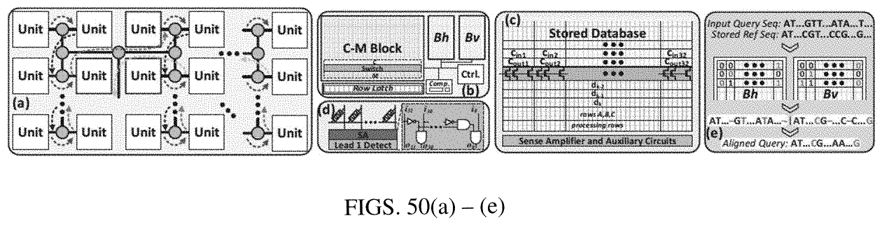

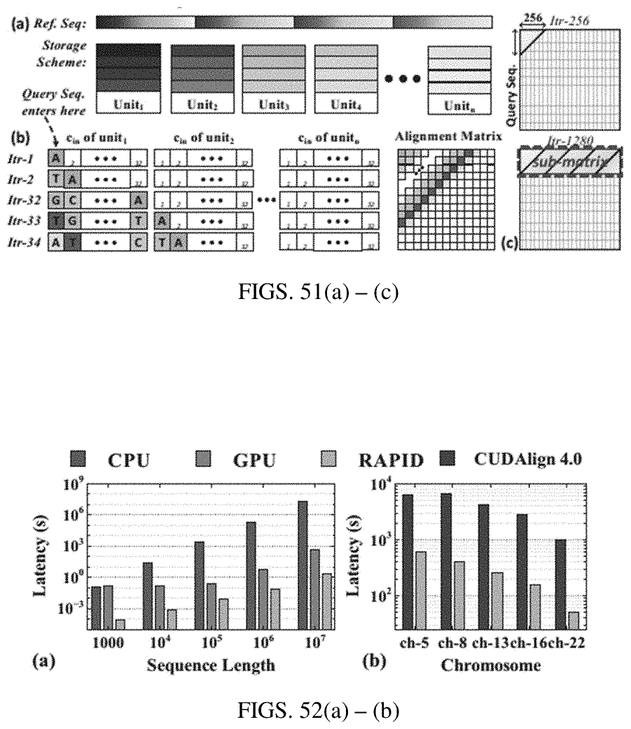

A RAPID chip can include multiple RAPID-units connected in H-tree structure, shown in FIG. 50. The RAPID-units collectively store database sequences or reference genome and perform the alignment. For maximum efficiency, RAPID evenly distributes the stored sequence among the units. RAPID takes in a query sequence and finally outputs details of the required insertions and deletions in the form of traceback information. As shown in FIG. 51b, RAPID takes in one word at a time. An iteration of RAPID evaluates one diagonal of the substitution or the alignment matrix. After every iteration, RAPID takes in a new word of the query sequence and the previous part is propagated through different units as shown in FIG. 51b. This propagation results in a continuous transfer of data from a unit to the next unit. Although this transfer is limited to a few words per iteration, it may create a bottleneck if the conventional bus-like interconnect is used to connect memory blocks. We also observe that most of these transfers are local, i.e., between adjacent units. Hence, RAPID uses an H-tree interconnect to connect different units.

1) RAPID organization: The H-tree structure of RAPID directly connects the adjacent units. FIG. 50a show the organization in detail. The H-tree interconnect allows low latency transfers between adjacent units. The benefits are enhanced as it allows multiple unit-pairs to exchange data in parallel. The arrows in the figure represent these data transfers, where transfers denoted by same-colored arrows happen in parallel. We also enable computation on these interconnects. In RAPID, each H-tree node has a comparator. This comparator receives some alignment scores from either two units or two nodes and stores the maximum of the two along with the details of its source. These comparators are present at every level of the hierarchy and track the location of the global maximum of chip.

2) RAPID-unit: Each RAPID-unit is made up of three ReRAM blocks: a big C-M block and two smaller blocks, Bₕ and Bᵥ. The C-M block stores the database or reference genome and is responsible for the generation of C and M matrices discussed in Section 7-III-A. The Bh and B, blocks store traceback information corresponding to the alignment in C-M.

C-M block: A C-M block is shown in FIG. 50c. The C-M block stores the database and computes matrices C and M, introduced in Section 7-III-A. C-M is divided into two sub-blocks using switches. The upper sub-block stores the database sequences in the gray region in the figure and computes the C matrix in the green region while the lower sub-block computes the M matrix in the blue region. This physical division allows RAPID to compute both the matrices independently while eliminating data transfer between the two matrices. C matrix pre-computes the penalties for mismatches between the query and reference sequences. The C sub-block generates one diagonal of C at a time. In each iteration, RAPID stores the new input word received from the adjacent unit as cᵢₙ₁. The cᵢₙ₂ to cᵢₙ₃₂ are formed by shifting the previous part of the sequence by one word as shown in FIG. 51b. The resulted ci. is then compared with one of the database rows to form C[i,j] for the diagonal as discussed in Equation (7-1). RAPID makes this comparison by XORing cinwith the database row. It stores the output of XOR in a row, cₒᵤₜ. All the non-zero data points in cₒᵤₜ are then set to m (Equation (7-1). C[i,j] generation uses just two rows in the C sub-block.

The M sub-block generates one diagonal of the substitution-matrix at a time. According to Technique 1, this computation involves two previously computed rows of M and one row of the C matrix. Hence, for computation of a row dₖ in M, dₖ₋₂ and dₖ₋₁ are required. C[i,j] is made available by activating the switches. The operations involved as per technique 1, namely XOR, addition, and minimum, are fully supported in memory as described in Section 7-III-C. The rows A, B, and C in FIG. 50c correspond to the rows A, B, and C in Technique 1. After the evaluation of dk, we need to identify the maximum value in dₖ to keep track of the maximum alignment score. Hence, RAPID reads out dₖ and stores it in the row latch in the figure. A comparator next to the row latch serially processes all the words in a row of C-M block and stores the value and index of the maximum alignment score. As shown in the figure, at any instance k, we just store dₖ, dₖ₋₁, and dₖ₋₂. This is in contrast to traditional implementations, where the entire M matrix (of size length_query×length_reference) is computed and stored. RAPID enables the storage of just two previous rows by (i) continuously tracking the global maximum alignment score and its location using H-tree node comparators and local unit comparators and (ii) storing traceback information. In total, M sub-block uses just eight rows, including two processing rows.

C-M block computational flow: Only one row of C is needed while computing a row of M. Hence we parallelize the computation of C and M matrices. The switch-based subdivision physically enables this parallelism. At any computation step, k, C[k] is computed in parallel to the addition of g to dₖ₋₁ (1 in Technique-1). Then addition output is read from the row A and written back after being shifted by one (2 in Technique-1) to row B. Following the technique, C[k] is added to dₖ-2 and stored in row C and finally dₖ is calculated by selecting the minimum of the results of previous steps.

Bh and By blocks: The matrices Bh and By together form the backtracking matrix. Every time a row dₖ is calculated, Bh and By are set depending upon the output of minimum operation. Let dₖi represent 1 th word in dₖ. Whenever the minimum for 1 th word is row A, {Bh[k,l], Bv[k,l]} is set to {1, 0}, for row B, {Bh[k,l], Bv[k,l]} is set to {0, 1}, and for row C, both Bh[k,l] and Bv[k,l] are reset to 0. After the completion of forward computation (substitution matrix buildup), the is in matrices Bh and By are traced from end to the beginning. The starting point for alignment is given by the index corresponding to the maximum score, which is present in the top-level registered-comparator. The values of [Bh[i,j], Bv[i,j]] form the final alignment. If [Bhij, Bvij] is (i) [1,0]: it represents insertion, (ii) [0,1]: it represents deletion, and (iii) [0,0]: it represents no gap.

3) Sequence Alignment over Multiple RAPID Units: Here, we first demonstrate the working of RAPID using a small example and then generalize it.

Example Setting: Say, that the RAPID chip has eight units, each with a C-M block size of 1024×1024. 1024 bits in a row result in a unit with just 32 words per row, resulting in Bh and By blocks of size 32×1024 each. Assume that the accelerator stores a reference sequence, seqr, of length 1024.

Storage of Reference Sequence: The reference sequence is stored in a way to maximize the parallelism while performing DP-based alignment approaches, as shown in FIG. 51a. RAPID fills a row, rᵢ, of all the C-M blocks before storing data in the consecutive rows. Hence, in total, the first 256 data words, 8×32 (#units×#words-per-row), are stored in the first rows of the units and the next 256 data words in the second rows. Since only 256 words of the reference sequence are available at a time, this chip can process just 256 elements of a diagonal in parallel.

Alignment: Now, a query sequence, seq_{q}, is to be aligned with seqr. Let the lengths of the query and reference sequences be L_{q} and Lᵣ, both being of length 1024. The corresponding substitution-matrix is of the size L_{q}×Lᵣ, 1024×1024 in this case. As our sample chip can process a maximum of 256 data words in parallel, we deal with 256 query words at a time. We divide the substitution-matrix into sub-matrices of 256 rows as shown in the FIG. 51c and process one sub-matrix at a time.

The sequence seq_{q} is transferred to RAPID, one word at a time, and stored as the first word of cᵢₙ. Every iteration receives a new query word (base). cᵢₙ is right shifted by one word and we append the new word received to cᵢₙ. The resultant cᵢₙ is used to generate one diagonal of substitution-matrix as explained earlier. For the first 256 iterations, RAPID computes first 256 diagonals completely as shown in FIG. 51c. This processes the first 256 query words with the first 256 reference words. Now, instead of receiving new inputs, RAPID uses the same inputs but processes them with the reference words in the second row. This goes on until the current 256 words of the query have not processed with all the rows of the reference sequence.

In the end, the first submatrix of 256 rows is generated (FIG. 51c). It takes 256×5 iterations (words_in_row×(#segᵣ_rows+1)). Similarly, RAPID generate the following sub-matrices.

4) Suitability of RAPID for DNA alignment: RAPID instruments each storage block with computing capability. This results in low internal data movement between different memory blocks. Also, the typical sizes of DNA databases don't allow storage of entire databases in a single memory chip. Hence, any accelerator using DNA databases needs to be highly scalable. RAPID, with its mutually independent blocks, compute-enabled H-tree connections, and hierarchical architecture, is highly scalable within a chip and across multiple chips as well. The additional chips add levels in RAPID's H-tree hierarchy.

### 7-III.3. RAPID Circuit Details

The computation of the disclosed technique uses three main operations: XOR, addition, and Min/Max. In the following, we explain how RAPID can implement these functionalities on different rows of a crossbar memory.

XOR: We use the PIM technique disclosed in to implement XOR in memory. XOR (⊗) can be expressed in terms of OR (+), AND (·), and NAND ((·)′) as A⊗B=(A+B)·(A·B)′. We first calculate OR and then use its output cell to implement NAND. These operations are implemented by the method earlier discussed in Section 7-II-B. We can execute this operation in parallel over all the columns of two rows.

Addition: Let A, B, and Cᵢₙ be 1-bit inputs of addition, and S and Cₒᵤₜ the generated sum and carry bits respectively. Then, S is implemented as two serial in-memory XOR operations (A⊗B)⊗C. Cₒᵤt, on the other hand, can be executed by inverting the output of the Min function. Addition takes a total of 6 cycles and similar to XOR, we can parallelize it over multiple columns.

Minimum: A minimum operation between two numbers is typically implemented by subtracting the numbers and checking the sign bit. The performance of subtraction scales with the size of inputs. Multiple such operations over long vectors lead to lower performance. Hence, we utilize a parallel in-memory minimum operation. It finds the element-wise minimum in parallel between two large vectors without sequentially comparing them. First, it performs a bitwise XOR operation over two inputs. Then it uses the leading one detector circuit in FIG. 50d to find the most significant mismatch bit in those words. The input with a value of ‘0’ at this bit is the minimum of the two.

### 7-IV. Evaluation

7-IV.1. Experimental setup

We created and used a cycle-accurate simulator which simulates the functionality of RAPID. For the accelerator design, we use HSPICE for circuit-level simulations to measure the energy consumption and performance of all the RAPID operations using a 45 nm process node. We used the VTEAM ReRAM device model disclosed in with the R_{OFF}/R_{ON} of 10M/10k Q. The device has a switching time of 1.1 ns, allowing RAPID to run at a frequency of 0.9 GHz. Energy consumption and performance are also cross-validated using NVSim. The device area model is based on. We used System Verilog and Synopsys Design Compiler to implement and synthesize RAPID controller.

For the comparisons, we consider RAPID with an area of 660 mm², similar to NVIDIA GTX-1080 Ti GPU with 4 GB memory, unless otherwise stated. In this configuration, RAPID has a simulated power dissipation of 470 W as compared ˜100 kW for 384-GPU cluster of CUDAlign 4.0, ˜1.3 kW for PRINS, and ˜1.5 kW for BioSEAL, while running similar workloads.

### 7-IV.2. RAPID & Sequence Length

We first evaluate RAPID's operational efficiency by implementing a pair-wise alignment of two sequences and compare the results with in-house CPU and GPU implementations. We vary the length of sequences to observe its effect on RAPID. For CPU baseline, we use a Julia implementation of the Needleman-Wunsch algorithm, run on a 2.8 GHz Intel Core i7 processor. While for GPU baseline, we use the implementation of Needleman-Wunsch from the package CUDAlign 4.0, run on NVIDIA GTX 1080 Ti GPU.

FIG. 52a shows the execution time of DNA alignment on different platforms. As our evaluation shows, increasing the length of the sequence degrades the alignment efficiency. However, the change in efficiency depends on the platform. Increasing the sequence length, exponentially increases the execution time of the CPU. This increase is because the CPU does not have enough cores to parallelize the alignment computation, resulting in a large amount of data movement between memory and processing cores. Similarity, the execution time of GPU increases with the sequence length. In contrast, RAPID has much smoother increases in the energy and execution time of the alignment. RAPID enables column-parallel operations where the alignment time only depends on the number of memory rows, which linearly increases by the size of sequences. Our evaluation over varying sequence lengths shows that for a sequence length of 1=1000 RAPID is 1585× faster computation than CPU. The benefit increases drastically as the size of the sequence increases, with RAPID being 9.6×106× faster than CPU for 1=10, 000, 000. The GPU implementation is observed to have significant latency overhead in the initial stages, performing very poorly on smaller test cases. However, in middle size sequences of 1=100, 000, GPU is only 34× slower than RAPID. However, as the sequence length further increases, e.g., 1=10, 000, 000, we observe that RAPID outperforms GPU by 214×. On the other hand, RAPID works better than GPU for both small and massive datasets.

### 7-IV.3. RAPID for Exact Chromosome-Wide Alignment

Workload: To demonstrate the applicability of RAPID to long chromosome-wide alignment, we used DNA sequences from the National Center for Biotechnology Information (NCBI). We compared the 25 homologous chromosomes from humans (GRCh37) and chimpanzees (panTro4). The sizes of chromosomes vary from 26 MBP (million base pairs) to 249 MBP. In total, these chromosomes add up to 3.3 billion base pairs (BBP) for GRCh37 and 3.1 BBP for panTro4. The human genome is assumed to be pre-stored in RAPID and acts as the reference sequence. The chimpanzee genome is assumed to be transferred to RAPID and acts as the query sequence. RAPID takes in one new base every iteration and propagates it. In the time taken by the external system to send a new query base to RAPID, it processes a diagonal of the substitution matrix. In every iteration, RAPID processes a new diagonal. For example, a comparison between chromosome-1 (ch-1) of human genome with 249 MBP and ch1 of chimpanzee genome with 228 MBP results in a substitution matrix with 477 million diagonals, requiring those many forward computation operations and then traceback.

TABLE 7-I
RELATIVE LATENCY AND POWER OF DIFFERENT
RAPID CHIPS FOR ch - 1

| Chip Area | | Relative | Relative |
|---|---|---|---|
| (mm²) | # Chips | Latency | Power |
| 660 | 1 | 1.00 | 1.00 |
| | 2 | 0.52 | 1.93 |
| 1300 | 1 | 0.52 | 1.96 |
| 332 | 1 | 1.94 | 0.51 |
| | 2 | 1.01 | 0.99 |
| | 4 | 0.53 | 1.90 |
| 168 | 1 | 3.82 | 0.26 |
| | 4 | 1.03 | 0.97 |
| | 8 | 0.54 | 1.88 |
| 85 | 1 | 7.50 | 0.13 |
| | 8 | 1.04 | 0.96 |
| | 16 | 0.54 | 2.09 |

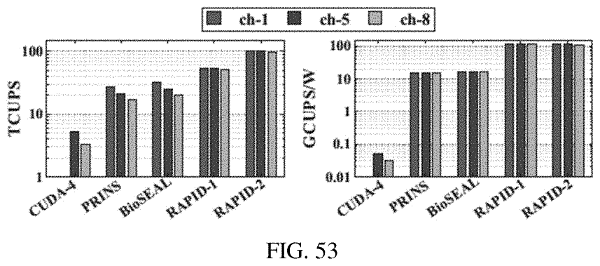

We compare RAPID with implementations of DNA sequence alignment while running exact chromosome-wide alignment. We compare our results with CUDAlign 4.0, the fastest GPU-based implementation and two ReCAM-based DNA alignments architecture proposed in PRINS and BioSEAL. FIG. 52b shows the execution time of aligning different test pairs on RAPID and CUDAlign 4.0. We observe that RAPID is on an average 11.8× faster than the CUD-Align 4.0 implementation with 384 GPUs. The improvements from RAPID increase further if fewer GPUs are available. For example, RAPID is over 300× faster than CUDAlign 4.0 with 48 GPUs. We also evaluated RAPID, CUDAlign 4.0, and the ReCAM-based designs, PRINS and BioSEAL in terms of cell updates per sec (CUPS) as shown in FIG. 53. RAPID achieves 2.4× and 2× higher performance as compared to PRINS and BioSEAL. It is also on average, 2820× more energy efficient than CUDAlign 4.0 and 7.5× and 6.9× than PRINS and BioSEAL respectively as shown in FIG. 6b. Also, when the area of the RAPID chip increases from the current 660 mm2 to 1300 mm², the performance doubles without increasing the total energy consumption significantly.

Scalability of RAPID: Table 7-I shows the latency and power of RAPID while aligning ch-1 pair from human and chimpanzee genomes on different RAPID chip sizes. Keeping RAPID-660 mm2 as the base, we observe that with decreasing chip area, the latency increases but power reduces almost linearly, implying that the total power consumption remains similar throughout. We also see that, by combining multiple smaller chips, we can achieve performance similar to a bigger chip. For example, eight RAPID-85 mm² chips can collectively achieve a speed similar to a RAPID-660 mm² chip, with just 4% latency overhead. This exceptional scalability is due to the hierarchical structure of H-tree, where RAPID considers multiple chips as additional levels in H-tree organization. However, this comes with the constraint of having the number of memory blocks as powers of 2 for maximum efficiency and simple organization.

### 7-V.4. Area Overhead

RAPID incurs 25.2% area overhead as compared to a conventional memory crossbar of the same memory capacity. This additional area comes in the form of registered comparators in units and at interconnect nodes (6.9%) and latches to store a whole row of a block (12.4%). We use switches to physically partition a C-M memory block, which contributes 1.1%. Using H-tree instead of the conventional interconnect scheme takes additional 4.8%.

As described herein, RAPID provides a processing-in-memory (PIM) architecture suited for DNA sequence alignment. In some embodiments, RAPID provides a dramatic reduction in internal data movement while maintaining a remarkable degree of operational column-level parallelism provided by PIM. The architecture is highly scalable, which facilitates precise alignment of lengthy sequences. We evaluated the efficiency of the disclosed architecture by aligning chromosome sequences from human and chimpanzee genomes. The results show that RAPID is at least 2× faster and 7× more power efficient than BioSEAL, the best DNA sequence alignment accelerator.

### Part 8: Workload-Aware Processing in Multi-FPGA Platforms

As appreciated by the present inventors, the continuous growth of big data applications with high computational and scalability demands has resulted in increasing popularity of cloud computing. Optimizing the performance and power consumption of cloud resources is therefore crucial to relieve the costs of data centers. In recent years, multi-FPGA platforms have gained traction in data centers as low-cost yet high-performance solutions particularly as acceleration engines, thanks to the high degree of parallelism they provide. Nonetheless, the size of data centers workloads varies during service time, leading to significant underutilization of computing resources while consuming a large amount of power, which turns out as a key factor of data center inefficiency, regardless of the underlying hardware structure.

Accordingly, disclosed herein is a framework to throttle the power consumption of multi-FPGA platforms by dynamically scaling the voltage and hereby frequency during runtime according to prediction of, and adjustment to the workload level, while maintaining the desired Quality of Service (QoS) (referred to herein as Workload-Aware). This is in contrast to, and more efficient than, conventional approaches that merely scale (i.e., power-gate) the computing nodes or frequency. This framework carefully exploits a pre-characterized library of delay-voltage, and power-voltage information of FPGA resources, which we show is indispensable to obtain the efficient operating point due to the different sensitivity of resources w.r.t. voltage scaling, particularly considering multiple power rails residing in these devices. Our evaluations by implementing state-of-the-art deep neural network accelerators revealed that, providing an average power reduction of 4.0×, the disclosed framework surpasses the previous works by 33.6% (up to 83%).

### 8-I. Introduction

The emergence and prevalence of big data and related analysis methods, e.g., machine learning on the one hand, and the demand for a cost-efficient, fast, and scalable computing platform on the other hand, have resulted in an ever-increasing popularity of cloud services where services of the majority of large businesses nowadays rely on cloud resources. In a highly competitive market, cloud infrastructure providers such as Amazon Web Services, Microsoft Azure, and Google Compute Engine, offer high computational power with affordable price, releasing individual users and corporations from setting up and updating hardware and software infrastructures. Increase of cloud computation demand and capability results in growing hyperscale cloud servers that consume a huge amount of energy. In 2010, data centers accounted for 1.1-1.5% of the world's total electricity consumption, with a spike to 4% in 2014 raised by the move of localized computing to cloud facilities. It is anticipated that the energy consumption of data centers will double every five years.

The huge power consumption of cloud data centers has several adverse consequences: (i) operational cost of cloud servers obliges the providers to raise the price of services, (ii) high power consumption increases the working temperature which leads to a significant reduction in the system reliability as well as the data center lifetime, and (iii) producing the energy required for cloud servers emits an enormous amount of environmentally hostile carbon dioxide. Therefore, improving the power efficiency of cloud servers is a critical obligation.

That being said several specialized hardware accelerators, or ASIC-ish solutions have been developed to increase the performance per watt efficiency of data centers. Unfortunately, they are limited to a specific subset of applications while the applications and/or implementation of data centers evolve with a high pace. Thanks to their relatively lower power consumption, fine-grained parallelism, and programmability, in the last few years, Field-Programmable Gate Arrays (FPGAs) have shown great performance in various applications. Therefore, they have been integrated in data centers to accelerate the data center applications. Cloud service providers offer FPGAs as Infrastructure as a Service (IaaS) or use them to provide Software as a Service (SaaS). Amazon and Azure provide multi-FPGA platforms for cloud users to implement their own applications. Microsoft and Google are other big names of corporations/companies that also provide applications as a service, e.g., convolutional neural networks, search engines, text analysis, etc. using multi-FPGA platforms.

Having all the benefits blessed by FPGAs, underutilization of computing resources is still the main contributor to energy loss in data centers. Data centers are expected to provide the required QoS of users while the size of the incoming workload varies temporally. Typically, the size of the workload is less than 30% of the users' expected maximum, directly translating to the fact that servers run at less than 30% of their maximum capacity. Several works have attempted to tackle the underutilization in FPGA clouds by leveraging the concept of virtual machines to minimize the amount of required resources and turn off the unused resources. In these approaches, FPGA floorplan is split into smaller chunks, called virtual FPGAs, each of which hosts a virtual machine. FPGA virtualization, however, degrades the performance of applications, congests routing, and more importantly, limits the area of applications. This scheme also suffers from security challenges.

Further, in some embodiments, energy consumption of multi-FPGA data center platforms, can be accounting for the fact that the workload is often considerably less than the maximum anticipated. Workload-Aware can use the available resources while efficiently scaling the voltage of the entire system such that the projected throughput (i.e., QoS) is delivered. Workload-AwareHD can epitomize a light-weight predictor for proactive estimation of the incoming workload and it to power-aware timing analysis framework that adjusts the frequency and finds optimal voltages, keeping the process transparent to users. Analytically and empirically, we show that Workload-AwareHD is significantly more efficient than conventional power-gating approaches and memory/core voltage scaling techniques that merely check timing closure, overlooking the attributes of implemented application.

### 8-II. Landscape of Workload-AwareHD

The use of FPGAs in modern data centers have been gained attention recently as a response to rapid evolution pace of data center services in tandem with the inflexibility of application-specific accelerators and unaffordable power requirement of GPUs. Data center FPGAs are offered in various ways, Infrastructure as a Service for FPGA rental, Platform as a Service to offer acceleration services, and Software as a service to offer accelerated vendor services/software. Though primary works deploy FPGAs as tightly coupled server addendum, recent works provision FPGAs as an ordinary standalone network-connected server-class node with memory, computation and networking capabilities. Various ways of utilizing FPGA devices in data centers have been well elaborated.

FPGA data centers, in parts, address the problem of programmability with comparatively less power consumption than GPUs. Nonetheless, the significant resource underutilization in non-peak workload yet wastes a high amount of data centers energy. FPGA virtualization attempted to resolve this issue by splitting the FPGA fabric into multiple chunks and implementing applications in the so-called virtual FPGAs.

### 8-III. Analysis

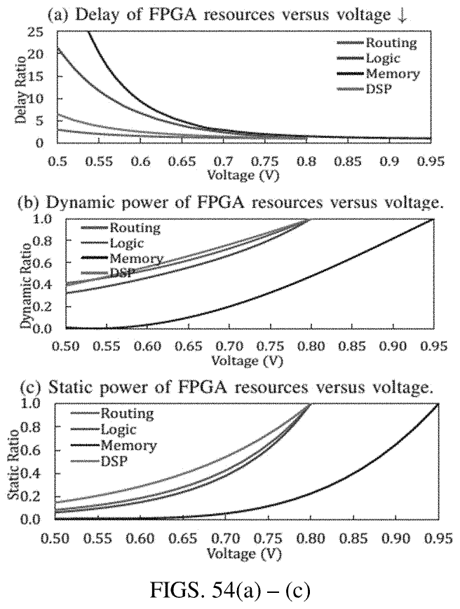

In this section, we use a simplified example to justify illustrate the disclosed Workload-AwareHD technique and how it surpasses the conventional approaches in power efficiency. FIG. 54 shows the relation of delay and power consumption of FPGA resources when voltage scales down. Experimental results will be elaborated in Section 8-VI, but concisely, routing and logic delay and power indicate the average delay and power of individual routing resources (e.g., switch boxes and connection block multiplexers) and logic resources (e.g., LUTs). Memory stands for the on-chip BRAMs, and DSP is the digital signal processing hard macro block. Except memory blocks, the other resources share the same V_{core} power rail. Since FPGA memories incorporate high-threshold process technology, they utilize a V_{bram} voltage that is initially higher than nominal core voltage V_{core} to enhance the performance. We assumed a nominal memory and core voltage of 0.95V and 0.8V, respectively.

The different sensitivity of resources' delay and power with respect to voltage scaling implies cautious considerations when scaling the voltage. For instance, by comparing FIG. 54a and FIG. 54c, we can understand that reducing the memory voltage from 0.95V down to 0.80V has a relatively small effect on its delay, while its static power decreases by more than 75%. Then we see a spike in memory delay with trivial improvement of its power, meaning that it is not beneficial to scale V_{bram} anymore. Similarly, routing resources show good delay tolerance versus voltage scaling. It is mainly because of their simple two-level pass-transistor based structure with boosted configuration SRAM voltage that alleviates the drop of drain voltages. Notice that we assume a separate power rail for configuration SRAM cells and do not change their voltages as they are made up of thick high-threshold transistors that have already throttled their leakage current by two orders of magnitude though have a crucial impact on FPGA performance. Nor we do scale the auxiliary voltage of I/O rails to facile standard interfacing. While low sensitivity of routing resources against voltage implied V_{core} is a prosperous candidate in interconnection-bound designs, the large increase of logic delay with voltage scaling hinders V_{core} scaling when the critical path consists of mostly LUTs. In the following we show how varying parameters of workload, critical path(s), and application affect optimum ‘V_{core}, V_{bram}’ point and energy saving.

Let us consider the critical path delay of an arbitrary application as Equation (8-1).

$${d}_{c p} = {d}_{l 0} \cdot {D}_{l} ( {V}_{c o r e} ) + {d}_{m 0} \cdot {D}_{m} ( {V}_{b r a m} ) \qquad ( 8 \text{-} 1 )$$

Where dₗ₀ stands for the initial delay of the logic and routing part of the critical path, and Dₗ(V_{core}) denotes the voltage scaling factor, i.e., information of FIG. 54a. Analogously, dₘ₀ and Dₘ(V_{bram}) are the memory counterparts. The original delay of the application is dₗ₀+dₘ₀, which can be stretched by (dₗ₀+dₘ₀)×S_{w} where S_{w}≥1 indicates the workload factor, meaning that in an 80% workload, the delay of all nodes can be increased up to

$${S}_{w} = \frac{1}{0.8} = 1 .2 .$$

### Defining

$$α = \frac{{d}_{m 0}}{{d}_{l 0}}$$

as the relative delay of memory block(s) in the critical path to logic/routing resources, the applications need to meet the following:

$${d}_{c p} ∝ {𝒟}_{1} ( {V}_{c o r e} ) + α \cdot {𝒟}_{m} ( {V}_{b r α m} ) \leq ( 1 + α ) \cdot {S}_{w} \qquad ( 8 \text{-} 2 )$$

We can derive a similar model for power consumption as a function of V_{core} and V_{bram} shown by Equation (8-3),

$${p}_{cir} ∝ {𝒫}_{1} ( {V}_{c o r e} , {d}_{c p} ) + β \cdot {𝒫}_{m} ( {V}_{bram} , {d}_{c p} ) \qquad ( 8 \text{-} 3 )$$

where P_{L}(V_{core}, d_{cp}) is for the total power drawn from the core rail by logic, routing, and DSP resources as a function of voltage V_{core} and frequency (delay) d_{cp}, and β is an application-dependent factor to determine the contribution of BRAM power. In the following, we initially assume α=0.2 (i.e., BRAM contributes to

$$\frac{0.2}{1 + 0.2}$$

of critical path delay) and β=0.4 (i.e., BRAM power initially is ˜25% of device total power).

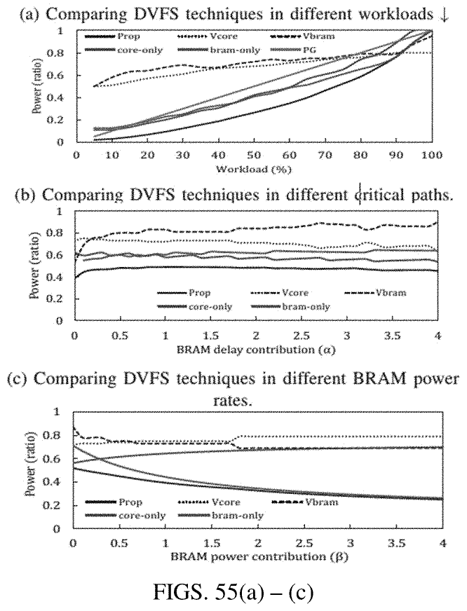

FIG. 55 demonstrates the efficiency of different voltage scaling schemes under varying workloads, applications' critical paths (‘α’s), and applications' power characteristics (i.e., β, the ratio of memory to chip power). Prop means the disclosed approach that simultaneously determines V_{core} and V_{bram}, core-only is the technique that only scales V_{core}, and bram-only is similar to. Dashed lines of V_{core} and V_{bram} in the figures show the magnitude of the V_{core} and V_{bram} in the disclosed approach, Prop (for the sake of clarity, we do not show voltages of the other methods). According to FIG. 55a, in high workloads (>90%, or S_{w}<1.1), our disclosed approach mostly reduces the V_{bram} voltage because slight reduction of the memory power in high voltages significantly improves the power efficiency, especially because the contribution of memory delay in the critical path is small (α=0.2), leaving room for V_{bram} scaling. For the same reason, core-only scheme has small gains there. FIG. 55 also reveals the sophisticated relation of the minimum voltage points and the size of workload; each workload level requires re-estimation of ‘V_{core}, V_{bram}’. In all cases, the disclosed approach yields the lowest power consumption. It is noteworthy that the conventional power-gating approach (denoted by PG in FIG. 55a) scales the number of computing nodes linearly with workload, though, the other approaches scale both frequency and voltage, leading to twofold power saving. In very low workloads, power-gating works better than the other two approaches because the crash voltage (˜0.50V) prevents further power reduction.

Similar insights can also be grasped from FIGS. 55b and 55c. A constant workload of 50% is assumed here while a and p parameters change. When the contribution of BRAM delay in total reduces, the disclosed approach tends to scale the V_{bram}. For α=0 highest power saving is achieved as the disclosed method can scale the voltage to the minimum possible, i.e., the crash voltage. Analogously in FIG. 55c, the effectiveness of the core-only (bram-only) method degrades (improves) when BRAM contributes to a significant ratio of total power, while our disclosed method can adjust both voltages cautiously to provide minimum power consumption. It is worth to note that the efficiency of the disclosed method increases in high BRAM powers because in these scenarios a minor reduction of BRAM power saves huge power with a small increase of delay (compare FIGS. 54a and 54c).

### 8-IV. Workload-AwareHD Approach

In practice, the generated data from different users are processed in a centralized FPGA platform located in datacenters. The computing resources of the data centers are rarely completely idle and sporadically operate near their maximum capacity. In fact, most of the time the incoming workload is between 10% to 50% of the maximum nominal workload. Multiple FPGA instances are designed to deliver the maximum nominal workload when running on the nominal frequency to provide the users' desired quality of service. However, since the incoming FPGA workloads are often lower than the maximum nominal workload, FPGA become underutilized. By scaling the operating frequency proportional to the incoming workload, the power dissipation will be reduced without violating the desired throughput. It is noteworthy that if an application has specific latency restrictions, it should be considered in the voltage and frequency scaling. The maximum operating frequency of the FPGA can be set depending on the delay of the critical path such that it guarantees the reliability and the correctness of the computation. By underscaling the frequency, i.e., stretching the clock period, delay of the critical path becomes less than the clock toggle rate. This extra timing room can be leveraged to underscale the voltage to minimize the energy consumption until the critical path delay again reaches the clock delay.

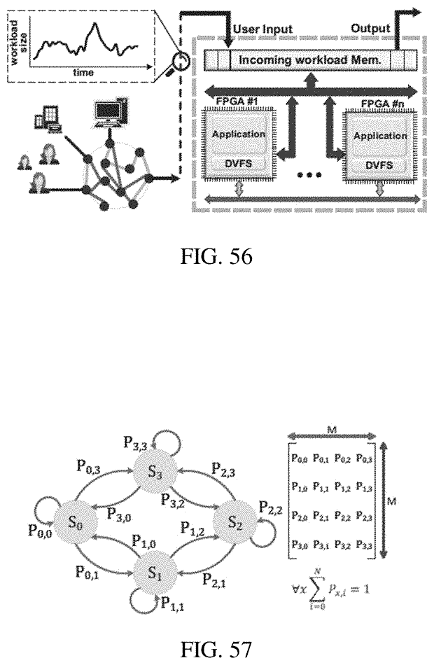

FIG. 56 abstracts an FPGA cloud platform consisting of n FPGA instances where all of them are processing the input data gathered from one or different users. FPGA instances are provided with the ability to modify their operating frequency and voltage. In the following we explain the workload prediction, dynamic frequency scaling and dynamic voltage scaling implementations.

### 8-IV.1. Workload Prediction

We divide the FPGA execution time to steps with the length of r, where the energy is minimized separately for each time step. At the i^{th} time step (τᵢ₋₁), our approach predicts the size of the workload for the i+1 time step. Accordingly, we set the working frequency of the platform such that it can complete the predicted workload for the t, time step.

To provide the desired QoS as well as minimizing the FPGA idle time, the size of the incoming workload needs to be predicted at each time step. The operating voltage and frequency of the platform is set based on the predicted workload. Generally, to predict and allocate resources for dynamic workloads, two different approaches have been established: reactive, and proactive. In reactive approach, resources are allocated to the workload based on a predefined threshold, while in proactive approach, the future size of the workload is predicted, and resources are allocated based on this prediction.

In the cases the service provider knows the periodic signatures of the incoming workload, the predictor can be loaded with this information. Workloads with repeating patterns are divided into time intervals which are repeated with the period. The average of the intervals represents a bias for the short-term prediction. For applications without repeating patterns, we use a discrete-time Markov chain with a finite number of states to represents the short-term characteristics of the incoming workload.

The size of the workload is discretized into M bins, each represented by a state in the Markov chain; all the states are connected through a directed edge. P_{i,j} shows the transition probability from state i to state j. Therefore, there are M×M edges between states where each edge has a probability learned during the training steps to predict the size of the incoming workload. FIG. 57 represents a Markov chain model with 4 states, {S₀, S₁, S₂, S₃}, in which a directed edge with label P_{i,j} shows the transition from Sᵢ to Sⱼ which happens with the probability of P_{i,j}. Considering the total probability of the outgoing edges of state Sᵢ has to be 1 as probability of selecting the next state is one.

Starting from S₀ with probability of P_{0,i} the next state will be Sᵢ. In the next time step, the third state will be again S₁ with P_{1,1} probability. If a pre-trained model of the workload is available, it can be loaded on FPGA, otherwise, the model needs to be trained during the runtime. During system initialization, the platform runs with the maximum frequency and works with the nominal frequency for the first I time steps. In the training phase, the Markov model learns the patterns of the incoming workload and the probability of transitions between states are set during this phase.

After I time steps, the Markov model predicts the incoming input of the next time step and the frequency of the platform is selected accordingly, with a t % throughput margin to offset the likelihood of workload under-estimation as well as to preclude consecutive mispredictions. Mispredictions can be either underestimations or over-estimations. In case of over-estimation, QoS is meet, however, some power is wasted as the frequency (and voltage) is set to an unnecessarily higher value. In case of workload under-estimation the desired QoS may be violated. The work in tackles most of the underestimations by t=5% margin.

### 8-IV.2. Frequency Scaling Flow

To achieve high energy efficiency, the operating FPGA frequency needs to be adjusted according to the size of the incoming workload. To scale the frequency of FPGAs, Intel (Altera) FPGAs enable Phase-Locked Loop (PLL) hard-macros (Xilinx also provide a similar feature). Each PLL generates up to 10 output clock signals from a reference clock. Each clock signal can have an independent frequency and phase as compared to the reference clock. PLLs support runtime reconfiguration through a Reconfiguration Port (RP). The reconfiguration process is capable of updating most of the PLL specifications, including clock frequency parameters sets (e.g., frequency and phase). To update the PLL parameters, a state machine controls the RP signals to all the FPGA PLL modules.

PLL module has a Lock signal that represents when the output clock signal is stable. The lock signal activates whenever there is a change in PLL inputs or parameters. After stabling the PLL inputs and the output clock signal, the lock signal is asserted again. The lock signal is de-asserted during the PLL reprogramming and will be issued again in, at most, 100 μSec. Each of the FPGA instances in the disclosed DFS module has its own PLL modules to generate the clock signal from the reference clock provided in the FPGA board. For simplicity of explanations, we assume the design works with one clock frequency, however, our design supports multiple clock signals with the same procedure. Each PLL generates one clock output, CLK0. At the start-up, the PLL is initialized to generate the output clock equal to the reference clock. When the platform modifies the clock frequency, at τi based on the predicted workload for τᵢ₊₁, the PLL is reconfigured to generate the output clock that—meets the QoS for τᵢ₊₁.

### 8-IV.3. Voltage Scaling Flow

To implement the dynamic voltage scaling for both V_{core} and V_{bram}, Texas Instruments (TI) PMBUS USB Adapter can be used for different FPGA vendors. TI adapter provides a C-based Application Programming Interface (API), which eases adjusting the board voltage rails and reading the chip currents to measure the power consumption through Power Management Bus (PMBUS) standard. To scale the FPGA voltage rails, the required PMBUS commands are sent to the adapter to set the V_{bram} and V_{core} to certain values. This adopter is used as a proof of concept, while in industry fast DC-DC converters are used to change the voltage rails. The work in has shown a latency of 3-5 nSec, and is able to generate voltages between 0.45V to 1V with 25 mV resolution. As these converters are faster than the FPGAs clock frequency, we neglect the performance overhead of the DVS module in the rest of the paper.

### 8-V. Workload-AwareHD Architecture

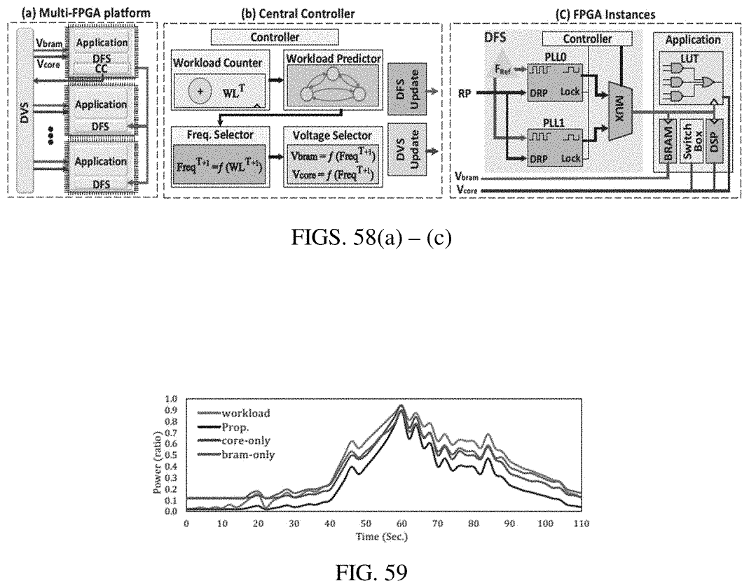

FIG. 58a demonstrates the architecture of the Workload-AwareHD energy efficient multi-FPGA platform. Our platform consists of n FPGAs where one of them is a central FPGA. The central FPGA has Central Controller (CC) and DFS blocks and is responsible to control the frequency and voltage of all other FPGAs. FIG. 58b shows the details of the CC managing the voltage/frequency of all FPGA instances. The CC predicts the workload size and accordingly scales the voltage and frequency of all other FPGAs. A Workload Counter computes the number of incoming inputs in a central FPGA, assuming all other FPGAs have the similar input rate. The Workload Predictor module compares the counter value with the predicted workload at the previous time step. Based on the current state, the workload predictor estimates the workload size in the next time step. Next, Freq. Selector module determines the frequency of all FPGA instances depending on the workload size. Finally, the Voltage Selector module sets the working voltages of different blocks based on the clock frequency, design timing characteristics (e.g., critical paths), and FPGA resources characteristics. This voltage selection happens for logic elements, switch boxes, and DSP cores (V_{core}); as well as the operating voltage of BRAM cells (V_{bram}). The obtained voltages not only guarantee timing (which has a large solution space), but also minimizes the power as discussed in Section 8-III. The optimal operating voltage(s) of each frequency is calculated during the design synthesis stage and are stored in the memory, where the DVS module is programmed to fetch the voltage levels of FPGAs instances.

Misprediction Detection: In CC, the misprediction happens when the workload bin for time step i^{th} is not equal to the bin achieved by the workload counter. To detect mispredictions, the value of t % should be greater than 1/m, where m is the number of bins. Therefore, the system discriminates each bin with the higher level bin. For example, if the size of the incoming workload is predicted to be in bin i^{th} while it actually belongs to i+1^{th} bin, the system is able to process the workload with the size of i+1^{th} bin. After each misprediction, the state of the Markov model is updated to the correct state. If the number of mispredictions exceeded a threshold, the probabilities of the corresponding edges are updated.

PLL Overhead: The CC issues the required signals to reprogram the PLL blocks in each FPGA. To reprogram the PLL modules, the DVF reprogramming FSM issues the RP signal serially. After reprogramming the PLL module, the generated clock output is unreliable until the lock signal is issued, which takes no longer than 100 μSec. In the cases the framework changes the frequency and voltage very frequently, the overhead of stalling the FPGA instances for the stable output clock signal limits the performance and energy improvement. Therefore, we use two PLL modules to eliminate the overhead of frequency adjustion. In this platform, as shown in FIG. 58c, the outputs of two PLL modules pass through a multiplexer, one of them is generating the current clock frequency, while the other is being programmed to generate the clock for the next time step. Thus, in the next clock, the platform will not be halted waiting for a stable clock frequency.

In case of having one PLL, each time step with duration τ requires t_{lock} extra time for generating a stable clock signal. Therefore, using one PLL has t_{lock} set up overhead. Since tlock <<τ, we assume the PLL overhead, t_{lock}, does not affect the frequency selection. The energy overhead of using one PLL is:

$$\underbrace{{P}_{Design} \times {t}_{lock}}_{Design energy during {t}_{lock}} + \underbrace{{P}_{PLL} \times ( τ + {t}_{lock} )}_{PLL energy} \qquad ( 8 \text{-} 4 )$$

In case of using two PLLs, there is no performance overhead. The energy overhead would be equal to power consumption of two PLLs multiplied by τ. The performance overhead is negligible since t_{lock}<100 μSec<<τ. Therefore, it is more efficient to use two PLLs when the following condition is hold:

$${P}_{design} \times {t}_{lock} + {P}_{P L L} \times ( τ + {t}_{l o c k} ) > 2 \times {P}_{P L L} \times τ \qquad ( 8 \text{-} 5 )$$

Since t_{lock}<<τ, we should have P_{design}×t_{Lock}>P_{PPL}×τ. Our evaluation shows that this condition can be always satisfied over all our experiments. In practice, the fully utilized FPGA power consumption is around 20 W while the PLL consumes about 0.1 W, and t_{lock} ˜10 μSec. Therefore, when τ>2 mSec, the overhead of using two PLL becomes less than using one PLL. In practice, r is at least in order of seconds or minutes; thus it is always more beneficial to use two PLLs.

### 8-VI. Experimental Results

### 8-VI.1. General Setup

We evaluated the efficiency of the disclosed method by implementing several state-of-the-art neural network acceleration frameworks on a commercial FPGA architecture. To generate and characterize the SPICE netlist of FPGA resources from delay and power perspectives, we used the latest version of COFFE with 22 nm predictive technology model (PTM) and an architectural description file similar to Stratix IV devices due to their well-provided architectural details. COFFE does not model DSPs, so we hand-crafted a Verilog HDL of Stratix IV DSPs and characterized with Synopsys Design Compiler using NanGate 45 nm Open-Cell Library tailored for libraries with different voltages by the means of Synopsys SiliconSmart. Eventually we scaled the 45 nm DSP characterization to 22 nm following the scaling factors of a subset of combinational and sequential cells obtained through SPICE simulations.

TABLE 8-I
Post place and route resource utilization and timing of the benchmarks.

| Parameter | Tab1a | DnnWeaver | DianNao | Stripes | Proteus |
|---|---|---|---|---|---|
| LAB | 127 | 730 | 3430 | 12343 | 2702 |
| DSP | 0 | 1 | 112 | 16 | 144 |
| M9K | 47 | 166 | 30 | 15 | 15 |
| M144K | 1 | 13 | 2 | 1 | 1 |
| I/O | 567 | 1655 | 4659 | 8797 | 5033 |
| Freq. (MHz) | 113 | 99 | 83 | 40 | 70 |

We synthesized the benchmarks using Intel (Altera) Quartus II software targeting Stratix IV devices and converted the resulted VQM (Verilog Quartus Mapping) file format to Berkeley Logic Interchange Format (BLIF) format, recognizable by our placement and routing VTR (Verilog-to-Routing) toolset. VTR gets a synthesized design in BLIF format along with the architectural description of the device (e.g., number of LUTs per slice, routing network information such as wire length, delays, etc.) and maps (i.e., performs place and routing) on the smallest possible FPGA device and simultaneously tries to minimize the delay. The only amendment we made in the device architecture was to increase the capacity of I/O pads from 2 to 4 as our benchmarks are heavily I/O bound. Our benchmarks include Tabla, DnnWeaver, DianNao, Stripes, and Proteus which are general neural network acceleration frameworks capable of optimizing various objective functions through gradient descent by supporting huge parallelism. The last two networks provide serial and variable precision acceleration for energy efficiency. Table 8-I summarizes the resource usage and post place and route frequencies of the synthesized benchmarks. LAB stands for Logic Array Block and includes 10 6-input LUTs. M9K and M144K show the number of 9 Kb and 144 Kb memories.

### 8-VI.2. Results

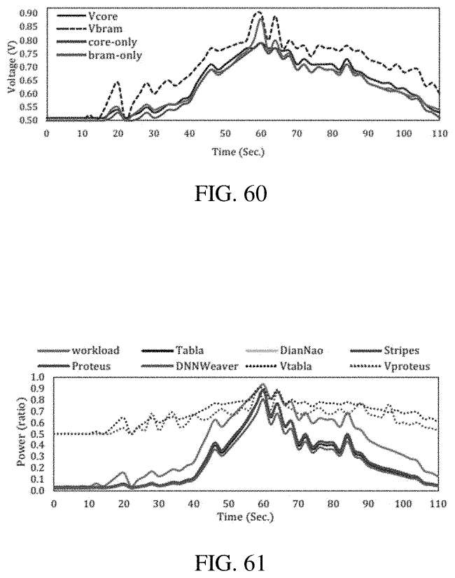

FIG. 59 compares the achieved power gain of different voltage scaling approaches implemented the Tabla acceleration framework under a varying workload. We considered a synthetic workload with 40% average load (of the maximum) from with λ=1000, H=0.76 and IDC=500 where λ, 0.5<H≤1 and IDC denote the average arrival rate of the whole process, Hurst exponent, and the index of dispersion, respectively. The workload also has been shown in the same figure (in green line) which is normalized to its expected peak load. We have showed the corresponding V_{core} and V_{bram} voltages of all approaches in FIG. 60. Note that we have not showed V_{bram} (V_{core}) for the core-only (bram-only) techniques as it is fixed 0.95V (0.8V) in this approach. An average of 4.1× power reduction is achieved, while this is 2.9× and 2.7× for the core-only and bram-only approaches. This means that the disclosed technique is 41% more efficient than the best approach, i.e., only considering the core voltage rails. An interesting point in FIG. 60 is the reaction of bram-only approach with respect to workload variation. It follows a similar scaling trend (i.e., slope) as V_{bram} in our approach. However, our method also scales the V_{core} to find more efficient energy point, thus V_{bram} in our disclosed approach is always greater than that of bram-only approach.

FIG. 61 compares the power saving of all accelerator frameworks employing Workload-Aware, where they follow a similar trend. This is due to the fact that the workload has considerably higher impact on the opportunity of power saving. We could also infer this from FIG. 55 where the power efficiency is significantly affected by workload rather than application specifications (α and β parameters). In addition, we observed that BRAM delay contributes to a similar portion of critical path delay in all of our accelerators (i.e., α parameters are close). Lastly, the accelerators are heavily I/O-bound which are obliged to be mapped to a considerably larger device where static power of the unused resources is large enough to cover the difference in applications power characteristics. Nevertheless, we have also represented the BRAM voltages of the Table 8-II (Tabla in dashed black line, the same presented in FIGS. 8-7) and Proteus (VProteus) applications in 8. As we can see, although the power trends of these applications almost overlap, they have a noticeably different minimum V_{bram} points.

TABLE 8-II
Power efficiency of different approaches

| Technique | Tabla | DianNao | Stripes | Proteus | DNNWeav. | Average |
|---|---|---|---|---|---|---|
| Core-only | 2.9× | 3.1× | 3.1× | 3.1× | 2.9× | 3.02× |
| Bram-only | 2.7× | 1.9× | 1.8× | 2.0× | 2.9× | 2.26× |
| The | 4.1× | 3.9× | 3.9× | 3.8× | 4.4× | 4.02× |
| proposed | | | | | | |
| Efficiency | 41- | 26- | 26- | 23- | 52% | 33.6%- |
| | 52% | 105% | 116% | 90% | | 83% |

Table 8-II summarizes the average power reduction of different voltage scaling schemes over the aforementioned workload. On average, the disclosed scheme reduces the power by 4.0×, which is 33.6% better than the previous core-only and 83% more effective than scaling the V_{bram}. As elaborated in Section 8-III, different power saving in applications (while having the same workload) arises from different factors including the distribution of resources in their critical path where each resource exhibits a different voltage-delay characteristics, as well as the relative utilization of logic/routing and memory resources that affect the optimum point in each approach.

### Part 9: SCRIMP: Stochastic Computing Architecture Using ReRAM Based In-Memory Processing

As further appreciated by the present inventors, stochastic computing (SC) reduces the complexity of computation by representing numbers with long independent bit-streams. However, increasing performance in SC comes with increase in area and loss in accuracy. Processing in memory (PIM) with non-volatile memories (NVMs) computes data in-place, while having high memory density and supporting bit-parallel operations with low energy. We disclose, herein, SCRIMP, an architecture for stochastic computing acceleration with resistive RAM (ReRAM) in-memory processing, which enables SC in memory. SCRIMP is highly general and can be used for a wide range of applications. It is a highly dense and parallel architecture which supports all SC encodings and operations in memory. It maximizes the performance and energy efficiency of implementing SC by introducing several innovations: (i) in-memory parallel stochastic number generation, (ii) efficient implication-based logic in memory, (iii) novel memory bitline segmenting, (iv) a new memory-compatible SC addition operation, and (v) enabling flexible block allocation. To show the generality and efficiency of SCRIMP, we implement image processing, deep neural networks (DNNs) and hyperdimensional (HD) computing, on the proposed hardware. Our evaluations show that running DNNs on SCRIMP is 141 times faster and 80 times more energy efficient as compared to GPU.

### 9-I. Introduction

The era of Internet of Things (IoT) is expected to create billions of inter-connected devices which are expected to be doubled every year. This results in generating a huge amount of raw data which need to be pre-processed by algorithms such as machine learning which are all computationally expensive. To ensure network scalability, security, and system efficiency, much of IoT data processing need to run at least partly on the devices at the edge of the internet. However, running data intensive workloads with large datasets on traditional cores results in high energy consumption and slow processing speed due to the large amount of data movement between memory and processing units. Although new processor technology has evolved to serve computationally complex tasks in a more efficient way, data movement costs between processor and memory still hinder the higher efficiency of application performance. This has changed the metrics used to describe a system from being performance focused (OPS/sec) to being efficiency focused (OPS/sec/mm2, OPS/sec/W). Restricted by these metrics, IoT devices either implement extremely simple versions of these complex algorithms, while trading a lot of accuracy, or transmit data to cloud for computation, while incurring huge communication latency costs.

New computing paradigms have shown the capability to perform complex computations at lower area and power costs. Stochastic Computing (SC) is one such paradigm, which represents each data point in the form of a bit-stream, where the probability of having ‘1’s corresponds to the value of the data. Representing data in such a format does increase the size of data, with SC requiring 2n bits to precisely represent an n-bit number. However, it comes with the benefit of extremely simplified computations and tolerance to noise. For example, a multiplication operation in SC requires a single logic gate as opposed to the huge and complex multiplier in integer domain. This simplification provides low area footprint and power consumption. However, with all its positives, SC comes with some disadvantages. (i) Generating stochastic numbers is expensive and is a key bottleneck in SC designs, consuming as much as 80% of total design area. (ii) Increasing the accuracy of SC requires increasing the bit-stream length, resulting in higher latency and area. (iii) Increasing the speed of SC comes at the expense of more logic gates, resulting in larger area. These pose a big challenge which cannot be solved with today's CMOS technology.

Processing In-Memory (PIM) is an implementation approach that uses high-density memory cells as computing elements. Specifically, PIM with non-volatile memories (NVMs) like resistive random accessible memory (ReRAM) has shown great potential for performing in-place computations and hence, achieving huge benefits over conventional computing architectures. ReRAM boast of (i) small cell sizes, making it suitable to store and process large bit-streams, (ii) low energy consumption for binary computations, making it suitable for huge number of bitwise operations in SC, (iii) high bit-level parallelism, making it suitable for bit-independent operations in memory, and (iv) stochastic nature at sub-threshold level, making it suitable for generating stochastic numbers.

Accordingly, SCRIMP can combine the benefits of SC and PIM to obtain a system which not only has high computational ability but also meets the area and energy constraints of IoT devices. We propose SCRIMP, an architecture for stochastic computing acceleration with ReRAM in-memory processing. As further described herein:
In some embodiments, SCRIMP is a ReRAM processing in memory architecture which brings together the benefits of both ReRAM devices and SC to efficiently support all SC encoding techniques and operations. It is a generalized architecture and can accelerate a wide range of tasks.
SCRIMP is a highly parallel architecture which efficiently scales with the size of SC computations. This high scalability is achieved by enabling flexible block allocation and a novel block segmenting scheme. This makes SCRIMP independent of stochastic bit-stream length and the number of inputs, making it suitable for any SC application.
SCRIMP combines the basic properties of ReRAM and SC to make implementation of SC on PIM highly efficient. First, SCRIMP exploits the stochastic nature of ReRAM devices to propose a new stochastic number generation scheme. This completely eliminates the use of stochastic number generators which can consume up to 80% area on a SC chip. Second, SCRIMP uses the analog nature of ReRAM PIM to present a novel SC addition which is highly compatible with memory. It is low in complexity but delivers high accuracy.
SCRIMP implements implication logic in regular crossbars. This enables SCRIMP to combine various logic families to execute logic operations more efficiently. SCRIMP implementation of basic SC operators using implication logic are faster and more efficient than state-of-the-art.

SCRIMP was also evaluated using six general image processing applications, DNNs, and HD computing to show the generality of SCRIMP. Our evaluations show that running DNNs on SCRIMP is 141 times faster and 80 times more energy efficient as compared to GPU.

### 9-II. Landscape of SCRIMP

### 9-II.1. Stochastic Computing

Stochastic computing (SC) represents numbers in terms of probabilities in long independent bit-streams. For example, a sequence x=0010110001 represents 0.4 since probability of a random bit in the sequence to be ‘1,’ px is 0.4. Various encodings like unipolar, bipolar, extended stochastic logic sign-magnitude stochastic computing (SM-SC), etc. have been proposed which allow converting both unsigned and signed binary number to a stochastic representation. To represent numbers beyond the range [0,1] for signed and [−1,1] for unsigned number, a pre-scaling operation is performed. Arithmetic operations in this representation involve simple logic operations on uncorrelated and independently generated input bit-streams. Multiplication for unipolar and SM-SC encodings is implemented by ANDing the two input bit-streams x1 and x2 bitwise. Here, all bitwise operations are independent of each other. The output bit-stream represents the product pₓ₁×pₓ₂. For bipolar numbers, multiplication is performed using XNOR operation.

Unlike multiplication, stochastic addition, or accumulation, is not a simple operation. Several methods have been proposed which involve a direct trade-off between the accuracy and complexity of operation. The simplest way is to OR x1 and x2 bitwise. Since the output is ‘1’ in all but one case, it incurs high error, which increases with the number of inputs. The most common stochastic addition passes N input bit-streams through a multiplexer (MUX). The MUX uses a randomly generated number in range 1 to N to select one of the N input bits at a time. The output, given by (pₓ₁+pₓ₂+ . . . +p_{xN})/N represents the scaled sum of the inputs. It has better accuracy due to random selection. The most accurate way is to count, sometimes approximately, the N bits at any bit position to generate a stream of binary numbers. Its large area and latency bottleneck due to addition at each bit position. For subtraction, which is only required for bipolar encoding, the subtrahend is first inverted bitwise. Any addition technique can then be used. Many arithmetic functions like trigonometric, logarithmic, and exponential functions can be approximated in stochastic domain with acceptable accuracy. A function f(x) can be implemented using a Bernstein polynomial, based on the Bernstein coefficients, bi.

Stochastic computing is enabled by stochastic number generators (SNGs), which perform binary to stochastic conversion. It compares the input with a randomly, or pseudo randomly, generated number every cycle using a comparator. The output of the comparator is a bit-stream representing the input. The random number generator, generally a counter or a linear feedback shift register (LFSR) and comparator have large area footprint, using as much as 80% of the total chip resources.

### 9-II.2. Digital Processing In Memory

A large number of recent designs enabling PIM in ReRAM are based on analog computing. Each element of array is a programmable multi-bit ReRAM device. In computing mode, a digital input data is transferred to analog domain using digital to analog converters (DACs) and passed through a crossbar memory. The accumulated current in each memory bitlines is sensed by an analog to digital converter (ADC), which outputs a digital number. The ADCs based designs have high power and area requirements. For example, for the accelerators ISAAC and IMP the ReRAM crossbar consumes just takes 8.7% (1.5%) and 19.0% (1.3%) of the total power (area) of the chip. Moreover, these designs cannot support many bitwise operations, restricting their use for stochastic computing.

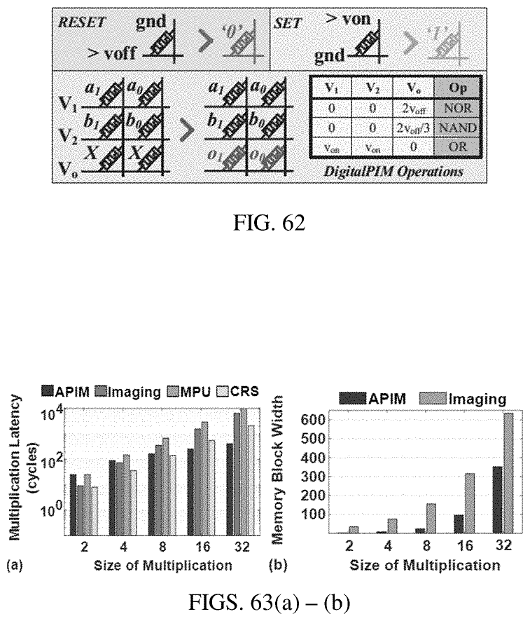

Digital processing in-memory exploits variable switching of memristor to implement a variety of logic functions inside memory. FIG. 62 shows how the output of operation changes with the applied voltage. The output device switches whenever the voltage across it exceeds a threshold. As shown, these operations can be implemented in parallel over multi-bits, even the entire row of memory. Digital PIM allows high density operations within memory without reading out the data. SCRIMP can utilize digital PIM to implement a majority of stochastic operations. In addition, SCRIMP can also support an entire class of digital logic, i.e. implication logic, in regular crossbar memory using digital PIM.

### 9-III. Stochastic on PIM

PIM on Conventional or Stochastic Data: The digital PIM designs, discussed in the Section 9-II.2, use the conditional switching of ReRAM devices to implement logic functions in memory. A series of these switching operations is used to implement more complex functions like addition and multiplication. This results in large latency, which increases with the size of the inputs. FIG. 63a shows the way the latency increases with the bit-length of inputs for binary multiplication in current PIM techniques. There is an approximately exponential increase in the latency, consuming as at least 164 (254) cycles for 8-bit (16-bit) multiplication. As shown in the previous section, multiplication in stochastic domain just requires bitwise AND/XOR of the inputs. With stochastic bits being independent from each other, increasing the bit-length in stochastic domain does not change the latency of operation, requiring just 2 cycles for both 8-bit and 16-bit multiplications.

PIM Parallelism: Digital PIM is often limited by the size of the memory block, particularly the width. FIG. 63b shows how the size of operands increases the demand for larger memory blocks in binary multiplication. Stochastic computing is uniquely able to overcome this issue. Since each bit in stochastic domain is independent, the bits may be stored over different blocks without changing the logical perspective. Although the stochastic operations are simple, parallelizing stochastic computation in conventional (CMOS) implementations comes at the cost of a direct, sometimes linear, increase in the hardware requirement. However, the independence between stochastic bits allows for extensive bit-level parallelism which many PIM techniques support.

### 9-IV. SCRIMP Overview

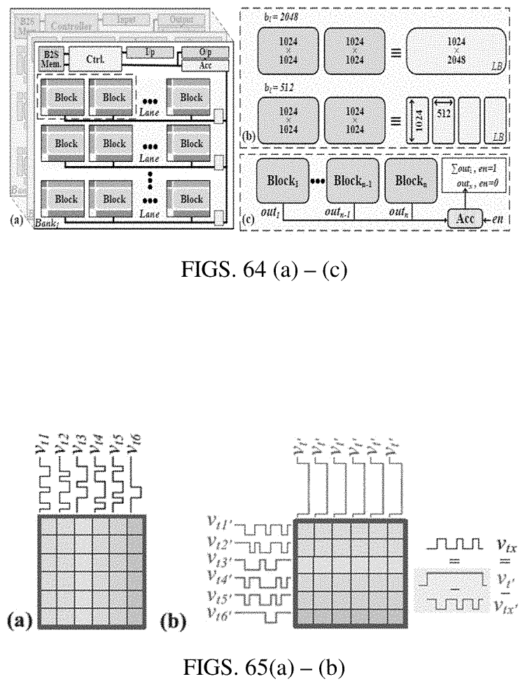

SCRIMP, a digital ReRAM-PIM based architecture for stochastic computing, a general stochastic platform which supports all SC computing techniques. It combines the complementary properties of ReRAM-PIM and SC as discussed in Section 9-III. SCRIMP architecture consists of multiple ReRAM crossbar memory blocks grouped into multiple banks (FIG. 64a). A memory block is the basic processing element in SCRIMP, which performs stochastic operations using digital ReRAM-PIM. The feature with enables SCRIMP to perform stochastic operations is the support for flexible block allocation.

Now, due to the limitations of crossbar memory the size of each block is restricted to, say, 1024′ 1024 ReRAM cells in our case. In a conventional architecture, if the length of stochastic bit-streams, bₗ, is less than 1024, it results in under-utilization of memory. Lengths of bₗ>1024 couldn't be supported. SCRIMP on the other hand allocates blocks dynamically. It divides a memory block (if bₗ<1024), or groups multiple blocks together (if bₗ>1024) to form a logical block (FIG. 64b). A logical block has a logical row-size of bₗ cells. This logical division and grouping is done dynamically by the bank controller. All the blocks in a bank work with the same bit-stream length, bₗ. However, different banks can configure logical blocks independently, enabling simultaneous multi-bₗ support. In addition, SCRIMP uses a within-a-block partitioning approach where a memory block is divided into 32 smaller partitions by segmenting the memory bitlines. The segmentation is performed by a novel buried switch isolation technique. The switches, when turned-off, isolate the segments from each other. This results in 32 smaller partitions, each of which behaves like a block of size 32′1024. This increases the intra-block parallelism in SCRIMP by up to 32′.

Any stochastic application may have three major phases, (i) binary to stochastic conversion (B2S), (ii) stochastic logic computation, (iii) stochastic to binary (S2B) conversion. SCRIMP follows bank level division where all the blocks in a bank work in the same phase at a time. The stochastic nature of ReRAM cells allows SCRIMP memory blocks to inherently support B2S conversion. Digital PIM techniques combined with memory peripherals enable logic computation in memory and S2B conversion in SCRIMP. S2B conversion over multiple physical blocks is enabled by accumulator-enabled bus architecture of SCRIMP (FIG. 64c).

### 9-V. Stochastic PIM

In this section, we present the hardware innovations which make SCRIMP efficient for SC. First, we present a PIM-B2S conversion technique. Then, we propose a new way to compute logic in memory. Next, we show how we bypass the physical limitations of previous PIM designs to achieve a highly parallel architecture. Last, we show the implementation different SC operations in SCRIMP.

### 9-V.1. Stochastic Number Generation

The ReRAM device switching is probabilistic at sub-threshold voltages, with the switching time following a Poisson distribution. For a fixed voltage, the switching probability of a memristor can be controlled by varying the width of the programming pulse. The group write technique presented in showed that stochastic numbers of large sizes can be generated over multiple bits of a column in parallel It first deterministically programs all the memory cells to zero (RESET) and then stochastically, based on the input number, programs them to one (SET). However, since digital PIM is row-parallel, it is desirable to generate such a number over a row. This can be achieved in two ways:

ON→OFF Group Write: To generate a stochastic number over a row, we need to apply the same programming pulse to the row. As shown before in FIG. 62, the bipolar nature of memristor allows it to switch only to ‘0’ by applying a voltage at the wordline. Hence, a ON→OFF group write is needed. Stochastic numbers can be generated over rows by applying stochastic programming pulses at wordlines instead of bitlines. However, a successful stochastic number generation requires us to SET all the rows initially. This results in a large number of SET operations. The SET phase is both slower as well as more energy consuming than the RESET phase, making this approach very inefficient. Hence, we propose a new generation method.

SCRIMP Row-Parallel Generation: The switching of memristor is based on the effective voltage across its terminals. In order to achieve low static energy for initialization, we RESET all the rows like the original group write. However, instead of applying different voltage pulses, vₜ₁, vₜ₂, . . . vₜₘ, to different bitlines, we apply a common pulse, vₜ′, to all the bitlines. A pulse, vₜₓ, applies a voltage v with a time width of tx. Now, we apply pulses, vₜ₁′, v_{t2′}, . . . v_{tn′}, to different word-lines such that vₜₓ=v_{t′}−v_{tx′}. It generates stochastic numbers over multiple rows in parallel as shown in FIG. 65b.

TABLE 9-I
Comparison of the proposed XNOR and AND with state-of-the-art techniques

| | Latency | | Energy | | Memory Req. | | Devise Sw. | |
|---|---|---|---|---|---|---|---|---|
| | (cycles) | | (fJ) | | (# of cells) | | (# of Cells) | |
| | XNOR | AND | XNOR | AND | XNOR | AND | XNOR | AND |
| SCRIMP | 2 | 2 | 37.1 | 45.2 | 1 | 2 | ≤2 | ≤2 |
| FELIX | 3 | 2 | 57.7 | 48.8 | 2 | 2 | ≤3 | ≤2 |
| MAGIC | 5 | 3 | 120.29 | 64.1 | 5 | 3 | ≤5 | ≤5 |

### 9-V.2. Efficient PIM Operations

SC multiplication with bipolar (unipolar, SM-SC) numbers involves XNOR (AND). While the digital PIM discussed in Section 2.2 implements these functions, they are inefficient in terms of latency, energy consumption, memory requirement, number of device switches. We propose to use a implication-based logic. Implication (→, where A→B=A′+B) combined with false (always zero) presents a complete logic family. XNOR and AND are implemented using implication very efficiently as described in Table 9-I. Some previous work implemented implication in ReRAM. However, they required additional resistors of specific value to be added to the memory crossbar. Instead, SCRIMP enables, for the first time, implication-based logic in conventional crossbar memory, with the same components as the basic digital PIM. Hence, SCRIMP supports both implication and basic digital PIM operations.

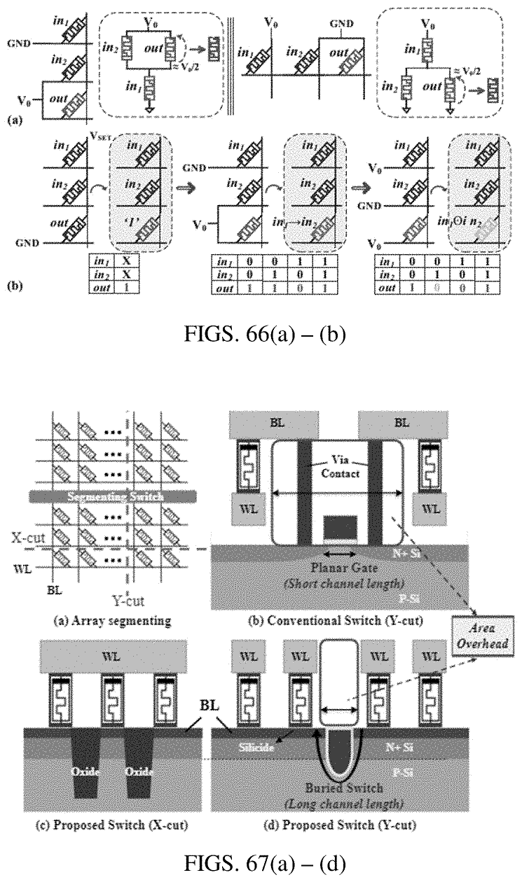

SCRIMP Implication in-memory: As discussed in Section 9-II.2, a memristor requires a voltage greater than v_{off} (−vₒₙ) to switch from ‘1’ (‘0’) to ‘0’ (‘1’) to high resistive state (HRS, logical ‘0’). We exploit this switching mechanism to implement implication logic in-memory. Consider three cells, two input cells and an output cell, in a row of crossbar memory as shown in FIG. 66a. We apply an execution voltage, V₀, at the bitline corresponding to one of the inputs (in₁), while ground the other input (in₂) and the output cell (out). Let out be initialized to ‘1’. In this configuration, out switches to ‘0’ only when the voltage across it is greater or equal to v_{off}. For all the cases when in₁ is ‘0’ most of the voltage drop is across in₁, resulting in a negligible voltage across out. In case in₁ is ‘1’ the voltage across out is ˜V₀/3 and ˜V₀/2 when in₂, is ‘1’, and ‘0’ respectively. If 2*v_{off}≤V₀<3*v_{off}, then out switches only when in₁ is ‘1’ and in₂ ‘0’. This results in the truth table shown in FIG. 66a, corresponding to in₁→in₂. To execute in₂→in₁, V₀ is applied to in₂ while in₁ and out are grounded.

SCRIMP XNOR in-memory: XNOR (⊙) can be represented as, A⊙B=(A→B), (B→A). Instead of calculating in₁→in₂ and in₂→in₁ separately and then ANDing them, we first calculate in₁→in₂ and then use its output cell to implement in₂→in₁ as shown in FIG. 66b. In this way, we eliminate separate execution of AND operation.

SCRIMP AND in-memory: AND (·) is represented as, A·B=(A→B′)′.

TABLE 9-II
DNN and HD computing workloads

| Deep Neural Networks | | | Hyperdimensional Computing (10,000 dimensions) | | | |
|---|---|---|---|---|---|---|
| ImageNet | Baseline | Quality | | | Baseline | Quality |
| Networks | Accuracy | Loss | Apps | # Classes | Accuracy | Loss |
| AlexNet [68] | 80.3% | 1.32% | ISOLET [69] | 26 | 96.4% | 0.72% |
| ResNet-18 [70] | 87.6% | 0.76% | FACE [71] | 2 | 95.3% | 0.29% |
| VGG-16 [72] | 89.3% | 1.18% | UCIHAR [73] | 12 | 93.1% | 0.49% |
| GoogleNet [74] | 90.8% | 1.61% | SECURITY [75] | 10 | 93.2% | 1.20% |

### 9-V.3. Memory Bitline Segmentation

As discussed in Section 9-II.2, digital PIM supports row-level parallelism, where an operation can be applied between two or three rows for the entire row-width in parallel. However, parallelism between multiple sets of rows is not possible. We enable multiple-row parallelism in SCRIMP by segmenting memory blocks. As shown in FIG. 67a, a row of segmenting switch physically divides two segments of memory block, preventing the interference of current from different segments. Prior works have segmented the array blocks using conventional transistor for the same purpose which utilizes a planar-type transistor. This type of structure has mainly two drawbacks: 1) large area overhead and 2) off-leaking due to short channel length. As shown in FIG. 67b the area of a single transistor with the planar-type structure is impacted by gate length, via contact area, gate to via space, via to adjacent-WL space in pairs for side of gate. On the other hand, we design a novel bitline isolation technique using buried switches. FIG. 67c and FIG. 67d describe the cross-sectional view of X-cut and Y-cut of the proposed design, respectively. SCRIMP utilizes a conductor on silicon, called silicide, to design the switch. This allows SCRIMP to fabricate the switch using a simple trench process. Here, instead of independent switches for different bitlines, we have a single row-width wide switch.

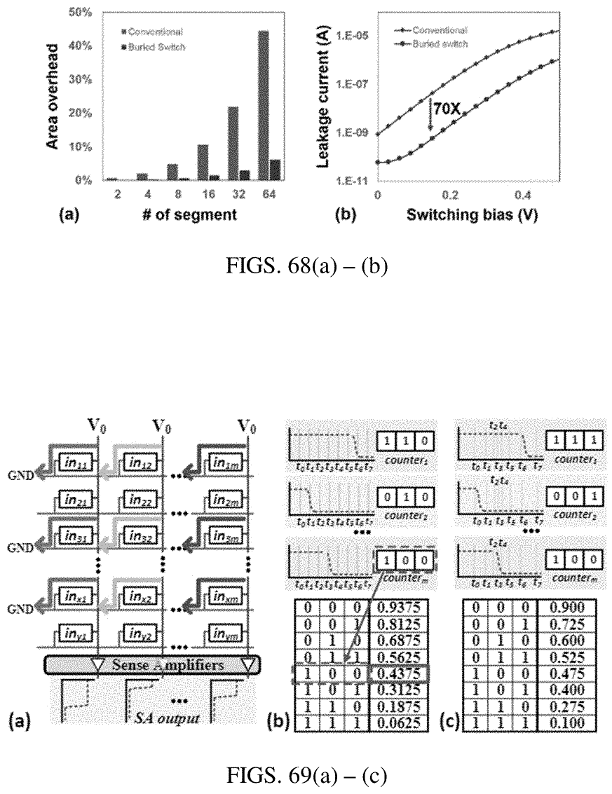

From the perspective of area, SCRIMP segmenting needs only a trench width in lateral direction. FIG. 68a shows change in area overhead due to segmentation as the number of segments increases. The estimated area from Cadence p-cell with 45 nm process shows that SCRIMP has 7 times less silicon footprint compared to conventional MOFET-based isolation. Due to its highly segmentation, SCRIMP with 32 partitions results in just 3% crossbar area overhead. In addition, the buried switch makes channel length longer than the conventional switch, as shown in FIG. 67d. This suppresses the short channel effect of conventional switches. As a result, SCRIMP achieves 70 times lower leakage current in the subthreshold region (FIG. 68b), enabling robust isolation. Switches can be selectively turned-off or -on to achieve the required configuration. For example, alternate switches can be turned-on to have 16 partitions of size 64 times 1024 each.

### 9-V.4. SC Arithmetic Operations in SCRIMP

Here, we explain how SCRIMP implements SC operations. The operands are either generated using the B2S conversion technique in Section 9-V.1 or are pre-stored in memory as outputs of previous operations. They are present in different rows of the memory, with their bits aligned. The output is generated in the output row, bit-aligned with the inputs.

Multiplication: As explained in Section 9-II, multiplication of two numbers in stochastic domain involves a bitwise XNOR (AND) between bipolar (unipolar, SM-SC) numbers across the bit-stream length. This is implemented in SCRIMP using the PIM technique explained in Section 9-V.2.

Conventional Addition/Subtraction/Accumulation: Implementations of different stochastic N-input accumulation techniques (OR, MUX, and count-based) discussed in Section 9-II can be generalized to addition by setting the number of inputs to two. In case of subtraction, the subtrahend is first inverted using a single digital PIM NOT cycle. Then, any addition technique can be used. The OR operation is supported by SCRIMP using the digital PIM operations, generating OR of N bits in single cycle. The operation can be executed in parallel for the entire bit-stream, bi, and takes just one cycle to compute the final output. To implement MUX-based addition in memory, we first stochastically generate bi random numbers between 1 to N using B2S conversion in Section 9-V.1. Each random number selects one of the N inputs for a bit position. The selected input bit is read using the memory sense amplifiers and stored in the output register. Hence, MUX-based addition takes one cycle to generate one output bit, consuming bi cycles for all the output bits. To implement parallel count (PC)-based addition in memory, one input bit-stream (bₗ bits) is read out by the sense amplifier every cycle and sent to counters. This is done for N inputs sequentially, consuming N cycles. In the end, the counters store the total number of ones at each bit position in the inputs.

SCRIMP Addition: Count-based addition is the most accurate but also the slowest of the previously proposed methods for stochastic addition. Instead, we use the analog characteristics of memory to generate a stream of bi binary numbers representing the sum of the inputs. As shown in FIG. 69a, the execution of addition in SCRIMP takes place in two phases. In the first phase, all the bitlines are pre-charged. In the second phase, only those wordlines or rows which contain the inputs of addition are grounded, while the rest of the wordlines are kept floating. This results in discharging of the bitlines. However, the speed of discharging depends upon the number of low resistive paths, i.e. the number of ‘1’s. Hence, more is the number of ‘1’s in a bitline, faster is the discharging. To detect the discharge edges, we use the traditional 1-bit sense amplifier, along with a time-controlled latch. We set the circuit to latch at eight different time steps, generating 3-bit (log₂8) outputs (FIG. 69b). The accuracy of this addition can be increased by having non-linear time steps as in FIG. 69c. We tested the accuracy of the proposed SCRIMP addition by generating 1M random binary numbers. We then calculated the average absolute errors. The accuracy of the SCRIMP addition is very close to the count-based addition (accuracy loss of 1.92% for bₗ=16, which decreases to 0.34% for bₗ=128). Increasing the number of time steps further increases the accuracy but at the cost of significant area overheads of increased latching and counting circuit.

Other Arithmetic Operations: SCRIMP supports trigonometric, logarithmic, and exponential functions using truncated Maclaurin Series expansion. The expansion approximates these functions using a series of multiplications and additions. With just 2-5 expansion terms, it has shown to produce more accurate results than most other stochastic methods.

### 9-VI. SCRIMP Architecture

A SCRIMP chip is divided into 128 banks, each consisting of 1024 ReRAM memory blocks. A memory block is the basic processing element in SCRIMP. Each block is a 1024 times 024-cell ReRAM crossbar. A block has a set of row and column drivers, which are responsible for applying appropriate voltages across the memory cells to read, write, and process the data. They are controlled by the memory controller.

SCRIMP Bank: A bank has 1024 memory blocks arranged in 32 lanes with 32 blocks each. A bank controller issues commands to the memory blocks. It also performs the logical block allocation in SCRIMP. Each bank has a small memory which decodes the programming time for B2S conversions. Using this memory, the bank controller sets the time corresponding to an input binary number for a logical block. The memory blocks in a bank lane are connected with a bus. Each lane bus has an accumulator to add the results from different physical blocks.

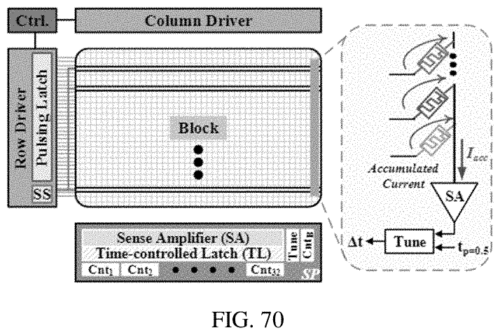

SCRIMP Block: Each block is a crossbar memory of 1024 times 1024 cells (FIG. 70). Each block can be segmented in up to 32 partitions using the buried switch isolation of Section 9-V.3. In addition to the memory sense amplifiers, block peripheral circuits include a 10-bit (log₂1024) counter per 32 columns to implement accumulation. Each block also use an additional 10-bit counter to support popcount across rows/columns.

Variation-Aware Design: ReRAM device properties show variations with time, temperature, and endurance, most of which change the device resistance. To make SCRIMP more resilient to resistance drift, we use only single level RRAM cells (RRAM-SLCs) whose large off/on resistance ratio makes them distinguishable even under large resistance drifts. Moreover, the probabilistic nature of SC makes it resilient to small noise/variations. To deal with large variations due to overtime decay or major temperature variations, SCRIMP implements a simple feedback enabled timing mechanism as shown in FIG. 70. One dummy column in a memory block is allocated to implement this approach. The cells in the designated column are activated and the total current through them is fed to a tuner circuit. The circuit outputs Δt, which is used to change the pulse widths for input generation and sense amplifier operations.

SCRIMP parallelism with bit-stream length: SCRIMP implements operations using digital PIM logic, where computations across the bit-stream can be performed in parallel. This results in proportional increase in performance, while consuming similar energy and area as bit-serial implementation. In contrast, the traditional CMOS implementations scale linearly with the bit-stream length, incurring large area overheads. Moreover, the dynamic logical block allocation allows the parallelism to extend beyond the size of block.

SCRIMP parallelism with number of inputs: SCRIMP can operate on multiple inputs and execute multiple operations in parallel within the same memory block. This is enabled by SCRIMP memory segmentation. When the segmented switches are turned-off, the current generated flowing through a bitline of a partition is isolated from currents of any other partition. Hence, SCRIMP can execute operations in different partitions in parallel.

### 9-VII. Learning on SCRIMP

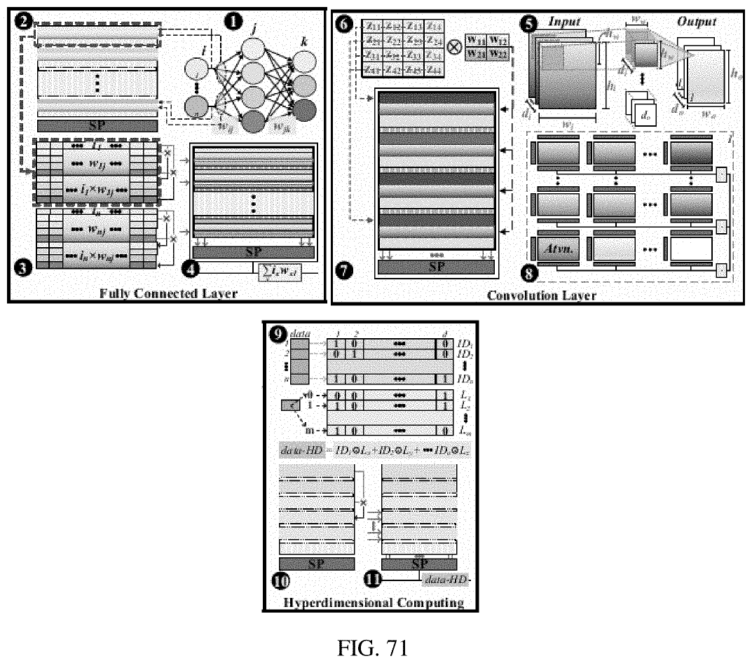

Here we study the implementation of two types of learning algorithms, deep neural networks (DNNs) and brain-inspired hyper-dimensional (HD) computing, on SCRIMP. FIG. 71 summarizes the discussion in this section.

### 9-VII.1. Deep Neural Networks

There has been some interest in implementing DNNs using stochastic computing. They provide high performance, but that performance comes at the cost of huge silicon area. Here, we show the way SCRIMP can be used to accelerate DNN applications. We describe SCRIMP implementation of different layers of neural networks, namely fully connected, convolution, and pooling layers.

Fully-Connected (FC) Layer: A FC layer with n inputs and p outputs is made up of p neurons. Each neuron has a weighted connection to all the n inputs generated by previous layer. All the weighted inputs for a neuron are then added together and passed through an activation function, generating the final result. SCRIMP distributes weights and inputs over different partitions of one or more blocks. Say, a neural network layer, j, receives input from layer i. The weighted connections between them can be represented with a matrix, wᵢⱼ \textcircled{1}. Each input (iₓ) and its corresponding weights (wₓⱼ) are stored in a partition \textcircled{2}. Inputs are multiplied with their corresponding weights using XNOR and the outputs are stored in the respective partition \textcircled{3}. Multiplication happens serially within a partition but in parallel across multiple partitions and blocks. Then, all the products corresponding to a neuron are selected and accumulated using SCRIMP addition \textcircled{4}. If 2p+1 (one input, p weights, p products) is less than the rows in a partition, the partition is shared by multiple inputs. If 2p+1 is greater than the number of rows, then wₓⱼ are distributed across multiple partitions.

Activation function brings non-linearity to the system and generally consists of non-linear functions like tan h, sigmoid, ReLU etc. Of these, ReLU is the most widely used operation. It is a threshold based function, where all numbers below a threshold value (vT) are set to vT. The output of FC accumulation is popcounted and compared to vT. All the numbers to be thresholded are replaced with stochastic vT. Other activation functions like tan h and sigmoid, if needed, are implemented using the Maclaurin series-based operations discussed in Section 9-V.4.

Convolution Layer: Unlike FC layer, instead of a single big set of weights, convolution has multiple smaller sets called weight kernels. A kernel moves through the input layer, processing a same-sized subset (window) of the input at a time and generates one output data point for each \textcircled{6}. A multiply and accumulate (MAC) operation is applied between a kernel and a window of the input at a time. Say, a convolution layer convolves an input layer (of width wᵢ, height hi and depth dᵢ) with do weight kernels (of width w_{w}, height h_{w}, and depth dᵢ) and generates an output with depth do.

We first show how a convolution between a single depth of input and weight kernel maps to SCRIMP. In \textcircled{5}, a 4×4 input is convolved with a 2×2 weight kernel. To completely parallelize multiplication in a convolution window, we distribute input such that all input elements in any window are stored in separate partitions. Same colored inputs in \textcircled{5} go to the same partitions as shown in \textcircled{7}. Each partition further has all the weights. To generalize, SCRIMP splits input into h_{w} times w_{w} partitions (partₗ₁, partₗ₂, . . . , partₕ_{_{w}}_{w}_{_{w}}). A partition, partᵢⱼ, has all the weights in the kernel and the input elements at every h_{w}th column and w_{w}th row starting from (i, j). A partition may be distributed over multiple physical SCRIMP segments as described in Section 9-V.3.

The MAC operation in a window is similar to the fully connected layer explained before. Since all the inputs in a window are mapped to different partitions \textcircled{7}, all multiplication operations for one window happen in parallel. The rows corresponding to all the products for a window are then activated and accumulated. The accumulated results undergo activation function (Atvn. in \textcircled{8}) and then, are written to the blocks for next layer. While all the windows for a unit depth of input are processed serially, different input depth levels and weight kernel depth levels are evaluated in parallel in different blocks \textcircled{8}. Further, computations for dₒ weight kernels are also parallelized over different blocks.

Pooling: A pooling window of size hₚ×wₚ is moved through the previous layer, processing one subset of input at a time. MAX, MIN, and average pooling are the three most commonly used pooling techniques. While average pooling is same as applying SCRIMP addition over a subset of the inputs in pooling window. MAX/MIN operations are implemented using the discharging concept used in SCRIMP addition. The input in the subset discharging the first (last) corresponds to the maximum (minimum) number.

### 9-VII.2. Hyperdimensional Computing

Hyperdimensional (HD) computing tries to mimic human brain and computes with patterns of numbers rather than the numbers themselves. HD represents data in the form of high-dimension (thousands) vectors, where the dimensions are independent of each other. The long bit-stream representation and dimension-wise independence makes HD very similar to stochastic computing. HD computing consists of two main phases: encoding and similarity check.

Encoding: The encoding uses a set of orthogonal hypervectors, called base hypervectors, to map each data point into the HD space with d dimensions. As shown in \textcircled{9}, each feature of a data point (feature vector) has two base hypervectors associated with it: identity hypervector, ID, and level hypervector, L. Each feature in the data point has a corresponding ID hypervector. The different values which each feature can take have corresponding L hypervectors. The ID and L hypervector for a data point are XNORed together. Then, the XNORs for all the features are accumulated to get the final hypervector for the data point.

The value of d is usually large, 1000s to 10,000s, which makes conventional architectures inefficient for HD computing. SCRIMP, being built for stochastic computing, presents the perfect platform for HD computing. The base hypervectors are generated just once. SCRIMP creates the orthogonal base hypervectors by generating d-bit long vectors with 50% probability as described in Section 9-V.1. it is based on the fact that randomly generated hypervectors are orthogonal. For each feature in data, the corresponding ID and L are selected and then XNORed using SCRIMP XNOR \textcircled{1}. The outputs of XNOR for different features are stored together. Then all the XNOR results are selected and accumulated using \textcircled{11} and further sent for similarity check.

Similarity Check: HD computes the similarity of the an unseen test data point with pre-stored hypervectors. The pre-stored hypervectors may represent different classes of cast of classification applications. SCRIMP computes the similarity of a test hypervector with k class hypervectors by performing k dot products between vectors in d dimensions. The hypervector with the highest dot product is selected as the output. To implement the dot product, the encoded d-dimension feature vector is first bitwise XNORed, using SCRIMP XNOR, with k d-dimension class hypervectors. It generates k product vectors of length d. SCRIMP then finds the maximum of the product hypervectors using the discharging mechanism of SCRIMP addition.

### 9-VIII. Evaluation

### 9-VIII.1. Experimental Setup

We developed a C++ based cycler-accurate simulator which emulates the functionalities of SCRIMP. The simulator uses the performance and energy characteristics of the hardware are obtained from circuit level simulations for a 45 nm CMOS process technology using Cadence Virtuoso. We use VTEAM memristor model for our memory design simulation with RON and ROFF of 10kΩ and 10MΩ respectively.

We compare the efficiency of the proposed SCRIMP with state-of-the-art processor NVIDIA GPU GTX 1080 Ti. As workload, we consider SCRIMP efficiency on several image processing and learning applications including: Sobel, Robert, Prewitt, and BoxSharp. We use random images from Caltech 101 library. For learning application, evaluate SCRIMP efficiency on Deep neural network and Hyperdimensional computing applications. As Table 9-II shows, we test SCRIMP efficiency and accuracy on four popular networks running on large-scaled ImageNet dataset. For HD computing, we evaluated SCRIMP accuracy and efficiency on four practical applications including speech recognition (ISOLET), face detection (FACE), activity recognition (UCIHAR), and security detection (SECURITY). Table 9-II compares the baseline accuracy (32-bit integer values) and the quality loss of the applications running on SCRIMP using 32-bit SM-SC encoding. Our evaluation shows that SCRIMP can result only about 1.5% and 1% quality loss on DNN and HD computing. 9-VIII.2. SCRIMP Trade-Offs

SCRIMP, and stochastic computing in general, depend on the length of bit-stream. The greater the length, higher is the accuracy. However, this increase in accuracy comes at the cost of increased area and energy consumption. As the length is increased more area (both memory and CMOS) is required to store and process the data, requiring more energy. It may also result in higher latency for some operations like MUX-based additions, for which the latency increases linearly with bit-stream length. To evaluate the effect of bit-stream length at operation level, we generate random inputs for each operation and take the average of 100 such samples. Each accumulation operation inputs 100 stochastic numbers. Moreover, the results here correspond to unipolar encoding. However, all other encodings have similar behavior with slight change in accuracy. An increase in bit-stream length has a direct impact on the accuracy, area, and energy at operation level. While the latency of the design remains same for all operations except MUX-based addition, Bernstein polynomial, and FSM-based operations. It happens because these operations process each bit sequentially. All operations have on an average 4× improvement in area and energy consumption respectively, while decreasing the bit-stream length from 1024 to 256, with 3.6% quality loss. For the same change in bit-stream length, the latency of MUX-based addition. Bernstein polynomial, and FSM-based operations differ on an average by 3.95×.

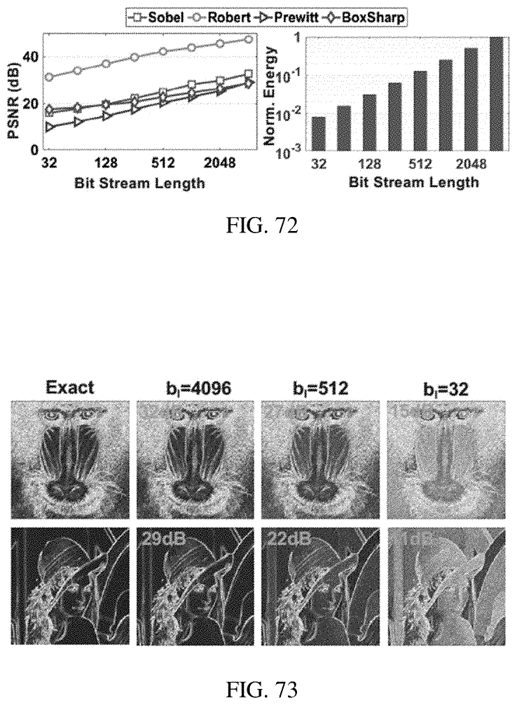

To evaluate the effect at application level, we implement the general applications listed above using SCRIMP with an input dataset of size 1 kB. The results shown here use unipolar encoding with AN-based multiplication, SCRIMP addition, and Maclaurin series-based other arithmetic functions. Since all these operations are scalable with the bit-stream length, the latency of the operations doesn't change. The minor increase in the latency at application level with the length is due to the time taken by stochastic-to-binary conversation circuits. However, this change is negligible. FIG. 72 shows the impact of bit-stream length on difference applications. On an average, both the area and energy consumption of the applications increase by 8×, when the bit-stream length increases from 512 to 4096, with an average 6.1 dB PSNR gain. As shown in FIG. 73, with a PSNR of 29 dB, the output of Sobel filter with bit-stream length of 4096 is visibly similar to that of the exact computation.

### 9-VIII.3. Learning on SCRIMP and GPU

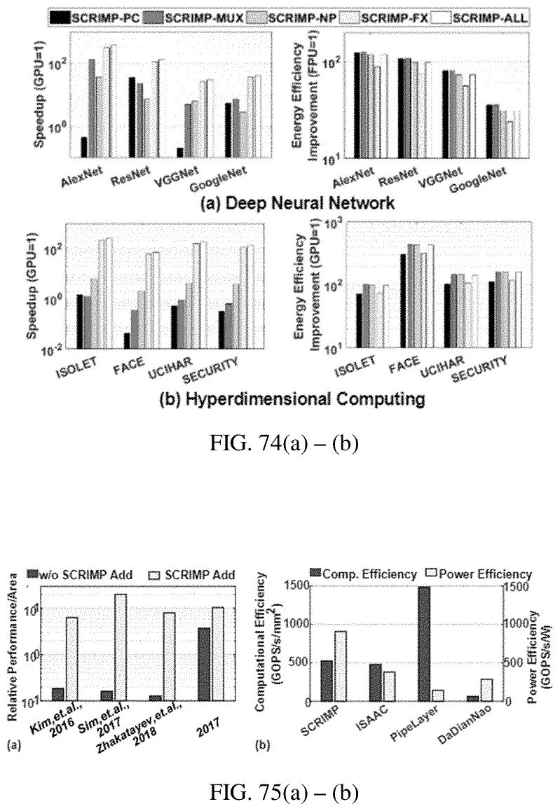

SCRIMP configurations: We compare SCRIMP with GPU for the DNNs and HD computing workloads detailed in Table 9-II. We use SM-SC encoding with a bit-stream length of 32 to represent the inputs and weights in DNNs and value of each dimension on HD computing on SCRIMP. Also, evaluation is performed while keeping the SCRIMP area and technology node same as GPU. We analyze SCRIMP in five different configurations to evaluate the impact of the various techniques proposed in this work at application level, as shown in FIGS. 74a-b. Of these configurations, SCRIMP-ALL is the best configuration and applies all the stochastic PIM techniques proposed in his work. As compared to SCRIMP-ALL, SCRIMP-PC and SCRIMP-MUX do not implement the new addition technique proposed in Section 9-V.4 but just use the conventional PC and MUX based addition/accumulation respectively. SCRIMP-NP implements all the techniques except the memory bitline segmentation, which eliminates block partitioning.

Comparison of different SCRIMP Configurations: Comparing different SCRIMP configurations, we observe that SCRIMP-PC addition is on an average 240.1× and 647.3× slower than SCRIMP-ALL for DNNs and HD computing. This happens since SCRIMP-PC reads each and every data sequentially for accumulation as compared to SCRIMP-ALL which performs a highly parallel single cycle accumulation. This effect is seen very clearly in case of DNNs, where SCRIMP-ALL is 810.6× and 140.3× faster than SCRIMP-PC for AlexNet and VGG-16, both of which have large FC layers. On the other hand, SCRIMP-ALL is just 3.8× and 7.7× better than SCRIMP-PC for ResNet-18 and GoogleNet which have one fairly small FC layer each accumulating {512×1000} and {1024×1000} data points. The latency of SCRIMP-MUX scales linearly with the bit-stream length. For our 32-bit DNN implementation, SCRIMP-ALL is 5.1× faster than SCRIMP-MUX. SCRIMP-ALL really shines over SCRIMP-MUX in the case of HD computing and is 188.1× faster. SCRIMP-MUX becomes a bottleneck in similarity check phase when the products for all dimensions need to be accumulated. SCRIMP-ALL provides the maximum theoretical speedup of 32× over SCRIMP-NP. In practice, SCRIMP-ALL is on average 11.9× faster than SCRIMP-NP for DNNs. Further, SCRIMP-ALL is 20% faster and 30% more energy efficient than SCRIMP-FX for DNNs. This shows the benefits of SCRIMP over previous digital PIM operations.

Comparison with GPU for DNNs: SCRIMP benefits from three factors: simpler computations due to stochastic computing, high density storage and processing architecture, and less data movement between processor and memory due to PIM. We observe that SCRIMP-ALL is on an average 141× faster than GPU for DNNs. SCRIMP latency majorly depends upon the convolution operations in a network. As discussed before, while SCRIMP parallelizes computations over input channels and weights depth in a convolution layer, the convolution of a weight window over an individual input channel still serializes the sliding of windows through the input. This means that the latency of a convolution layer in SCRIMP is directly proportional to its output size. It is reflected in the results where SCRIMP achieves higher acceleration in case of AlexNet (362×) and ResNet-18 (130×) as compared to VGG-16 (29×) and GoogleNet (41×). Here, even though ResNet-18 is deeper than VGG-16, its execution is faster because it reduces the size of the output of its convolution significantly faster than VGG-16. Also, SCRIMP-ALL is 80× more energy efficient than GPU. This is due to the low-cost SC operations and the reduced data movement in SCRIMP, where the DNN models are pre-stored in memory.

Comparison with GPU for HD Computing: SCRIMP-ALL is on an average 156× faster than GPU for HD classification tasks. The computation in a HD classification task is directly proportional to the number of output classes. However, computation for different classes are independent from each other. The high parallelism (due to the dense architecture and configurable partitioning structure) provided by SCRIMP makes the execution time of different applications less dependent on the number of classes. However, in the case of GPU, the restricted parallelism (4000 cores in GPU vs 10,000 dimensions in HD) makes the latency directly dependent on the number of classes. The energy consumption of SCRIMP-ALL scales linearly with classes while being on an average 2090× more energy efficient than GPU. This is majorly due to the reduced data movement in SCRIMP, where the huge class models are pre-stored in the memory. Moreover, GPU performs hundreds of thousands of MAC operations to implement HD dot product whereas SCRIMP just uses simple XNORs and highly efficient accumulation.

### 9-VIII.4. SCRIMP vs Previous Accelerators

Stochastic Accelerators: We first compared SCRIMP with four state-of-the-art SC accelerators. To demonstrate the benefits of SCRIMP, we first implement the designs proposed by them on SCRIMP hardware. FIG. 75a shows the relative performance per area of SCRIMP compared to them. We present the results for two configurations. In the first, we use the same bitstream length and logic for multiplication, addition, and other functions that the corresponding accelerators use. In the second, we replace the additions and accumulations in all the designs with SCRIMP addition. Irrespective of the configuration, SCRIMP consumes 7.9×, 1134.0×, 474.7×, 2999.9× less area as compared to respectively. While comparing with previous designs in their original configuration, we observe that SCRIMP does not perform better than three of the designs. The high area benefits provided by SCRIMP are overshadowed by the high latency addition used in these designs. It requires popcounting each data point either exactly or approximately, both of which require reading out data. Unlike previous accelerators, SCRIMP uses memory block as processing elements. Multiple data read-outs from a memory block need to be done sequentially, resulting in high execution times, with SCRIMP being on an average 6.3× and maximum 7.9× less efficient. Moreover, the baseline performance figures for these accelerators used to compare SCRIMP are optimized for small workloads which do not scale with the complexity and size of operations (a 200-input neuron for and a 8×8×8 MAC unit for, while ignoring the overhead of SNGs). However, when SCRIMP addition is used for these accelerators, SCRIMP is on an average 11.5× and maximum 20.1× more efficient than these designs.

On the other hand, when the workload size and complexity is increased, as in case of SC-DNN which implements LeNet-5 neural network for MNIST dataset SCRIMP is better than SC-DNN even in their original configuration, being 3.7× more efficient for the most accurate SC-DNN design. Further, when SCRIMP addition and accumulation is used on the same design, SCRIMP becomes 10.4× more efficient.

DNN Accelerators: We also compare the computational (GOPS/s/mm2) and power efficiency (GOPS/s/W) of SCRIMP with state-of-the-art DNN accelerators. Here, Da-DianNao is a CMOS-based ASIC design, while ISAAC and PipeLayer are ReRAM based PIM designs. Unlike these designs, which have a fixed processing element (PE) size, the high flexibility of SCRIMP allows it to change the size of its PE according to the workload and operation to be performed. For example, a 3×3 convolution (2000×100 FC layer) is spread over 9 (2000) logical partitions, each of which may further be split into multiple physical partitions as discussed in Section 9-VII.1. As a result, SCRIMP doesn't have theoretical figures for computational and power efficiency. However, to compare SCRIMP with these accelerators, we run the four neural networks shown in Table 9-II on SCRIMP and report their average efficiency in FIG. 75b. We observe that SCRIMP is more power efficient than all DNN accelerators being 3.2×, 2.4×, and 6.3× better than DaDianNao, ISAAC, and PipeLayer, respectively. This is due to three main reasons, reducing the complexity of each operation, reducing the number of intermediate reads and writes to the memory, and eliminating the use of power hungry conversions between analog and digital domains.

We also observe that SCRIMP is computationally more efficient than DaDianNao and ISAAC, being 8.3× and 1.1× better respectively. This is due to the high parallelism that SCRIMP provides, processing different input and outputs channels in parallel. XCRIMP is still 2.8× computationally efficient as compared to PipeLayer. It happens because even though SCRIMP parallelizes computations within a convolution window, it serializes sliding of a window over the convolution operation. On the other hand, PipeLayer makes a large number of copies of weights to parallelize computation within the entire convolution operation. However, computational efficiency is inversely effected by the size of accelerator, which makes the comparatively old technology node of SCRIMP an invisible overhead in computational efficiency. To give an intuition for the benefits which SCRIMP can provide, we scale all the accelerators to the same technology, i.e., 28 nm. DaDianNao and PipeLayer are already reported at 28 nm node. On scaling ISAAC and SCRIMP to 28 nm, their computational efficiency increase to 625.6 GOPS/s/mm2 and 1355.5 GOPS/s/mm2, respectively. This shows that SCRIMP can be as computational efficient as the best DNN accelerator while providing significantly better power efficiency.

### 9-VIII.5. SCRIMP and Memory Non-Idealities

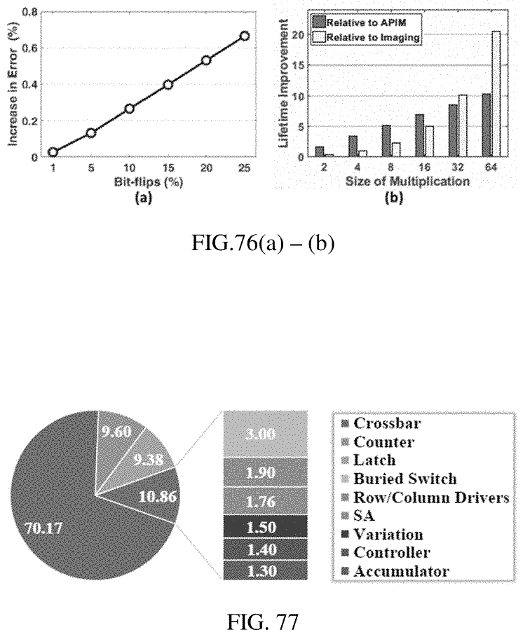

Bit-Flips: Stochastic computing is inherently immune to singular bit-flips in data. SCRIMP, being based on it, enjoys the same immunity. Here we evaluate the quality loss in the general applications with the same configuration as in Section 9-VIII.2 with a bit-stream length of 1024. The quality loss is measured as the difference between accuracy with and without bit-flips. FIG. 76a shows that with 10% bit-flips, the average quality loss is meagre 0.27%. When the bit-flips increase to 25%, applications lose only 0.66% in accuracy.

Memory Lifetime: SCRIMP uses the switching of ReRAM cells, which are known to have low endurance. Higher switching per cell may result in reduced memory lifetime and increased unreliability. Previous work uses iterative process to implement multiplication and other complex operations. The more the iterations, higher is the number of operations and so is the per cell switching count. SCRIMP reduces this complex iterative process to just one logic gate, in case of multiplication, while it breaks down other complex operations into a series of simple operations. Hence, achieving less switching count per cell. FIG. 76b shows that for multiplication, SCRIMP increases the lifetime of memory by 5.9× and 6.6× on an average as compared to APIM and Imaging respectively.

### 9-VIII.6. Area Breakdown

SCRIMP completely eliminates the overhead of SNGs which typically consume 80% of the total area in a SC system. However, the SCRIMP addition, which significantly accelerates SC addition and accumulation and overcomes the effect of slow PIM operations, requires significant changes to the memory peripheral circuits. Adding SC capabilities to the crossbar incurs ˜22% area overhead to the design as shown in FIG. 77. This comes in the form of 3-bit counters (9.6%), 1-bit latches (9.38%), modified SAs (1.76%), an accumulator (1.3%). We use buried switches to physically partition a memory block, which contributes 3% to the total area overhead. Our variation aware SA tuning mechanism costs additional 1.5% overhead. The remaining 73.47% of SCRIMP area is consumed by traditional memory components.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the various embodiments described herein. As used herein, the term “and/or” includes any and all combinations of one or more of the associated listed items.

The terminology used herein is for the purpose of describing particular embodiments only and is not intended to be limiting to other embodiments. As used herein, the singular forms “a”, “an” and “the” are intended to include the plural forms as well, unless the context clearly indicates otherwise. It will be further understood that the terms “comprises,” “comprising,” “includes” and/or “including”, “have” and/or “having” when used herein, specify the presence of stated features, integers, steps, operations, elements, and/or components, but do not preclude the presence or addition of one or more other features, integers, steps, operations, elements, components, and/or groups thereof. Elements described as being “to” perform functions, acts and/or operations may be configured to or other structured to do so.

Unless otherwise defined, all terms (including technical and scientific terms) used herein have the same meaning as commonly understood by one of ordinary skill in the art to which various embodiments described herein belong. It will be further understood that terms used herein should be interpreted as having a meaning that is consistent with their meaning in the context of this specification and the relevant art and will not be interpreted in an idealized or overly formal sense unless expressly so defined herein.

As will be appreciated by one of skill in the art, various embodiments described herein may be embodied as a method, data processing system, and/or computer program product. Furthermore, embodiments may take the form of a computer program product on a tangible computer readable storage medium having computer program code embodied in the medium that can be executed by a computer.

Any combination of one or more computer readable media may be utilized. The computer readable media may be a computer readable signal medium or a computer readable storage medium. A computer readable storage medium may be, for example, but not limited to, an electronic, magnetic, optical, electromagnetic, infrared, or semiconductor system, apparatus, or device, or any suitable combination of the foregoing. More specific examples (a non-exhaustive list) of the computer readable storage medium would include the following: a portable computer diskette, a hard disk, a random access memory (RAM), a read-only memory (ROM), an erasable programmable read-only memory (EPROM or Flash memory), a portable compact disc read-only memory (CD-ROM), an optical storage device, a magnetic storage device, or any suitable combination of the foregoing. In the context of this document, a computer readable storage medium may be any tangible medium that can contain, or store a program for use by or in connection with an instruction execution system, apparatus, or device.

A computer readable signal medium may include a propagated data signal with computer readable program code embodied therein, for example, in baseband or as part of a carrier wave. Such a propagated signal may take any of a variety of forms, including, but not limited to, electro-magnetic, optical, or any suitable combination thereof. A computer readable signal medium may be any computer readable medium that is not a computer readable storage medium and that can communicate, propagate, or transport a program for use by or in connection with an instruction execution system, apparatus, or device. Program code embodied on a computer readable signal medium may be transmitted using any appropriate medium, including but not limited to wireless, wired, optical fiber cable, RF, etc., or any suitable combination of the foregoing.

Computer program code for carrying out operations for aspects of the present disclosure may be written in any combination of one or more programming languages, including an object oriented programming language such as Java, Scala, Smalltalk, Eiffel, JADE, Emerald, C++, C#, VB.NET, Python or the like, conventional procedural programming languages, such as the “C” programming language, Visual Basic, Fortran 2003, Perl, COBOL 2002, PHP, ABAP, dynamic programming languages such as Python, Ruby and Groovy, or other programming languages, such as a programming language for a FPGA, Verilog, System Verilog, Hardware Description language (HDL), and VHDL. The program code may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider) or in a cloud computer environment or offered as a service such as a Software as a Service (SaaS).

Some embodiments are described herein with reference to flowchart illustrations and/or block diagrams of methods, systems and computer program products according to embodiments. It will be understood that each block of the flowchart illustrations and/or block diagrams, and combinations of blocks in the flowchart illustrations and/or block diagrams, can be implemented by computer program instructions. These computer program instructions may be provided to a processor of a general purpose computer, special purpose computer, or other programmable data processing apparatus to produce a machine, such that the instructions, which execute via the processor of the computer or other programmable data processing apparatus, create a mechanism for implementing the functions/acts specified in the flowchart and/or block diagram block or blocks.

These computer program instructions may also be stored in a computer readable medium that when executed can direct a computer, other programmable data processing apparatus, or other devices to function in a particular manner, such that the instructions when stored in the computer readable medium produce an article of manufacture including instructions which when executed, cause a computer to implement the function/act specified in the flowchart and/or block diagram block or blocks. The computer program instructions may also be loaded onto a computer, other programmable instruction execution apparatus, or other devices to cause a series of operational steps to be performed on the computer, other programmable apparatuses or other devices to produce a computer implemented process such that the instructions which execute on the computer or other programmable apparatus provide processes for implementing the functions/acts specified in the flowchart and/or block diagram block or blocks.

It is to be understood that the functions/acts noted in the blocks may occur out of the order noted in the operational illustrations. For example, two blocks shown in succession may in fact be executed substantially concurrently or the blocks may sometimes be executed in the reverse order, depending upon the functionality/acts involved. Although some of the diagrams include arrows on communication paths to show a primary direction of communication, it is to be understood that communication may occur in the opposite direction to the depicted arrows.

Many different embodiments have been disclosed herein, in connection with the above description and the drawings. It will be understood that it would be unduly repetitious and obfuscating to literally describe and illustrate every combination and subcombination of these embodiments. Accordingly, all embodiments can be combined in any way and/or combination, and the present specification, including the drawings, shall support claims to any such combination or subcombination.

What is claimed:

1. A hyperdimensional processing unit (HPU) configured to process hyperdimensional (HD) data, the HPU comprising:
an HPU controller circuit configured to execute programmed native HD operations to operate on hyperdimensional data having N dimensions, the HPU controller circuit including an instruction FIFO to store native hyperdimensional vector operations for execution on the hyperdimensional data;
M processing tiles coupled in parallel with one another to a data interconnect configured to carry hypervector data to/from the M processing tiles, each of the processing tiles further including:
M processing engines coupled in parallel with one another to the data interconnect, each of the processing engines configured to operate on P/M dimensions of the N dimensions of the hyperdimensional data in parallel;
wherein each of the processing engines includes:
a digital to analog converter circuit configured to convert the P/M dimensions of the N dimensions of the hyperdimensional data from digital to analog format;
a plurality of first ReRAM memory cells coupled in a first cross-bar memory array configuration to carry out processing-in-memory (PIM) operations on the P/M dimensions of the N dimensions of the hyperdimensional data in analog format inside the first cross-bar memory array to provide first analog format output HD data;
an analog to digital converter circuit coupled to the first cross-bar array, the analog to digital converter circuit configured to provide first digital format output HD data; and
an accumulator circuit coupled to the first digital format output HD data.

2. The HPU of claim 1 wherein each processing engine is configured to perform a native hyperdimensional PIM addition operation in-memory by applying data to be added first and second rows in first cross-bar memory array and measuring a resulting total current in bitlines of the first cross-bar memory array.

3. The HPU of claim 1 wherein each processing engine is configured to perform a native hyperdimensional PIM subtraction operation in-memory by applying data to be added first and second rows in first cross-bar memory array and measuring a resulting net current in bitlines of the first cross-bar memory array.

4. The HPU of claim 1 wherein each processing engine is configured to perform a native hyperdimensional PIM multiply operation in-memory by applying first data to cells in rows of the first cross-bar memory array and applying second data to bitlines shared by the cells in the rows and measuring a resulting current in bitlines of the first cross-bar memory array.

5. The HPU of claim 1 wherein each processing engine is configured to perform a native hyperdimensional PIM dot product operation in-memory by applying first data to cells in rows of the first cross-bar memory array and applying second data to bitlines shared by the cells in the rows and measuring a resulting current in rows of the first cross-bar memory array.

6. The HPU of claim 1 further comprising:
a plurality of second ReRAM memory cells coupled in a second cross-bar memory array configuration to carry out processing-in-memory operations on the P/M dimensions of the N dimensions of the hyperdimensional data in analog format inside the second cross-bar memory array to provide second analog format output HD data; and
wherein the analog to digital converter circuit is coupled to the second cross-bar array, the analog to digital converter circuit is configured to provide second digital format output HD data; and
wherein the accumulator circuit is coupled to the second digital format output HD data.

7. The HPU of claim 1 wherein N×M is at least about 10,000.

8. The HPU of claim 1 wherein each processing engine is configured to perform a native hyperdimensional PIM operation by applying a dimensional bitmask to the N dimensions of the hyperdimensional data to operate on partial portions of the N dimensions to provide a series of partial portion results for combination to provide a complete result.

9. A hyperdimensional processing system configured to process hyperdimensional (HD) data, the system comprising:
A CPU configured to receive compiled binary executable data including CPU native instructions and hyperdimensional processing unit (HPU) native instructions, wherein the CPU is configured to store the CPU native instructions in a main memory coupled to the CPU for retrieval and execution by the CPU, the CPU further configured to forward the HPU native instructions to a HPU; and
The HPU configured to receive HPU native instructions native instructions and to store the HPU native instructions in a hyperdimensional memory coupled to the HPU for retrieval and execution by the CPU.

10. The system of claim 9 further comprising:
an HPU controller circuit configured to execute the HPU native instructions on hyperdimensional data having N dimensions, the HPU controller circuit including an instruction FIFO to store the HPU native instructions for execution on the hyperdimensional data;
M processing tiles coupled in parallel with one another to a data interconnect configured to carry hypervector data to/from the M processing tiles.

11. A method of operating a trained machine learning model, the method comprising:
providing a trained hyperdimensional machine learning model that includes a plurality of trained hypervector classes, wherein each of the trained hypervector classes includes N elements;
eliminating selected ones of the N elements from the trained hypervector classes based on whether a selected element of the N elements is equal to zero or about equal to zero to provide one or more pruned trained hypervector classes included in a pruned hyperdimensional machine learning model;
quantizing a query hypervector received for an inference operation using the pruned hyperdimensional machine learning model to provide a quantized query hypervector; and
determining a similarity between the quantized query hypervector and the one or more pruned trained hypervector classes to perform the inference operation.

12. A method of providing recommendations on items for use by users, the method comprising:
generating a user characterization hypervector for each user of a system to which recommendations for items are made wherein each user characterization hypervector combines a rating hypervector that encodes a respective rating given by the user for each item rated by the user with a hypervector for each item rated by the user;
generating an item characterization hypervector for each of the items for which the recommendations are made to the users wherein each item characterization hypervector combines a hypervector for each rating given a respective user on the item with a user hypervector that encodes the respective user that provided the rating; and
determining a prediction that a target user will give to a potential recommended item that has not been used by the target user based on a similarity between the user characterization hypervector for the target user and the item characterization hypervector for the potential recommended item.

13. A method of operating a hyper-dimensional machine learning model, the method comprising:
encoding a feature vector representing non-binary data by quantizing the feature vector to select a base hypervector to be combined with a respective ID hypervector representing a position of data included in the feature vector to provide a non-binary query hypervector;
applying a threshold to each dimension of the non-binary query hypervector to provide a binary query hypervector;
training the hyper-dimensional machine learning model using the binary query hypervector as training data where the hyper-dimensional machine learning model is initialized to include N hypervectors in each of K classes in the model;
identifying which of the K classes includes the binary query hypervector to provide a selected class for the binary query hypervector; and then
checking similarity between the binary query hypervector and the N hypervectors included in the selected class to provide an identified N hypervector within the class that is most similar to the binary query hypervector; and
updating the hyper-dimensional machine learning model by performing a bit-wise substitution to replace data located at a sub-set of indices in the identified N hypervector with data from a corresponding sub-set of indices in the binary query hypervector.

14. A method of operating a machine learning model, the method comprising:
training a hyperdimensional machine learning model by determining a cosine similarity between training data hypervectors and K initial class hypervectors to provide K trained class hypervectors;
normalizing the K trained class hypervectors to provide K normalized initial class hypervectors;
determining a dot product between a query hypervector and the K normalized initial class hypervectors to determine a closest similarity among the K normalized initial class hypervectors and the query hypervector;
grouping similar ones of the K normalized initial class hypervectors into M-sized groups to provide a K/M sized category stage and a K sized main stage for an associative search and associating each entry in the K/M sized category stage with an entry in the K sized main stage to provide a multi-stage hyperdimensional machine learning model;
quantizing each dimension of elements of the K normalized initial class hypervectors using a combination of two powers of two to provide a quantized multi-stage hyperdimensional machine learning model; and
applying a validation data set to the quantized multi-stage hyperdimensional machine learning model to provide an error corrected quantized multi-stage hyperdimensional machine learning model.

15. A system configured to control operations of programmable logic circuits, the system comprising:
a plurality of programmable logic circuits each configured to process a respective portion of a workload assigned to the plurality of programmable logic circuits;
a central controller circuit included in at least one of the plurality of programmable logic circuits, the central controller circuit configured to control respective operating frequencies and voltage levels provided to each of the plurality of programmable logic circuits to process the respective portion of the workload, the central controller circuit further comprising:
a workload counter circuit configured to determine the respective portion of the workload assigned to the at least one of the plurality of programmable logic circuits that includes the central controller circuit during a current time interval to provide a workload count;
a workload prediction model circuit coupled to the workload counter circuit, the workload prediction model circuit configured to identify the respective operating frequencies and voltage levels for a future time interval based on a prediction of the workload that will be assigned to the plurality of programmable logic circuits in the future time interval; and
a misprediction circuit coupled to the workload counter circuit and to the workload prediction model circuit, the misprediction circuit configured to adjust a model for the workload prediction model circuit based on an error detected between the prediction of the workload prediction model circuit and the workload count.

16. A system configured to process data, the system comprising:
a plurality of ReRAM memory blocks, wherein each memory block is configured to couple accessed data to an array of bitlines to perform logical operations on the accessed data within the array of bitlines to provide output data from the respective memory block;
a data lane that couples the output data from each of the plurality of ReRAM memory blocks together;
an accumulator circuit, coupled to the data lane, that is configured to output a stochastic representation of the output data received from the plurality of ReRAM memory blocks; and
a bitline segmentation switch that extends across the bitlines and is configured segment each of the memory blocks into smaller memory blocks when deactivated, wherein a gate of the bitline segmentation switch extends into a substrate of the ReRAM memory blocks between adjacent wordlines to switchably couple the bitlines together.
